(19) United States
(12) Patent Application Publication
(10) Pub. No.: US 2024/0158658 A1
(43) Pub. Date: May 16, 2024

(54) IODINE REDUCTION FOR REPRODUCIBLE AND HIGH PERFORMANCE PEROVSKITE SOLAR CELLS AND MODULES

(71) Applicant: The University of North Carolina at Chapel Hill, Chapel Hill, NC (US)

(72) Inventors: Jinsong Huang, Chapel Hill, NC (US); Shangshang Chen, Chapel Hill, NC (US)

(21) Appl. No.: 18/270,383

(22) PCT Filed: Dec. 30, 2021
(86) PCT No.: PCT/US2021/065601

§ 371 Date: Jun. 29, 2023

Related U.S. Application Data
(60) Provisional application No. 63/234,930, filed on Aug. 19, 2021.
(60) Provisional application No. 63/131,959, filed on Dec. 30, 2020.

(51) Int. Cl. C09D 11/52; C09D 11/033; C09D 11/037; H10K 85/50; H10K 85/60

(52) U.S. Cl. CPC C09D 11/52; C09D 11/033; C09D 11/037; H10K 85/50; H10K 85/60; H10K 85/655; H10K 71/13

(57) ABSTRACT

Described herein are oxidative-resistant ink solutions, comprising: a first composition of formula ABI_{3-y}X_{y}; one or more solvents; and a compound of Formula (II), or a salt thereof, wherein A, B, y, and X are described herein. Methods for preparing perovskite films using the oxidative-resistant ink solutions and the use of the films in solar cells and solar modules are additionally described. In certain embodiments, further described are methods of preparing perovskite films having reduced interfacial voids, comprising adding a compound of Formula (II), or a salt thereof, to the perovskite precursor solution used to prepare the film.

### CROSS REFERENCE TO RELATED APPLICATIONS

This application claims the benefit of and priority to U.S. Provisional Application No. 63/131,959, filed Dec. 30, 2020, and U.S. Provisional Application No. 63/234,930, filed Aug. 19, 2021, both of which are hereby incorporated by reference in their entirety.

### GOVERNMENT SUPPORT

This invention was made with government support under Grant Number DE-AC36-08GO28308 awarded by the U.S. Department of Energy and Grant Numbers N6833520C0390 and N00014-18-1-2239 awarded by the Office of Naval Research. The government has certain rights in the invention.

### FIELD

The presently disclosed subject matter relates generally to perovskite ink solutions containing a hydrazine reductant to help prevent the oxidation of the precursor ink. The perovskite ink solutions can be used in the fabrication of polycrystalline films for use in photovoltaic or photoactive devices.

### BACKGROUND

Organic-inorganic hybrid perovskite photovoltaics have progressed rapidly in the past decade and are a promising alternative to inorganic photovoltaics for solar technology (Green, M. A., et al. Nat. Photonics 8, 506-514, (2014); Correa-Baena, J.-P. et al. Science 358, 739-744, (2017); and Rong, Y. et al. Science 361, eaat8235, (2018)). Compared to conventional inorganic photovoltaics, one of the advantages of perovskite solar technology is its solution processability, which allows for facile manufacturing, such as blade-coating or slot-die coating, at a low production cost (Li, Z. et al. Nat. Rev. Mater. 3, 18017, (2018)). Despite this, poor reproducibility of solution-processed perovskite solar cells (PSCs) remains an outstanding issue in perovskite photovoltaics, and the relatively large device batch-to-batch variation has impeded perovskite photovoltaic commercialization (Saliba, M. et al. Chem. Mater. 30, 4193-4201, (2018). One factor influencing this device variability is the sensitivity of the precursor solutions used to prepare the perovskite devices. For example, variations in the stoichiometric ratio of the organic halide to lead salt, colloidal size, storing conditions and aging duration can impact the stability of the resultant perovskite device (Zhang, W. et al. Nat. Commun. 6, 10030, (2015); Yan, K. et al. J. Am. Chem. Soc. 137, 4460-4468, (2015); Dou, B. et al. ACS Energy Lett. 3, 979-985, (2018); Wei, H., et al. Chem. Mater. 32, 2501-2507, (2020); and Shin, G. S., et al. ACS Appl. Mater. Interfaces 12, 15167-15174, (2020)). While fresh precursor solutions may be able to produce perovskite solar cells with decent power conversion efficiencies, after the solutions are stored for a few days, the aged solutions are oftentimes no longer able to reproduce the efficient power conversion energies. Consequently, the photovoltaic performance and the reproducibility of the perovskite devices have declined due to the degradation of the perovskite precursor solutions. There exists a need in the art to restore and stabilize perovskite precursor solutions towards efficient and reproducible perovskite solar devices. The subject matter described herein addresses this unmet need.

### BRIEF SUMMARY

In one aspect, the presently disclosed subject matter is directed to an oxidative-resistant ink solution, comprising:
a) a composition of Formula (I):

ABI_{3-y}X_{y} (I)
wherein A is a cation selected from the group consisting of methylammonium (MA), tetramethylammonium, formamidinium (FA), cesium (Cs), rubidium (Rb), potassium (K), sodium (Na), butylammonium (BA), phenethylammonium (PEA), phenylammonium (PA), guanidinium (GA), and a combination thereof;
B is a metal cation selected from the group consisting of lead, tin, calcium, cadmium, germanium, zinc, nickel, platinum, palladium, mercury, titanium, silicon, and a combination thereof;
X is selected from the group consisting of Cl⁻, Br⁻, F⁻, SCN⁻, and a combination thereof;
and
   y is between 0 and 3;
b) one or more solvents;
and
c) a compound of Formula (II):

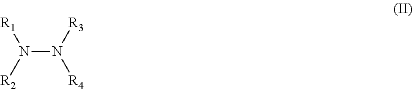

wherein, R₁, R₂, R₃, and R₄ are each independently selected from the group consisting of hydrogen, C₁-C₄₀ alkyl, C₂-C₄₀ alkenyl, C₂-C₄₀ alkynyl, aminoalkyl, C₆-C₁₂ aryl, C₃-C₇ cycloalkyl, 4- to 7-membered heterocyclyl, 5- to 10-membered heteroaryl, C₆-C₁₂ aryl-C₁-C₁₀ alkyl, C₃-C₇ cycloalkyl-C₁-C₁₀ alkyl, 4- to 7-membered heterocyclyl-C₁-C₁₀ alkyl, 5- to 10-membered heteroaryl-C₁-C₁₀ alkyl, and C₁-C₂₀ alkyl-thio-C₁-C₂₀ alkyl, each of which is optionally substituted one or more times with a substituent, each independently selected from the group consisting of halogen, cyano, hydrazino, C₁-C₂₀ alkyl, amino, C₁-C₂₀ alkoxy, C₂-C₂₀ alkenyl, C₂-C₂₀ alkynyl, C₆-C₁₂ aryl, C₃-C₇ cycloalkyl, 4- to 7-membered heterocyclyl, and 5- to 10-membered heteroaryl;
   wherein one or more carbon atoms in said “alkyl” of C₁-C₄₀ alkyl, aminoalkyl, C₆-C₁₂ aryl-C₁-C₁₀ alkyl, C₃-C₇ cycloalkyl-C₁-C₁₀ alkyl, 4- to 7-membered heterocyclyl-C₁-C₁₀ alkyl, 5- to 10-membered heteroaryl-C₁-C₁₀ alkyl, or C₁-C₂₀ alkyl-thio-C₁-C₂₀ alkyl are optionally:
   i. replaced with O or S; and/or
   ii. substituted with (═O);
or, a salt thereof,
provided that when B is tin, said compound of Formula (II), or salt thereof, is other than hydrazinium chloride.

In another aspect, the subject matter described herein is directed to a method of preparing an oxidative-resistant ink solution, comprising: contacting an ink solution comprising a composition of Formula (I) with a compound of Formula (II), or a salt thereof, wherein said oxidative-resistant ink solution is prepared.

In another aspect, the subject matter described herein is directed to a method of reducing oxidation in an ink solution, comprising contacting an ink solution comprising a composition of Formula (I) with an oxidative reducing amount of a compound of Formula (II), or a salt thereof.

In certain embodiments, the subject matter described herein is directed to a method for producing a polycrystalline perovskite film using the oxidative-resistant ink solutions described herein, said method comprising: contacting said ink solution using a fast coating process onto a substrate to form a film, wherein said fast coating process is selected from the group consisting of blade coating, slot die coating, shear coating, gravure coating, brush coating, syringe coating, and screen printing.

In certain embodiments, the subject matter described herein is directed to a polycrystalline film comprising a composition of Formula (I) and a compound of Formula (II).

In certain embodiments, the subject matter described herein is directed to a semiconductor device comprising:
one or more anode layers;
one or more cathode layers; and
one or more active layers, wherein at least one of said one or more active layers comprises a polycrystalline film produced using the ink solutions described herein.

In certain embodiments, the subject matter described herein is directed to a solar cell, comprising:
one or more transparent conductive oxide layers;
one or more conductive electrode layers; and
one or more active layers, wherein at least one of said one or more active layers comprises a polycrystalline film produced using the ink solutions described herein.

In certain embodiments, the subject matter described herein is directed to a method of preparing a perovskite film having reduced interfacial voids, comprising contacting a precursor solution comprising one or more non-coordinating solvents and a composition of Formula (I)

ABI_{3-y}X_{y} (I)
wherein,
A is a cation selected from the group consisting of methylammonium (MA), tetramethylammonium, formamidinium (FA), cesium (Cs), rubidium (Rb), potassium (K), sodium (Na), butylammonium (BA), phenethylammonium (PEA), phenylammonium (PA), guanidinium (GA), and a combination thereof;
B is a metal cation selected from the group consisting of lead, tin, calcium, cadmium, germanium, zinc, nickel, platinum, palladium, mercury, titanium, silicon, and a combination thereof;
X is selected from the group consisting of Cl⁻, Br⁻, F⁻, SCN⁻, and a combination thereof;
y is between 0 and 3;
   with:
(i) a compound of Formula (II), or a salt thereof,

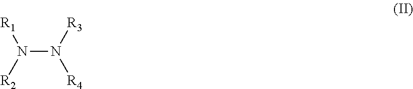

wherein,
R₁, R₂, R₃, and R₄ are each independently selected from the group consisting of hydrogen, C₁-C₄₀ alkyl, C₂-C₄₀ alkenyl, C₂-C₄₀ alkynyl, aminoalkyl, C₆-C₁₂ aryl, C₃-C₇ cycloalkyl, 4- to 7-membered heterocyclyl, 5- to 10-membered heteroaryl, C₆-C₁₂ aryl-C₁-C₁₀ alkyl, C₃-C₇ cycloalkyl-C₁-C₁₀ alkyl, 4- to 7-membered heterocyclyl-C₁-C₁₀ alkyl, 5- to 10-membered heteroaryl-C₁-C₁₀ alkyl, and C₁-C₂₀ alkyl-thio-C₁-C₂₀ alkyl, each of which is optionally substituted one or more times with a substituent, each independently selected from the group consisting of halogen, cyano, hydrazino, C₁-C₂₀ alkyl, amino, C₁-C₂₀ alkoxy, C₂-C₂₀ alkenyl, C₂-C₂₀ alkynyl, C₆-C₁₂ aryl, C₃-C₇ cycloalkyl, 4- to 7-membered heterocyclyl, and 5- to 10-membered heteroaryl;
wherein one or more carbon atoms in said “alkyl” of C₁-C₄₀ alkyl, aminoalkyl, C₆-C₁₂ aryl-C₁-C₁₀ alkyl, C₃-C₇ cycloalkyl-C₁-C₁₀ alkyl, 4- to 7-membered heterocyclyl-C₁-C₁₀ alkyl, 5- to 10-membered heteroaryl-C₁-C₁₀ alkyl, or C₁-C₂₀ alkyl-thio-C₁-C₂₀ alkyl are optionally:
i. replaced with O or S; and/or
ii. substituted with (═O);
   and
(ii) a coordinating solvent, to prepare a modified precursor solution; and contacting said modified precursor solution onto a substrate to prepare a perovskite film, wherein said perovskite film prepared has reduced interfacial voids.

These and other aspects are described herein.

### BRIEF DESCRIPTION OF THE DRAWINGS

FIG. 1A shows a schematic of how I₂ generated during the aging of a perovskite precursor solution can be reduced back to I⁻ after the addition of BHC.

FIG. 1B shows photographs of the precursor solutions and materials: pristine 1.37 M MAI:FAI (7:3) in 2-methoxyethanol before (1) and after aged (2) in air for 2 days (lower left); fresh FAI power (3) and the FAI (4) after being stored in air for 5 months.

FIG. 1C shows UV-Vis absorption spectra of the fresh and aged 1.37 M MAI:FAI (7:3) before and after addition of BHC. The inset shows the chemical reaction between BHC and I₂.

FIG. 2 shows a photo of the 1.37 M MAI and FAI solutions in 2-ME after being aged in air for two days.

FIG. 3 shows SEM images of blade-coated perovskite films processed from (a) aged and (b) aged+BHC precursor solutions.

FIG. 4A shows XRD patterns of perovskite films or solar devices processed from different precursor solutions.

FIG. 4B shows PL intensity spectra of the perovskite films or solar devices processed from different precursor solutions.

FIG. 4C J-V characteristics of the perovskite films or solar devices processed from different precursor solutions.

FIG. 4D shows stabilized power output of the champion PSC at a fixed bias of 1.04 V.

FIG. 4E shows EQE spectra of three types of devices processed from different precursor solutions

FIG. 4F shows tDOS spectra of three types of devices processed from different precursor solutions.

FIG. 4G shows a statistical analysis on the PCEs of PSCs processed from BHC-added, aged, and fresh precursor solutions.

FIG. 5 shows a NREL certification of a blade-coated PSC with a stabilized efficiency of (22.62±0.40) %.

FIG. 6 shows a plot of J-V characteristics of PSCs based on aged precursor solutions with different molar ratios of BHC with respect to Pb.

FIG. 7A shows a plot of operational stability test results of the encapsulated PSCs processed from different precursor solutions under one sun equivalent illumination in air (neither cooling nor UV filters were used in this test).

FIG. 7B shows a plot of absorption spectra of toluene solutions in which MA_{0.7}FA_{0.3}PbI₃ films with and without BHC were immersed under 1 sun illumination for eight hours. The inset shows a picture of the vials in which two films (15 mm×15 mm) were immersed into 5 mL of toluene.

FIG. 8 shows a plot of J-V curves of PSCs processed from precursor solutions with propylhydrazine hydrochloride (PHC) and (2-thienylmethyl)hydrazine hydrochloride (THC), respectively. The inset shows the chemical structures of PHC and THC.

FIG. 9A shows a plot of J-V characteristics of a perovskite mini-module with an aperture area of 35.8 cm². The inset shows a picture of a champion mini-module.

FIG. 9B shows a plot of the power output of a champion mini-module at a fixed bias of 9.8 V.

FIG. 10 shows a plot of a UV-Vis absorption spectrum of a 1.37 M MAI:FAI (7:3) 2-ME solution aged in a glovebox for ˜2 months.

FIG. 11 shows how carbohydrazide can stabilize perovskite precursor solutions: (A) is a picture of a precursor perovskite solution before carbohydrazide addition; (B) is a picture of a precursor perovskite solution right after the addition of carbohydrazide, wherein a white precipitate formed; and (C) is a picture showing how the precipitate in (B) disappeared after shaking the solution.

FIG. 12 shows current density versus voltage plots of perovskite solutions comprising various amounts of DMSO with or without carbohydrazide additive.

FIG. 13A shows a schematic of peeling off perovskite films from ITO glass substrates with an epoxy encapsulant for SEM characterization. On the right is an image of a peeled-off device from an ITO glass substrate.

FIG. 13B shows top-view SEM images of perovskite-substrate interfaces of blade-coated perovskite films which were prepared from precursor solutions with different amounts of DMSO and then peeled off from ITO glass substrates. Scale bar: 1 m.

FIG. 13C shows a schematic displaying how voids are formed at perovskite-substrate interfaces.

FIG. 13D shows top-view SEM images of peeled-off perovskite-substrate interfaces of light-soaked MA_{0.6}FA_{0.4}PbI₃ films. Scale bar: 1 μm,

FIG. 14 shows (A) Top-view SEM and (B) AFM characterization results of an ITO glass substrate after the peeling-off process. (C) XPS spectra of a perovskite film and ITO glass substrate after peeling-off.

FIG. 15 shows a plot of J-V curves for control MA_{0.6}FA_{0.4}PbI₃ PSCs processed from different amounts of DMSO.

FIG. 16 shows a cross-sectional SEM image of a control perovskite film. The two right-most circles show the interfacial voids with a depth of ˜100 nm. It is uncertain in the left-most circled region whether this region contains real voids or the grains were removed when cutting the film for SEM characterization.

FIG. 17 shows FIB-SEM images of (A) control and (B) target MA_{0.6}FA_{0.4}PbI₃ perovskite films blade-coated at a humidity of 35 to 40% in air. The control and target films were processed from precursor solutions containing 38% DMSO and (25% DMSO+1.5% CBH), respectively. The target film shows much fewer voids than the control film.

FIG. 18 shows top-view SEM images of perovskite-substrate interfaces of spin-coated (A) MAPbI₃, (B) Cs_{0.05}FA_{0.81}MA_{0.14}PbI₃ and (C) Cs_{0.4}FA_{0.6}PbI_{1.95}Br_{1.05} films.

FIG. 19 shows ¹H NMR spectra of scraped perovskite films annealed for (A) 1 s, (B) 5 s, (C) 15 s, (D) 30 s, (E) 1 min, and (F) 5 min.

FIG. 20 shows the relative amount of DMSO to Pb in perovskite films over annealing durations determined from ¹H NMR spectra.

FIG. 21 shows a grayed SEM image used in the analysis of the volume ratio of the voids in perovskites. The white regions are set as the voids, which account for ˜10% of the interface. The depth of voids was ˜100 nm (10% of the thickness of the perovskite film), so the volume ratio of the voids to perovskites was calculated to be 1%.

FIG. 22 shows images displaying the characterization of perovskite films. (A) Chemical structures of DMSO and CBH. (B) FTIR spectra of DMSO, CBH, and MA_{0.6}FA_{0.4}PbI₃ films with the addition of DMSO and carbohydrazide. (C) Top-view SEM image of the perovskite-substrate interface of the target perovskite film peeled off from ITO glass substrate. Scale bar: 1 μm. (D) XPS spectra of the perovskite-substrate (bottom) and perovskite-air (top) interfaces of an identical target MA_{0.6}FA_{0.4}PbI₃ film. (E) PL maps of the control (left) and target (right) perovskite films on thin glass excited from the glass side with a 485 nm laser.

FIG. 23 shows a weight change comparison of DMSO and CBH heated at 120° C. The initial weight of DMSO and CBH were 1.01 and 0.99 grams, respectively. Then, DMSO or CBH was heated on a hot plate at 120° C. and their weight was recorded every 5 minutes during heating to examine the weight change.

FIG. 24 shows ¹H NMR spectra of (A) CBH and (B) target perovskite film dissolved in D₂O. The integration of the peak of CBH at 7.40 ppm shows that ˜1.4 mol % CBH relative to Pb remains in the target perovskite film, which is consistent with the amount (1.5%) that was added into the perovskite precursor solutions.

FIG. 25 shows photographs of blade-coated perovskite films on a hot plate at 80° C. for different durations. Both perovskite films were processed from the precursor solutions with DMF as the solvent. The right film contained CBH, while the left did not. The photographs show the delayed crystallization of perovskite by CBH additive, which is at least partially a result of the bonding of CBH with lead ions.

FIG. 26 shows XRD patterns of perovskite films processed from (A) neat 2-ME and (B) 2-ME+CBH before and after thermal annealing. CBH additive enhanced the crystallinity of formed perovskites. The control film shows comparable film crystallization before and after thermal annealing, while the crystallization of the film slowed down after adding CBH.

FIG. 27 shows top-view SEM images of the perovskite-substrate interfaces of five individual peeled-off (A) control and (B) target MA_{0.6}FA_{0.4}PbI₃ perovskite films blade-coated at a humidity of 35 to 40% in air. The control and target films were processed from precursor solutions containing 38% DMSO and (25% DMSO+1.5% CBH), respectively.

FIG. 28 shows grazing incidence X-ray diffraction patterns of the target perovskite films following annealing for (A) 0 s and (B) 3 s at 120° C. Three characteristic peaks at 2 theta of 6.6°, 7.2°, and 9.2° were observed at all incidence angles for the non-annealed film, which were assigned to the (002), (021), and (022) planes of the crystalline intermediate phase containing DMSO. When the film was annealed for 3 s, the intermediate phase only presented itself deep in the bulk (large incidence angles of 2° and 30), rather than at the film surface (small incidence angles of 0.5° and 10). Therefore, the target film follows the downward crystallization scenario.

FIG. 29 shows an XPS spectrum of a control perovskite-substrate interface after peeling-off from an ITO glass substrate.

FIG. 30 shows data plots of the photovoltaic performance of PSCs. (A) J-V curve of the champion target PSC. Inset shows the stabilized power output of the champion target PSC fixed at a bias of 1.04 V for 600 s. (B) The efficiency distribution of 65 target PSCs. (C) Operational stability test results of the encapsulated control and target PSCs processed under one sun equivalent illumination in air (neither cooling nor UV filters were used in this test). Inset shows the top-view SEM images of the peeled-off perovskite-substrate interface of the light-soaked control (left) and target (right) PSCs after the stability test. Scale bar: 1 μm. (D) UV-Vis absorption spectra of the toluene solutions in which control and target MA_{0.6}FA_{0.4}PbI₃ films were immersed under 1 sun illumination for 15 hours. Inset shows a picture of the vials in which each film (15 mm×15 mm) was immersed into 5 mL toluene.

FIG. 31 shows EQE spectra of control and target PSCs.

FIG. 32 shows photographs of I₂ in 2-ME before and after adding CBH.

FIG. 33 shows plots of the photovoltaic performance of perovskite mini-modules. (A) J-V characteristics of two perovskite mini-modules with aperture areas of 17.9 and 50.1 cm², respectively. (B) NREL certified stabilized current-voltage dots around the MPP point of the mini-modules with aperture areas of 18.1 and 50.0 cm². (C) Average efficiencies versus aperture areas of 112 mini-modules. Inset shows the aperture efficiency distribution of 112 mini-modules. (D) Long-term operational stability results of five perovskite mini-modules under simulated one sun illumination at 50° C. The abrupt PCE change at ˜400 h was caused by the replacement of the peeling-off PDMS anti-reflection layers.

FIG. 34 shows an optical microscope image of the dead zone of perovskite mini-modules (A); and a surface profile of the module dead zone (B).

FIG. 35 shows a stabilized efficiency of 19.3% for a perovskite mini-module with an aperture area of 18.1 cm² certified by NREL.

FIG. 36 shows a stabilized efficiency of 19.2% for a perovskite mini-module with an aperture area of 50.0 cm² certified by NREL.

### DETAILED DESCRIPTION

The subject matter described herein relates to a low-cost hydrazine reductant of Formula (II) that can effectively reduce I₂ back to I⁻ in aged precursor solutions and thus restore perovskite precursor solutions. While several research investigations have been directed to improving the stability of perovskite solar cell devices, the stability of perovskite precursor solutions has not been as extensively studied (Christians, J. A., et al. ACS Energy Lett. 3, 2136-2143, (2018); and Leijtens, T. et al. Adv. Energy Mater. 5, 1500963, (2015)). Preventing or reducing the degradation of perovskite precursor solutions when exposed to O₂ and moisture is important because large-area perovskite modules are generally manufactured in air and the state of the precursor solutions influences the performance and yield of the perovskite modules. Among the precursor materials used in preparing perovskite precursor solutions, organic halide salts, such as methylammonium iodide (MAI) and formamidinium iodide (FAI), often suffer from poorer stability compared to metal halides. One instability issue is that I⁻ ions are readily oxidized to I₂ during storage of perovskite precursor solutions. The oxidation of I⁻ has been observed in other I⁻-containing solutions, like HI in which hypophosphorous acid is often added as a stabilizer. This instability issue has been observed to significantly deteriorate the photovoltaic performance of perovskite devices (Zhang, W. et al. Nat. Commun. 6, 10030, (2015)). One way to address this issue would be use pure organic halides to prepare fresh precursor solutions before solar device fabrication, but this strategy is tedious and time-consuming, and certainly increases the manufacturing cost.

As shown herein, a low-cost hydrazine reductant of Formula (II) can effectively reduce I₂ back to I⁻ in aged precursor solutions and therefore restore perovskite precursor solutions back to their pristine form. In addition, the hydrazine residual in the perovskite films can both passivate defects and reduce I₂ generated during light soaking. As a result of this dual effect, the blade-coated p-i-n PSCs processed from the hydrazine aged precursor solution can achieve high PCEs and excellent operational stability. The subject matter disclosed herein provides a simple and effective strategy to restore and stabilize the perovskite precursor solutions towards efficient and reproducible perovskite solar devices.

As further described herein, the compounds of Formula (II) can help prevent degradation of perovskite solar cells. Degradation of PSCs starts from the interfaces, including both perovskite-metal electrode and perovskites-substrate interfaces, where defects develop (Z. Ni et al., Science 367, 1352-1358 (2020); S. Yang et al., Science 365, 473-478 (2019); F. Wang, et al. npjFlexible Electronics 2, 22 (2018); and S. P. Dunfield et al., Adv. Energy Mater. 10, 1904054 (2020)). Most research efforts have focused on stabilizing the perovskite-metal electrode interface through surface passivation or post-fabrication treatment, whereas the imbedded perovskite-substrate interface has received less attention (B. Chen, et al., Chem. Soc. Rev. 48, 3842-3867 (2019); and J. Xue, R. Wang, Y. Yang, Nat. Rev. Mater. 5, 809-827 (2020)). This is partly due to difficulties in investigating the morphology of these regions through tools such as scanning electron microscopy (SEM) or atomic force microscopy (AFM). Nevertheless, stabilizing the imbedded bottom interfaces should be considered when evaluating PSC design and efficiency (X. Yang et al., Adv. Mater. 33, 2006435 (2021)). Trap density profiling showed that the perovskite layers near the substrate side have an even higher defect concentration, particularly deep charge traps, than those of perovskite-metal electrode interfaces (Z. Ni et al., Science 367, 1352-1358 (2020)). High-resolution transmittance electron microscopy also revealed that perovskite at this interface contains amorphous regions or nanocrystals with large interface areas. Furthermore, incident light from the perovskite-substrate interface makes it more vulnerable to degradation.

As described herein, a high density of voids was discovered at the perovskite-substrate interfaces of bladed and spun perovskite films with a variety of compositions. These voids were discovered after peeling the perovskite films off of the substrates. The perovskites around these voids underwent faster degradation under light illumination. The formation of these voids was related to entrapped non-volatile dimethyl sulfoxide (DMSO) near the bottom of perovskite films. DMSO was partially replaced with a solid-state lead-coordinating additive of carbohydrazide (CBH) (a compound of Formula II), which reduced the formation of interfacial voids, yielding blade-coated p-i-n structure PSCs with a significantly enhanced stabilized PCE and exceptional module efficiency. In addition, the reduced interfacial voids and the CBH residuals in perovskite films stabilized the PSCs and improved the yield of high-efficiency perovskite modules.

The presently disclosed subject matter will now be described more fully hereinafter. However, many modifications and other embodiments of the presently disclosed subject matter set forth herein will come to mind to one skilled in the art to which the presently disclosed subject matter pertains having the benefit of the teachings presented in the foregoing descriptions. Therefore, it is to be understood that the presently disclosed subject matter is not to be limited to the specific embodiments disclosed and that modifications and other embodiments are intended to be included within the scope of the appended claims. In other words, the subject matter described herein covers all alternatives, modifications, and equivalents. Unless otherwise defined, all technical and scientific terms used herein have the same meaning as commonly understood by one of ordinary skill in this field. All publications, patent applications, patents, and other references mentioned herein are incorporated by reference in their entirety. In the event that one or more of the incorporated literature, patents, and similar materials differs from or contradicts this application, including but not limited to defined terms, term usage, described techniques, or the like, this application controls.

### I. Definitions

As used herein, “and/or” refers to and encompasses any and all possible combinations of one or more of the associated listed items, as well as the lack of combinations when interpreted in the alternative (“or”).

As used herein, the term “about,” when referring to a measurable value such as an amount of a compound or agent of the current subject matter, dose, time, temperature, and the like, is meant to encompass variations of ±20%, ±10%, ±5%, ±1%, ±0.5%, or even ±0.1% of the specified amount.

As used herein, conditional language used herein, such as, among others, “can,” “could,” “might,” “may,” “e.g.,” and the like, unless specifically stated otherwise or otherwise understood within the context as used, is generally intended to convey that certain embodiments include, while other embodiments do not include, certain features, elements and/or steps. Thus, such conditional language is not generally intended to imply that features, elements and/or steps are in any way required for one or more embodiments or that one or more embodiments necessarily include logic for deciding, with or without author input or prompting, whether these features, elements and/or steps are included or are to be performed in any particular embodiment. The terms “comprising,” “including,” “having,” and the like are synonymous and are used inclusively, in an open-ended fashion, and do not exclude additional elements, features, acts, operations, and so forth. Also, the term “or” is used in its inclusive sense (and not in its exclusive sense) so that when used, for example, to connect a list of elements, the term “or” means one, some, or all of the elements in the list.

In certain embodiments, “contacting” refers to allowing an ink solution to be contacted with a compound. The contact may or may not be facilitated by mixing, agitating, stirring, and the like. In other embodiments, “contacting” refers to allowing a perovskite ink solution to contact a substrate so as to form a film.

As used herein, “PSC” refers to perovskite solar cell.

As used herein, the terms “power conversion efficiency,” “PCE,” “photovoltaic efficiency”, and “solar cell efficiency,” may be used interchangeably and refer to the ratio of energy output from the photovoltaic device to the energy input to the photovoltaic device. The energy output is in the form of electrical energy and energy input is in the form of electromagnetic radiation (e.g., sunlight). Unless otherwise indicated, the photovoltaic efficiency refers to terrestrial photovoltaic efficiency, corresponding to AM1.5 conditions, where AM is Air Mass. PCE may be measured by one or more techniques conventionally known to one of ordinary skill in the art.

As used herein, the term “illumination equivalent to 1 sun” refers to an illumination (radiation) intensity and/or electromagnetic spectrum of illumination that substantially approximates or is substantially equivalent to terrestrial solar intensity and/or electromagnetic spectrum.

As used herein, “active layer” refers to a photoactive layer in a device, such as a solar cell, and/or it may include a photoactive material. Furthermore, it should be noted that the use of the term “active layer” is in no way meant to restrict or otherwise define, explicitly or implicitly, the properties of any other layer in the device.

As used herein, “oxidative resistant” refers to an ink solution that resists oxidation of I⁻ to I₂. In embodiments, the ink solutions described herein contain a compound of Formula (II) that can help reduce I₂ back to I⁻.

A dash (“-”) that is not between two letters or symbols is used to indicate a point of attachment for a substituent. For example, —C(O)NH₂ is attached through the carbon atom. A dash at the front or end of a chemical group is a matter of convenience; chemical groups may be depicted with or without one or more dashes without losing their ordinary meaning. A wavy line or a dashed line drawn through or perpendicular across the end of a line in a structure indicates a specified point of attachment of a group. Unless chemically or structurally required, no directionality or stereochemistry is indicated or implied by the order in which a chemical group is written or named.

The prefix “Cᵤ-Cᵥ” indicates that the following group has from u to v carbon atoms. For example, “C₁-C₆ alkyl” indicates that the alkyl group has from 1 to 6 carbon atoms.

“Alkyl” refers to an unbranched or branched saturated hydrocarbon chain. As used herein, alkyl has 1 to 20 carbon atoms (i.e., C₁-C₂₀ alkyl), 1 to 12 carbon atoms (i.e., C₁-C₁₂ alkyl), 1 to 8 carbon atoms (i.e., C₁-C₈ alkyl), 1 to 6 carbon atoms (i.e., C₁-C₆ alkyl), 1 to 4 carbon atoms (i.e., C₁-C₄ alkyl), or 1 to 3 carbon atoms (i.e., C₁-C₃ alkyl). Examples of alkyl groups include, e.g., methyl, ethyl, propyl, isopropyl, n-butyl, sec-butyl, iso-butyl, tert-butyl, pentyl, 2-pentyl, isopentyl, neopentyl, hexyl, 2-hexyl, 3-hexyl and 3-methylpentyl. When an alkyl residue having a specific number of carbons is named by chemical name or identified by molecular formula, all positional isomers having that number of carbons may be encompassed; thus, for example, “butyl” includes n-butyl (i.e., —(CH₂)₃CH₃), sec-butyl (i.e., —CH(CH₃)CH₂CH₃), isobutyl (i.e., —CH₂CH(CH₃)₂) and tert-butyl (i.e., —C(CH₃)₃); and “propyl” includes n-propyl (i.e., —(CH₂)₂CH₃) and isopropyl (i.e., —CH(CH₃)₂).

Certain commonly used alternative chemical names may be used. For example, a divalent group such as a divalent “alkyl” group, a divalent “aryl” group, etc., may also be referred to as an “alkylene” group or an “alkylenyl” group, an “arylene” group or an “arylenyl” group, respectively. Also, unless indicated explicitly otherwise, where combinations of groups are referred to herein as one moiety, e.g., arylalkyl or aralkyl, the last mentioned group contains the atom by which the moiety is attached to the rest of the molecule.

“Alkenyl” refers to an alkyl group containing at least one carbon-carbon double bond and having from 2 to 20 carbon atoms (i.e., C₂-C₂₀ alkenyl), 2 to 8 carbon atoms (i.e., C₂-C₈ alkenyl), 2 to 6 carbon atoms (i.e., C₂-C₆ alkenyl) or 2 to 4 carbon atoms (i.e., C₂-C₄ alkenyl). Examples of alkenyl groups include, e.g., ethenyl, propenyl, butadienyl (including 1,2-butadienyl and 1,3-butadienyl).

“Alkynyl” refers to an alkyl group containing at least one carbon-carbon triple bond and having from 2 to 20 carbon atoms (i.e., C₂-C₂₀ alkynyl), 2 to 8 carbon atoms (i.e., C₂-C₈ alkynyl), 2 to 6 carbon atoms (i.e., C₂-C₆ alkynyl) or 2 to 4 carbon atoms (i.e., C₂-C₄ alkynyl). The term “alkynyl” also includes those groups having one triple bond and one double bond.

“Alkoxy” refers to the group “alkyl-O—” (i.e. C₁-C₃ alkoxy or C₁-C₆ alkoxy). Examples of alkoxy groups include, e.g., methoxy, ethoxy, n-propoxy, iso-propoxy, n-butoxy, tert-butoxy, sec-butoxy, n-pentoxy, n-hexoxy and 1,2-dimethylbutoxy.

“Alkoxy-alkyl” refers to the group “-alkyl-alkoxy” (i.e. C₁-C₃ alkoxy-C₁-C₃ alkyl, C₁-C₆ alkoxy-C₁-C₃ alkyl). Non-limiting examples of alkoxy-alkyl are —CH₂OCH₃, —CH₂OC(CH₃)₃, and —C(CH₃)₂CH₂OCH₃.

“Alkylthio” refers to the group “alkyl-S—”. “Alkylthioalkyl” refers to the group -alkyl-S-alkyl, such as C₁-C₃-alkyl-S—C₁-C₃ alkyl. A non-limiting example of alkylthioalkyl is —CH₂CH₂SCH₃. “Alkylsulfinyl” refers to the group “alkyl-S(O)—”. “Alkylsulfonyl” refers to the group “alkyl-S(O)₂—”. “Alkylsulfonylalkyl” refers to -alkyl-S(O)₂-alkyl.

“Amino” refers to the group —NR^{y}R^{z} wherein R^{y} and R^{z} are independently hydrogen, alkyl, alkenyl, alkynyl, cycloalkyl, heterocyclyl, aryl, heteroalkyl or heteroaryl; each of which may be optionally substituted, as defined herein.

“Aminoalkyl” refers to the group —NR^{y}R^{z} wherein R^{y} is alkyl and R^{z} is hydrogen, alkyl, alkenyl, alkynyl, cycloalkyl, heterocyclyl, aryl, heteroalkyl or heteroaryl; each of R^{z} and R^{y} may be optionally substituted, as defined herein.

“Aryl” refers to an aromatic carbocyclic group having a single ring (e.g., monocyclic) or multiple rings (e.g., bicyclic or tricyclic) including fused systems. As used herein, aryl has 6 to 20 ring carbon atoms (i.e., C₆-C₂₀ aryl), 6 to 12 carbon ring atoms (i.e., C₆-C₁₂ aryl), or 6 to 10 carbon ring atoms (i.e., C₆-C₁₀ aryl). Examples of aryl groups include, e.g., phenyl, naphthyl, fluorenyl and anthryl. Aryl, however, does not encompass or overlap in any way with heteroaryl defined below. If one or more aryl groups are fused with a heteroaryl, the resulting ring system is heteroaryl regardless of the point of attachment. If one or more aryl groups are fused with a heterocyclyl, the resulting ring system is heterocyclyl regardless of the point of attachment.

“Arylalkyl” or “Aralkyl” refers to the group “aryl-alkyl-”, such as (C₆-C₁₀ aryl)-C₁-C₃ alkyl. A non-limiting example of arylalkyl is benzyl.

“Cycloalkyl” refers to a saturated or partially unsaturated cyclic alkyl group having a single ring or multiple rings including fused, bridged and spiro ring systems. The term “cycloalkyl” includes cycloalkenyl groups (i.e., the cyclic group having at least one double bond) and carbocyclic fused ring systems having at least one sp³ carbon atom (i.e., at least one non-aromatic ring). As used herein, cycloalkyl has from 3 to 20 ring carbon atoms (i.e., C₃-C₂₀ cycloalkyl), 3 to 12 ring carbon atoms (i.e., C₃-C₁₂ cycloalkyl), 3 to 10 ring carbon atoms (i.e., C₃-C₁₀ cycloalkyl), 3 to 8 ring carbon atoms (i.e., C₃-C₈ cycloalkyl), 3 to 7 ring carbon atoms (i.e., C₃-C₇ cycloalkyl), or 3 to 6 ring carbon atoms (i.e., C₃-C₆ cycloalkyl). Monocyclic groups include, for example, cyclopropyl, cyclobutyl, cyclopentyl, cyclohexyl, cycloheptyl and cyclooctyl. Polycyclic groups include, for example, bicyclo[2.2.1]heptanyl, bicyclo[2.2.2]octanyl, adamantyl, norbornyl, decalinyl, 7,7-dimethyl-bicyclo[2.2.1]heptanyl and the like. Further, the term cycloalkyl is intended to encompass any non-aromatic ring which may be fused to an aryl ring, regardless of the attachment to the remainder of the molecule. Still further, cycloalkyl also includes “spirocycloalkyl” when there are two positions for substitution on the same carbon atom, for example spiro[2.5]octanyl, spiro[4.5]decanyl, or spiro[5.5]undecanyl.

“Cycloalkylalkyl” refers to the group “cycloalkyl-alkyl-”, such as (C₃-C₆ cycloalkyl)-C₁-C₃ alkyl.

“Cycloalkylalkyl-alkoxy” refers to the group “-alkoxy-alkyl-cycloalkyl” (i.e. C₃-C₇ cycloalkyl-C₁-C₃ alkyl-C₁-C₃ alkoxy-), such as —OCH₂-cyclopropyl.

“Hydrazino” refers to —NHNH₂.

“Halogen” or “halo” refers to atoms occupying group VIIA of the periodic table, such as fluoro (fluorine), chloro (chlorine), bromo (bromine) or iodo (iodine).

“Haloalkyl” refers to an unbranched or branched alkyl group as defined above, wherein one or more (e.g., 1 to 6, or 1 to 3) hydrogen atoms are replaced by a halogen. For example, halo-C₁-C₃ alkyl refers to an alkyl group of 1 to 3 carbons wherein at least one hydrogen atom is replaced by a halogen. Where a residue is substituted with more than one halogen, it may be referred to by using a prefix corresponding to the number of halogen moieties attached. Dihaloalkyl and trihaloalkyl refer to alkyl substituted with two (“di”) or three (“tri”) halo groups, which may be, but are not necessarily, the same halogen. Examples of haloalkyl include, e.g., trifluoromethyl, difluoromethyl, fluoromethyl, trichloromethyl, 2,2,2-trifluoroethyl, 1,2-difluoroethyl, 3-bromo-2-fluoropropyl, 1,2-dibromoethyl and the like.

“Haloalkoxy” refers to an alkoxy group as defined above, wherein one or more (e.g., 1 to 6, or 1 to 3) hydrogen atoms are replaced by a halogen. Non-limiting examples of haloalkoxy are —OCH₂CF₃, —OCF₂H, and —OCF₃.

“Hydroxyalkyl” refers to an alkyl group as defined above, wherein one or more (e.g., 1 to 6, or 1 to 3) hydrogen atoms are replaced by a hydroxy group (i.e. hydroxy-C₁-C₃-alkyl, hydroxy-C₁-C₆-alkyl). Non-limiting examples of hydroxyalkyl include —CH₂OH, —CH₂CH₂OH, and —C(CH₃)₂CH₂OH.

“Hydroxyalkoxy” refers to the group “-alkoxy-hydroxy,” (i.e. hydroxy-C₁-C₃ alkoxy, hydroxy-C₁-C₆ alkoxy). Non-limiting examples of hydroxyalkoxy include —OCH₂CH₂OH and —OCH₂C(CH₃)₂OH.

“Heteroalkyl” refers to an alkyl group in which one or more of the carbon atoms (and any associated hydrogen atoms) are each independently replaced with the same or different heteroatomic group, provided the point of attachment to the remainder of the molecule is through a carbon atom. In certain embodiments, the heteroalkyl can have 1 to 3 carbon atoms (i.e. C₁-C₃ heteroalkyl) or 1 to 6 carbon atoms (i.e. C₁-C₆ heteroalkyl). The term “heteroalkyl” includes unbranched or branched saturated chain having carbon and heteroatoms. By way of example, 1, 2 or 3 carbon atoms may be independently replaced with the same or different heteroatomic group. Heteroatomic groups include, but are not limited to, —NR^{y}—, —O—, —S—, —S(O)—, —S(O)₂—, and the like, wherein R^{y} is hydrogen, alkyl, alkenyl, alkynyl, cycloalkyl, heterocyclyl, aryl, heteroalkyl or heteroaryl; each of which may be optionally substituted, as defined herein. Examples of heteroalkyl groups include, e.g., ethers (e.g., —CH₂OCH₃, —CH(CH₃)OCH₃, —CH₂CH₂OCH₃, —CH₂CH₂OCH₂CH₂OCH₃, etc.), thioethers (e.g., —CH₂SCH₃, —CH(CH₃)SCH₃, —CH₂CH₂SCH₃, —CH₂CH₂SCH₂CH₂SCH₃, etc.), sulfones (e.g., —CH₂S(O)₂CH₃, —CH(CH₃)S(O)₂CH₃, —CH₂CH₂S(O)₂CH₃, —CH₂CH₂S(O)₂CH₂CH₂OCH₃, etc.) and amines (e.g., —CH₂NR^{y}CH₃, —CH(CH₃)NR^{y}CH₃, —CH₂CH₂NR^{y}CH₃, —CH₂CH₂NR^{y}CH₂CH₂NR^{y}CH₃, etc., where R^{y} is hydrogen, alkyl, alkenyl, alkynyl, cycloalkyl, heterocyclyl, aryl, heteroalkyl, or heteroaryl; each of which may be optionally substituted, as defined herein). As used herein, heteroalkyl includes 1 to 10 carbon atoms, 1 to 8 carbon atoms, or 1 to 4 carbon atoms; and 1 to 3 heteroatoms, 1 to 2 heteroatoms, or 1 heteroatom.

“Heteroaryl” refers to an aromatic group having a single ring, multiple rings or multiple fused rings, with one or more ring heteroatoms independently selected from nitrogen, oxygen, and sulfur. As used herein, heteroaryl includes 1 to 20 ring carbon atoms (i.e., C₁-C₂₀ heteroaryl), 3 to 12 ring carbon atoms (i.e., C₃-C₁₂ heteroaryl), or 3 to 8 carbon ring atoms (i.e., C₃-C₈ heteroaryl), and 1 to 5 ring heteroatoms, 1 to 4 ring heteroatoms, 1 to 3 ring heteroatoms, 1 to 2 ring heteroatoms, or 1 ring heteroatom independently selected from nitrogen, oxygen and sulfur. In certain instances, heteroaryl includes 9-10 membered ring systems (i.e., 9-10 membered heteroaryl), 5-10 membered ring systems (i.e., 5-10 membered heteroaryl), 5-7 membered ring systems (i.e., 5-7 membered heteroaryl), 5-6 membered ring systems (i.e., 5-6 membered heteroaryl), or 4-6 membered ring systems (i.e., 4-6 membered heteroaryl), each independently having 1 to 4 ring heteroatoms, 1 to 3 ring heteroatoms, 1 to 2 ring heteroatoms, or 1 ring heteroatom independently selected from nitrogen, oxygen and sulfur. Examples of heteroaryl groups include, e.g., acridinyl, benzimidazolyl, benzothiazolyl, benzindolyl, benzofuranyl, benzothiazolyl, benzothiadiazolyl, benzonaphthofuranyl, benzoxazolyl, benzothienyl (benzothiophenyl), benzotriazolyl, benzo[4,6]imidazo[1,2-a]pyridyl, carbazolyl, cinnolinyl, dibenzofuranyl, dibenzothiophenyl, furanyl, isothiazolyl, imidazolyl, indazolyl, indolyl, indazolyl, isoindolyl, isoquinolyl, isoxazolyl, naphthyridinyl, oxadiazolyl, oxazolyl, 1-oxidopyridinyl, 1-oxidopyrimidinyl, 1-oxidopyrazinyl, 1-oxidopyridazinyl, phenazinyl, phthalazinyl, pteridinyl, purinyl, pyrrolyl, pyrazolyl, pyridinyl, pyrazinyl, pyrimidinyl, pyridazinyl, quinazolinyl, quinoxalinyl, quinolinyl, quinuclidinyl, isoquinolinyl, thiazolyl, thiadiazolyl, triazolyl, tetrazolyl and triazinyl. Examples of the fused-heteroaryl rings include, but are not limited to, benzo[d]thiazolyl, quinolinyl, isoquinolinyl, benzo[b]thiophenyl, indazolyl, benzo[d]imidazolyl, pyrazolo[1,5-a]pyridinyl and imidazo[1,5-a]pyridinyl, where the heteroaryl can be bound via either ring of the fused system. Any aromatic ring, having a single or multiple fused rings, containing at least one heteroatom, is considered a heteroaryl regardless of the attachment to the remainder of the molecule (i.e., through any one of the fused rings). Heteroaryl does not encompass or overlap with aryl as defined above.

“Heteroarylalkyl” refers to the group “heteroaryl-alkyl-”, such as (5- to 10-membered monocyclic heteroaryl)-C₁-C₃ alkyl.

“Heterocyclyl” refers to a saturated or partially unsaturated cyclic alkyl group, with one or more ring heteroatoms independently selected from nitrogen, oxygen and sulfur. The term “heterocyclyl” includes heterocycloalkenyl groups (i.e., the heterocyclyl group having at least one double bond), bridged-heterocyclyl groups, fused-heterocyclyl groups and spiro-heterocyclyl groups. A heterocyclyl may be a single ring or multiple rings wherein the multiple rings may be fused, bridged or spiro, and may comprise one or more (e.g., 1 to 3)N-oxide (—O⁻) moieties. Any non-aromatic ring containing at least one heteroatom is considered a heterocyclyl, regardless of the attachment (i.e., can be bound through a carbon atom or a heteroatom). Further, the term heterocyclyl is intended to encompass any non-aromatic ring containing at least one heteroatom, which ring may be fused to an aryl or heteroaryl ring, regardless of the attachment to the remainder of the molecule. As used herein, heterocyclyl has 2 to 20 ring carbon atoms (i.e., C₂-C₂₀ heterocyclyl), 2 to 12 ring carbon atoms (i.e., C₂-C₁₂ heterocyclyl), 2 to 10 ring carbon atoms (i.e., C₂-C₁₀ heterocyclyl), 2 to 8 ring carbon atoms (i.e., C₂-C₈ heterocyclyl), 3 to 12 ring carbon atoms (i.e., C₃-C₁₂ heterocyclyl), 3 to 8 ring carbon atoms (i.e., C₃-C₈ heterocyclyl), or 3 to 6 ring carbon atoms (i.e., C₃-C₆ heterocyclyl); having 1 to 5 ring heteroatoms, 1 to 4 ring heteroatoms, 1 to 3 ring heteroatoms, 1 to 2 ring heteroatoms, or 1 ring heteroatom independently selected from nitrogen, sulfur or oxygen. When the heterocycle ring contains 4- to 6-ring atoms, it is also referred to herein as a 4- to 6-membered heterocycle. Also disclosed herein are 5- or 6-membered heterocyclyls, having 5 or 6 ring atoms and 5- to 10-membered heterocyclyls have 5- to 10-ring atoms. Examples of heterocyclyl groups include, e.g., azetidinyl, azepinyl, benzodioxolyl, benzo[b][1,4]dioxepinyl, 1,4-benzodioxanyl, benzopyranyl, benzodioxinyl, benzopyranonyl, benzofuranonyl, dioxolanyl, dihydropyranyl, hydropyranyl, thienyl[1,3]dithianyl, decahydroisoquinolyl, furanonyl, imidazolinyl, imidazolidinyl, indolinyl, indolizinyl, isoindolinyl, isothiazolidinyl, isoxazolidinyl, morpholinyl, octahydroindolyl, octahydroisoindolyl, 2-oxopiperazinyl, 2-oxopiperidinyl, 2-oxopyrrolidinyl, oxazolidinyl, oxiranyl, oxetanyl, phenothiazinyl, phenoxazinyl, piperidinyl, piperazinyl, 4-piperidonyl, pyrrolidinyl, pyrazolidinyl, quinuclidinyl, thiazolidinyl, tetrahydrofuryl, tetrahydropyranyl, trithianyl, tetrahydroquinolinyl, thiophenyl (i.e., thienyl), tetrahydropyranyl, thiomorpholinyl, thiamorpholinyl, 1-oxo-thiomorpholinyl and 1,1-dioxo-thiomorpholinyl. In certain embodiments, the term “heterocyclyl” can include “spiroheterocyclyl” when there are two positions for substitution on the same carbon atom. Examples of the spiro-heterocyclyl rings include, e.g., bicyclic and tricyclic ring systems, such as 2-oxa-7-azaspiro[3.5]nonanyl, 2-oxa-6-azaspiro[3.4]octanyl and 6-oxa-1-azaspiro[3.3]heptanyl. Examples of the fused-heterocyclyl rings include, but are not limited to, 1,2,3,4-tetrahydroisoquinolinyl, 4,5,6,7-tetrahydrothieno[2,3-c]pyridinyl, indolinyl and isoindolinyl, where the heterocyclyl can be bound via either ring of the fused system.

“Heterocyclylalkyl” refers to the group “heterocyclyl-alkyl-.”

“Oxo” refers to the group (═O).

The terms “optional” or “optionally” means that the subsequently described event or circumstance may or may not occur and that the description includes instances where said event or circumstance occurs and instances in which it does not. Also, the term “optionally substituted” refers to any one or more (e.g., 1 to 5, 1 to 4, or 1 to 3) hydrogen atoms on the designated atom or group may or may not be replaced by a moiety other than hydrogen.

The term “substituted” used herein means any of the above groups (i.e., alkyl, alkenyl, alkynyl, alkylene, alkoxy, haloalkyl, haloalkoxy, cycloalkyl, aryl, heterocyclyl, heteroaryl, and/or heteroalkyl) wherein at least one (e.g., 1 to 5, 1 to 4, or 1 to 3) hydrogen atom is replaced by a bond to a non-hydrogen atom such as, but not limited to alkyl, alkenyl, alkynyl, alkoxy, alkylthio, acyl, amido, amino, amidino, aryl, aralkyl, azido, carbamoyl, carboxyl, carboxyl ester, cyano, cycloalkyl, cycloalkylalkyl, guanidino, halo, haloalkyl, haloalkoxy, hydroxyalkyl, heteroalkyl, heteroaryl, heteroarylalkyl, heterocyclyl, heterocyclylalkyl, —NHNH₂, ═NNH₂, imino, imido, hydroxy, oxo, oxime, nitro, sulfonyl, sulfinyl, alkylsulfonyl, alkylsulfinyl, thiocyanate, —S(O)OH, —S(O)₂OH, sulfonamido, thiol, thioxo, N-oxide or —Si(R^{y})₃, wherein each R^{y} is independently hydrogen, alkyl, alkenyl, alkynyl, heteroalkyl, cycloalkyl, aryl, heteroaryl or heterocyclyl.

In certain embodiments, “substituted” includes any of the above alkyl, alkenyl, alkynyl, cycloalkyl, heterocyclyl, aryl or heteroaryl groups in which one or more (e.g., 1 to 5, 1 to 4, or 1 to 3) hydrogen atoms are independently replaced with deuterium, halo, cyano, nitro, azido, oxo, alkyl, alkenyl, alkynyl, haloalkyl, cycloalkyl, heterocyclyl, aryl, heteroaryl, —NR^{g}R^{h}, —NR^{g}C(═O)R^{h}, —NR^{g}C(═O)NR^{g}R^{h}, —NR^{g}C(═O)OR^{h}, —NR^{g}S(═O)₁₋₂R^{h}, —C(═O)R^{g}, —C(═O)OR^{g}, —OC(═O)OR^{g}, —OC(═O)R^{g}, —C(═O)NR^{g}R^{h}, —OC(═O)NR^{g}R^{h}, —OR^{g}, —SR^{g}, —S(═O)R^{g}, —S(═O)₂R^{g}, —OS(═O)₁₋₂R^{g}, —S(═O)₁₋₂OR^{g}, —NR^{g}S(═O)₁₋₂NR^{g}R^{h}, ═NSO₂R^{g}, ═NOR^{g}, —S(═O)₁₋₂NR^{g}R^{h}, —SF₅, —SCF₃ or —OCF₃. In certain embodiments, “substituted” also means any of the above groups in which one or more (e.g., 1 to 5, 1 to 4, or 1 to 3) hydrogen atoms are replaced with —C(═O)R^{g}, —C(═O)OR^{g}, —C(═O)NR^{g}R^{h}, —CH₂SO₂R^{g}, or —CH₂SO₂NR^{g}R^{h}. In the foregoing, R^{g} and R^{h} are the same or different and independently hydrogen, alkyl, alkenyl, alkynyl, alkoxy, thioalkyl, aryl, aralkyl, cycloalkyl, cycloalkylalkyl, haloalkyl, heterocyclyl, heterocyclylalkyl, heteroaryl, and/or heteroarylalkyl. In certain embodiments, “substituted” also means any of the above groups in which one or more (e.g., 1 to 5, 1 to 4, or 1 to 3) hydrogen atoms are replaced by a bond to an amino, cyano, hydroxyl, imino, nitro, oxo, thioxo, halo, alkyl, alkoxy, alkylamino, thioalkyl, aryl, aralkyl, cycloalkyl, cycloalkylalkyl, haloalkyl, heterocyclyl, N-heterocyclyl, heterocyclylalkyl, heteroaryl, and/or heteroarylalkyl, or two of R^{g} and R^{h} and Rⁱ are taken together with the atoms to which they are attached to form a heterocyclyl ring optionally substituted with oxo, halo or alkyl optionally substituted with oxo, halo, amino, hydroxyl, or alkoxy.

### II. Polycrystalline Perovskite Films

In one aspect, the subject matter described herein is directed to a polycrystalline perovskite film, comprising:
a) a composition of Formula (I):

ABI_{3-y}X_{y} (I)
wherein A is a cation selected from the group consisting of methylammonium (MA), tetramethylammonium, formamidinium (FA), cesium (Cs), rubidium (Rb), potassium (K), sodium (Na), butylammonium (BA), phenethylammonium (PEA), phenylammonium (PA), guanidinium (GA), and a combination thereof;
B is a metal cation selected from the group consisting of lead, tin, calcium, cadmium, germanium, zinc, nickel, platinum, palladium, mercury, titanium, silicon, and a combination thereof;
X is selected from the group consisting of Cl⁻, Br⁻, F⁻, SCN⁻, and a combination thereof;
and
   y is between 0 and 3;
      and
b) a compound of Formula (II):

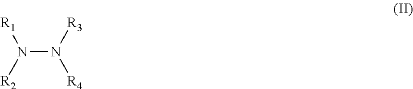

wherein, R₁, R₂, R₃, and R₄ are each independently selected from the group consisting of hydrogen, C₁-C₄₀ alkyl, C₂-C₄₀ alkenyl, C₂-C₄₀ alkynyl, aminoalkyl, C₆-C₁₂ aryl, C₃-C₇ cycloalkyl, 4- to 7-membered heterocyclyl, 5- to 10-membered heteroaryl, C₆-C₁₂ aryl-C₁-C₁₀ alkyl, C₃-C₇ cycloalkyl-C₁-C₁₀ alkyl, 4- to 7-membered heterocyclyl-C₁-C₁₀ alkyl, 5- to 10-membered heteroaryl-C₁-C₁₀ alkyl, and C₁-C₂₀ alkyl-thio-C₁-C₂₀ alkyl, each of which is optionally substituted one or more times with a substituent, each independently selected from the group consisting of halogen, cyano, hydrazino, C₁-C₂₀ alkyl, amino, C₁-C₂₀ alkoxy, C₂-C₂₀ alkenyl, C₂-C₂₀ alkynyl, C₆-C₁₂ aryl, C₃-C₇ cycloalkyl, 4- to 7-membered heterocyclyl, and 5- to 10-membered heteroaryl;
wherein one or more carbon atoms in said “alkyl” of C₁-C₄₀ alkyl, aminoalkyl, C₆-C₁₂ aryl-C₁-C₁₀ alkyl, C₃-C₇ cycloalkyl-C₁-C₁₀ alkyl, 4- to 7-membered heterocyclyl-C₁-C₁₀ alkyl, 5- to 10-membered heteroaryl-C₁-C₁₀ alkyl, or C₁-C₂₀ alkyl-thio-C₁-C₂₀ alkyl are optionally:
   i. replaced with O or S; and/or
   ii. substituted with (═O);
or, a salt thereof;
   provided that when B is tin, said compound of Formula (II), or salt thereof, is other than hydrazinium chloride or 4-fluorobenzohydrazide.

In certain embodiments of the polycrystalline film, A comprises an ammonium, an organic cation of the general formula [NR₄]⁺ where the R groups can be the same or different groups. Suitable R groups include, but are not limited to: methyl, ethyl, propyl, butyl, pentyl group or isomer thereof, any alkane, alkene, or alkyne CₓH_{y}, where x=1-20, y=1-42, cyclic, branched or straight-chain; alkyl halides, CₓH_{y}X_{z}, x=1-20, y=0-42, z=1-42, X═F, Cl, Br, or I; any aromatic group (e.g., phenyl, alkylphenyl, alkoxyphenyl, pyridine, naphthalene); cyclic complexes where at least one nitrogen is contained within the ring (e.g., pyridine, pyrrole, pyrrolidine, piperidine, tetrahydroquinoline); any sulfur-containing group (e.g., sulfoxide, thiol, alkyl sulfide); any nitrogen-containing group (nitroxide, amine); any phosphorous containing group (phosphate); any boron-containing group (e.g., boronic acid); any organic acid (e.g., acetic acid, propanoic acid); and ester or amide derivatives thereof, any amino acid (e.g., glycine, cysteine, proline, glutamic acid, arginine, serine, histindine, 5-ammoniumvaleric acid) including alpha, beta, gamma, and greater derivatives; any silicon containing group (e.g., siloxane); and any alkoxy or group, —OCₓH_{y}, where x=0-20, y=1-42. In certain embodiments, A comprises methylammonium, (CH₃NH₃⁺).

In certain embodiments of the perovskite film, A comprises a formamidinium, an organic cation of the general formula [R₂NCHNR₂]⁺ where the R groups can be the same or different groups. Suitable R groups include, but are not limited to: hydrogen, methyl, ethyl, propyl, butyl, pentyl or an isomer thereof; any alkane, alkene, or alkyne CₓH_{y}, where x=1-20, y=1-42, cyclic, branched or straight-chain; alkyl halides, CₓH_{y}X_{z}, x=1-20, y=0-42, z=1-42, X═F, Cl, Br, or I; any aromatic group (e.g., phenyl, alkylphenyl, alkoxyphenyl, pyridine, naphthalene); cyclic complexes where at least one nitrogen is contained within the ring (e.g., imidazole, benzimidazole, dihydropyrimidine, (azolidinylidenemethyl)pyrrolidine, triazole); any sulfur-containing group (e.g., sulfoxide, thiol, alkyl sulfide); any nitrogen-containing group (nitroxide, amine); any phosphorous containing group (phosphate); any boron-containing group (e.g., boronic acid); any organic acid (acetic acid, propanoic acid) and ester or amide derivatives thereof, any amino acid (e.g., glycine, cysteine, proline, glutamic acid, arginine, serine, histindine, 5-ammoniumvaleric acid) including alpha, beta, gamma, and greater derivatives; any silicon containing group (e.g., siloxane); and any alkoxy or group, OCₓH_{y}, where x=0-20, y=1-42. In certain embodiments A comprises a formamidinium ion represented by (H₂N═CH—NH₂⁺).

In certain embodiments of the perovskite film, A comprises a guanidinium, an organic cation of the general formula [(R₂N)₂C═NR₂]⁺ where the R groups can be the same or different groups. Suitable R groups include, but are not limited to: hydrogen, methyl, ethyl, propyl, butyl, pentyl group or isomer thereof; any alkane, alkene, or alkyne CₓH_{y}, where x=1-20, y=1-42, cyclic, branched or straight-chain; alkyl halides, CₓH_{y}X_{z}, x=1-20, y=0-42, z=1-42, X═F, Cl, Br, or I; any aromatic group (e.g., phenyl, alkylphenyl, alkoxyphenyl, pyridine, naphthalene); cyclic complexes where at least one nitrogen is contained within the ring (e.g., octahydropyrimido[1,2-a]pyrimidine, pyrimido[1,2-a]pyrimidine, hexahydroimidazo[1,2-a]imidazole, hexahydropyrimidin-2-imine); any sulfur-containing group (e.g., sulfoxide, thiol, alkyl sulfide); any nitrogen-containing group (nitroxide, amine); any phosphorous containing group (phosphate); any boron-containing group (e.g., boronic acid); any organic acid (acetic acid, propanoic acid) and ester or amide derivatives thereof, any amino acid (e.g., glycine, cysteine, proline, glutamic acid, arginine, serine, histindine, 5-ammoniumvaleric acid) including alpha, beta, gamma, and greater derivatives; any silicon containing group (e.g., siloxane); and any alkoxy or group, —OCₓH_{y}, where x=0-20, y=1-42. In certain embodiments, A comprises a guanidinium ion of the type (H₂N═C(NH₂)₂⁺).

In certain embodiments of the perovskite film, A comprises an alkali metal cation, such as Li⁺, Na⁺, K⁺, Rb⁺, or Cs⁺.

In certain embodiments of the perovskite film, the perovskite crystal structure composition may be substituted (e.g., by partial substitution of the cation A and/or the metal B) with another element, which may be, for example, an alkali metal (e.g., Li⁺, Na⁺, K⁺, Rb⁺, or Cs⁺), an alkaline earth metal (e.g., Mg⁺², Ca⁺², Sr⁺², Ba⁺²) or other divalent metal, such as provided below for B, but different from B (e.g., Sn⁺², Pb²⁺, Zn⁺², Cd⁺², Ge⁺², Ni⁺², Pt⁺², Pd⁺², Hg⁺², Si⁺², Ti⁺²), or a Group 15 element, such as Sb, Bi, As, or P, or other metals, such as silver, copper, gallium, indium, thallium, molybdenum, or gold, typically in an amount of up to or less than about 1, 5, 10, 20, 25, 30, 35, 40, 45, 50, 55, 60, 65, 70, 75, 80, 85, 90, 95, 99, or 100 mol % of A or B. A may comprise a mixture of cations. B may comprise a mixture of cations.

In certain embodiments of the perovskite film, B comprises at least one divalent (B⁺²) metal atom. The divalent metal (B) can be, for example, one or more divalent elements from Group 14 of the Periodic Table (e.g., divalent lead, tin, or germanium), one or more divalent transition metal elements from Groups 3-12 of the Periodic Table (e.g., divalent titanium, vanadium, chromium, manganese, iron, cobalt, nickel, copper, zinc, palladium, platinum, and cadmium), and/or one or more divalent alkaline earth elements (e.g., divalent magnesium, calcium, strontium, and barium).

In certain embodiments of the perovskite film, the variable X is independently selected from one or a combination of halide atoms, wherein the halide atom (X) may be, for example, fluoride (F⁻), chloride (Cl⁻), bromide (Br⁻), and/or iodide (I⁻). In embodiments, the variable X comprises iodide.

In certain embodiments of the perovskite film, y in said composition of Formula (I) is 0. In certain embodiments of the perovskite film, y in said composition of Formula (I) is 0.2, 0.5, 0.7, 0.9, 1.0, 1.3, 1.5, 1.7, 2.0, 2.3, 2.5, or 2.7. In certain embodiments of the polycrystalline film, A in said composition of Formula (I) is selected from the group consisting of Cs, MA, FA, and a combination thereof. In certain embodiments of the polycrystalline film, B is lead. In certain embodiments of the polycrystalline film, the composition of Formula (I) is Cs_{z}MA_{1-x-z}FAₓPbI₃, wherein x and z are between 0 and 1, provided that the sum of x and z does not exceed 1. In certain embodiments of the polycrystalline film, z is selected from the group consisting of 0, 0.05, 0.08, 0.09, 0.10, 0.12, and 0.15; and x is selected from the group consisting of 0, 0.2, 0.3, 0.4, and 0.5. In certain embodiments, x and z are each independently selected from the group consisting of 0, 0.1, 0.2, 0.3, 0.4, 0.5, 0.6, 0.7, 0.8, 0.9, and 1.0. In certain embodiments of the polycrystalline film, x is 0.3 and z is 0 or x is 0.92 and z is 0.08. In certain embodiments of the polycrystalline film, the composition of Formula (I) is MA_{0.7}FA_{0.3}PbI₃. In certain embodiments of the polycrystalline perovskite film, said compound of Formula (II), or salt thereof is other than hydrazinium chloride or 4-fluorobenzohydrazide.

In certain embodiments of the polycrystalline film, R₃ and R₄ are each hydrogen, R₁ is hydrogen, and R₂ is selected from the group consisting of C₁-C₄₀ alkyl, C₂-C₄₀ alkenyl, C₂-C₄₀ alkynyl, aminoalkyl, C₆-C₁₂ aryl, C₃-C₇ cycloalkyl, C₃-C₇ heterocyclyl, C₅-C₁₂ heteroaryl, C₆-C₁₂ aryl-C₁-C₁₀ alkyl, C₃-C₇ cycloalkyl-C₁-C₁₀ alkyl, C₃-C₇ heterocyclyl-C₁-C₁₀ alkyl, C₅-C₁₂ heteroaryl-C₁-C₁₀ alkyl, and C₁-C₂₀ alkyl-thio-C₁-C₂₀ alkyl, each of which is optionally substituted one or more times with a substituent, each independently selected from the group consisting of halogen, cyano, hydrazino, C₁-C₂₀ alkyl, amino, C₁-C₂₀ alkoxy, C₂-C₂₀ alkenyl, C₂-C₂₀ alkynyl, C₆-C₁₂ aryl, C₃-C₇ cycloalkyl, C₃-C₇ heterocyclyl, and C₅-C₁₂ heteroaryl;
wherein one or more carbon atoms in said “alkyl” of C₁-C₄₀ alkyl, aminoalkyl, C₆-C₁₂ aryl-C₁-C₁₀ alkyl, C₃-C₇ cycloalkyl-C₁-C₁₀ alkyl, C₃-C₇ heterocyclyl-C₁-C₁₀ alkyl, C₅-C₁₂ heteroaryl-C₁-C₁₀ alkyl, C₁-C₂₀ alkyl-thio-C₁-C₂₀ alkyl are optionally:
i. replaced with O or S; and/or
ii. substituted with (═O).

In certain embodiments of the polycrystalline film, in the compound or salt of Formula (II), R₂ is C₁-C₁₀ alkyl optionally substituted with hydrazino, wherein one of more carbon atoms in C₁-C₁₀ alkyl are substituted with (═O). In certain embodiments, R₂ is C₁ alkyl, substituted with (═O) and hydrazino. In certain embodiments, R₂ is

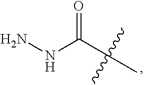 [SMILES: *C(=O)NN]

and R₁, R₄, and R₃ are each hydrogen. In certain embodiments of the polycrystalline film, the compound of Formula (II) is

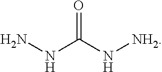

In certain embodiments of the polycrystalline film, in the compound or salt of Formula (II), R₂ is selected from the group consisting of C₁-C₁₀ alkyl, C₆-C₁₂ aryl-C₁-C₆ alkyl, and 5- to 10-membered heteroaryl-C₁-C₆ alkyl. In certain embodiments of the polycrystalline film, in the compound or salt of Formula (II), R₂ is C₆-C₁₂ aryl-C₁-C₆ alkyl. In certain embodiments of the polycrystalline film, in the compound or salt of Formula (II), R₂ is benzyl. In certain embodiments of the polycrystalline film, in the compound or salt of Formula (II), R₂ is C₁-C₁₀ alkyl. In certain embodiments of the polycrystalline film, in the compound or salt of Formula (II), R₂ is selected from the group consisting of methyl, ethyl, propyl, and butyl. In certain embodiments of the polycrystalline film, in the compound or salt of Formula (II), R₂ is propyl. In certain embodiments of the polycrystalline film, in the compound or salt of Formula (II), R₂ is 5- to 10-membered heteroaryl-C₁-C₆ alkyl. In certain embodiments of the polycrystalline film, in the compound or salt of Formula (II), R₂ is thiophene-methyl.

In certain embodiments of the polycrystalline film, the compound of Formula (II) is a salt. In certain embodiments of the polycrystalline film, wherein the compound of Formula (II) is a salt, the salt is

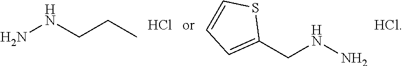

In certain embodiments of the polycrystalline film, wherein the compound of Formula (II) is a salt, the salt is

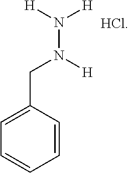

In certain embodiments of the polycrystalline film, the composition of Formula (I) is MA_{0.7}FA_{0.3}PbI₃ and the compound of Formula (II) or salt thereof is

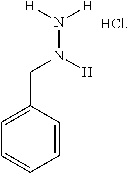

In certain embodiments of the polycrystalline film, the compound of Formula (II), or salt thereof, is present in a molar percent of about 0.01 to about 5 relative to said composition of Formula (I). In certain embodiments of the polycrystalline film, the compound of Formula (II), or salt thereof, is present in about 0.01 mol % to about 2 mol %, about 0.10 mol % to about 5 mol %, about 0.5 mol % to about 3 mol %, about 0.01 mol % to about 0.10 mol %, about 0.01 mol % to about 1.5 mol %, about 0.01 mol % to about 0.50 mol %, about 0.10 mol % to about 0.25 mol %, about 0.15 mol % to about 0.75 mol % about 0.15 mol % to about 1.0 mol %, about 0.50 mol % to about 2.0 mol %, about 0.50 mol % to about 1.0 mol %, about 0.35 mol % to about 0.75 mol %, about 0.50 mol % to about 1.50 mol %, about 0.80 mol % to about 1.25 mol %, about 1.0 mol % to about 2.0 mol %, about 0.65 mol % to about 2.0 mol %, or about 0.75 mol % to about 1.75 mol % relative to said composition of Formula (I). In certain embodiments of the polycrystalline film, the compound of Formula (II), or salt thereof, is present in about 0.05 mol %, 0.10 mol %, 0.15 mol %, 0.16 mol %, 0.17 mol %, 0.18 mol %, 0.19 mol %, 0.20 mol %, 0.21 mol %, 0.22 mol %, 0.23 mol %, 0.24 mol %, 0.25 mol %, 0.26 mol %, 0.27 mol %, 0.28 mol %, 0.29 mol %, 0.30 mol %, 0.31 mol %, 0.32 mol %, 0.33 mol %, 0.34 mol %, 0.35 mol %, 0.36 mol %, 0.37 mol %, 0.38 mol %, 0.39 mol %, 0.40 mol %, 0.41 mol %, 0.42 mol %, 0.43 mol %, 0.44 mol %, 0.45 mol %, 0.50 mol %, 0.6 mol %, 0.65 mol %, 0.7 mol %, 0.75 mol %, 0.8 mol %, 0.85 mol %, 0.9. mol %, 0.95 mol %, 1.0 mol %, 1.05 mol %, 1.10 mol %, 1.15 mol %, 1.20 mol %, 1.25 mol %, 1.30 mol %, 1.35 mol %, 1.40 mol %, 1.45 mol %, 1.50 mol %, 1.55 mol %, 1.60 mol %, 1.65 mol %, 1.70 mol %, 1.75 mol %, 1.80 mol %, 1.85 mol %, 1.90 mol %, 1.95 mol %, 2.0 mol %, 2.5 mol %, 3 mol %, 3.5 mol %, 4 mol %, 4.5 mol %, or 5.0 mol % relative to said composition of Formula (I).

In certain embodiments of the polycrystalline film, the film has an area of at least 0.01 cm². In certain embodiments of the polycrystalline films, the film has an area of at least 0.02 cm², 0.03 cm², 0.04 cm², 0.05 cm², 0.06 cm², 0.07 cm², 0.08 cm², 0.09 cm², 0.10 cm², 0.50 cm², 0.75 cm², 1 cm², 2 cm², 3 cm², 4 cm², 5 cm², 7 cm², 10 cm², 12 cm² 15 cm², 17 cm², 20 cm², 22 cm², 25 cm², 26 cm², 27 cm², 28 cm², 29 cm², 30 cm², 31 cm², 32 cm², 33 cm², 34 cm², 35 cm², 36 cm², 37 cm², 38 cm², 39 cm², 40 cm², 41 cm² 42 cm², 43 cm², 44 cm², 45 cm² 50 cm², 55 cm², 60 cm², 75 cm², 80 cm², 81 cm², 82 cm², 83 cm², 84 cm², 85 cm², 86 cm², 87 cm², 88 cm², 89 cm², 90 cm², 95 cm², 100 cm² 125 cm², 150 cm², 200 cm², 225 cm², 250 cm², 275 cm², 300 cm², 325 cm², or 350 cm².

In certain embodiments, the polycrystalline film comprises a composition of Formula I of MA_{1-X}FA_{X}PbI₃, and a compound of Formula II having the structure,

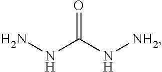

wherein x is 0, 0.1, 0.2, 0.3, 0.4, 0.5, or 0.6. In certain embodiments, x is 0.4. In certain embodiments, the compound of Formula II is present in the film at about 1-2 mol % relative to the composition of Formula I. In certain embodiments, the compound of Formula II is present in the film at about 1.5 mol % relative to the composition of Formula I. In certain embodiments, the perovskite film is characterized as having reduced interfacial voids.

In certain embodiments, the polycrystalline films described herein have a film thickness in the range of about 10 nm to about 1 cm. In certain embodiments, the polycrystalline films have a thickness of about 300 nm to about 1000 nm. In certain embodiments, the polycrystalline films have a thickness in the range of about 80 nm to about 300 nm. In certain embodiments, the polycrystalline films have a thickness in the range of about 0.1 mm to about 50 mm. In certain embodiments, the polycrystalline films have a thickness in the range of about 100 nm to about 1000 nm. In certain embodiments, the polycrystalline films have a film thickness of about, at least, above, up to, or less than, for example, 200 nm, 300 nm, 400 nm, 500 nm, 600 nm, 700 nm, 800 nm, 900 nm, 1000 nm (1 μm), 2 μm, 3 μm, 4 μm, 5 μm, 6 μm, 7 μm, 8 μm, 9 μm, or 10 μm.

In certain embodiments, the polycrystalline films described herein have an average grain size of about 10 nm to about 1 mm. In certain embodiments, the polycrystalline films have an average grain size of about, at least, or above 0.01 μm, 10 μm, 20 μm, 30 μm, 40 μm, 50 μm, 60 μm, 70 μm, 80 μm, 90 μm, 100 μm, 120 μm, 150 μm, 180 μm, 200 μm, 220 μm, 250 μm, 280 μm, 300 μm, 350 μm, 400 μm, 450 μm, 500 μm, 550 μm, 600 μm, 650 μm, 700 μm, 800 μm, 850 μm, 900 μm, 1000 μm, or an average grain size within a range bounded by any two of the foregoing exemplary values. It is generally known in the art that large grain sizes are suitable for films in photoactive or photovoltaic applications.

In certain embodiments, the polycrystalline perovskite films disclosed herein are characterized as having a reduced density of interfacial voids. As used herein, “interfacial voids” refers to vacancies that exist at or close to the interface between the perovskite layer and the ETL (electron transport layer), the perovskite layer and the HTL (hole transport layer), or between the perovskite layer and a substrate, such as ITO-coated glass or electrode (at the perovskite film surface up to a depth of about 40% of the film). The interfacial voids can accumulate charges and decomposition products in perovskite solar cells and modules. As disclosed herein, however, the addition of a compound of Formula II, such as carbohydrazide (CBH) to the perovskite precursor solution can significantly reduce the density of interfacial voids in the prepared perovskite films. This reduction in interfacial voids leads to enhanced solar cell or solar module performance. The polycrystalline perovskite films, produced using precursor solutions containing a Formula II additive, exhibit a reduction in interfacial voids of at least 10%, 20%, 30%, 40%, 50%, 60%, 70%, 80%, 90%, 95%, 96%, 97%, 98%, 99%, or 100% compared with perovskite films prepared without the Formula II additive.

### III. Oxidative-Resistant Perovskite Ink Solutions

In another aspect, the subject matter described herein is directed to an oxidative-resistant ink solution, comprising:
a) a composition of Formula (I):

ABI_{3-y}X_{y} (I)
wherein A is a cation selected from the group consisting of methylammonium (MA), tetramethylammonium, formamidinium (FA), cesium (Cs), rubidium (Rb), potassium (K), sodium (Na), butylammonium (BA), phenethylammonium (PEA), phenylammonium (PA), guanidinium (GA), and a combination thereof;
B is a metal cation selected from the group consisting of lead, tin, calcium, cadmium, germanium, zinc, nickel, platinum, palladium, mercury, titanium, silicon, and a combination thereof;
X is selected from the group consisting of Cl⁻, Br⁻, F⁻, SCN⁻, and a combination thereof;
and
   y is between 0 and 3;
b) one or more solvents;
   and
c) a compound of Formula (II):

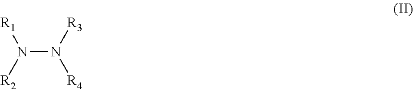

wherein, R₁, R₂, R₃, and R₄ are each independently selected from the group consisting of hydrogen, C₁-C₄₀ alkyl, C₂-C₄₀ alkenyl, C₂-C₄₀ alkynyl, aminoalkyl, C₆-C₁₂ aryl, C₃-C₇ cycloalkyl, 4- to 7-membered heterocyclyl, 5- to 10-membered heteroaryl, C₆-C₁₂ aryl-C₁-C₁₀ alkyl, C₃-C₇ cycloalkyl-C₁-C₁₀ alkyl, 4- to 7-membered heterocyclyl-C₁-C₁₀ alkyl, 5- to 10-membered heteroaryl-C₁-C₁₀ alkyl, and C₁-C₂₀ alkyl-thio-C₁-C₂₀ alkyl, each of which is optionally substituted one or more times with a substituent, each independently selected from the group consisting of halogen, cyano, hydrazino, C₁-C₂₀ alkyl, amino, C₁-C₂₀ alkoxy, C₂-C₂₀ alkenyl, C₂-C₂₀ alkynyl, C₆-C₁₂ aryl, C₃-C₇ cycloalkyl, 4- to 7-membered heterocyclyl, and 5- to 10-membered heteroaryl;
wherein one or more carbon atoms in said “alkyl” of C₁-C₄₀ alkyl, aminoalkyl, C₆-C₁₂ aryl-C₁-C₁₀ alkyl, C₃-C₇ cycloalkyl-C₁-C₁₀ alkyl, 4- to 7-membered heterocyclyl-C₁-C₁₀ alkyl, 5- to 10-membered heteroaryl-C₁-C₁₀ alkyl, or C₁-C₂₀ alkyl-thio-C₁-C₂₀ alkyl are optionally:
   i. replaced with O or S; and/or
   ii. substituted with (═O);
or, a salt thereof,
provided that when B is tin, said compound of Formula (II), or salt thereof, is other than hydrazinium chloride.

In certain embodiments of the oxidative-resistant ink solution, the compound of Formula (II), or salt thereof, is other than hydrazinium chloride or 4-fluorobenzohydrazide.

In certain embodiments of the oxidative-resistant ink solution, A comprises an ammonium, an organic cation of the general formula [NR₄]⁺ where the R groups can be the same or different groups. In certain embodiments, A comprises methylammonium, (CH₃NH₃⁺).

In certain embodiments of the oxidative-resistant ink solution, A comprises a formamidinium, an organic cation of the general formula [R₂NCHNR₂]⁺ where the R groups can be the same or different groups. In certain embodiments A comprises a formamidinium ion represented by (H₂N═CH—NH₂⁺).

In certain embodiments of the oxidative-resistant ink solution, A comprises a guanidinium, an organic cation of the general formula [(R₂N)₂C═NR₂]⁺ where the R groups can be the same or different groups. In certain embodiments, A comprises a guanidinium ion of the type (H₂N═C—(NH₂)₂⁺).

In certain embodiments of the oxidative-resistant ink solution, A comprises an alkali metal cation, such as Li⁺, Na⁺, K⁺, Rb⁺, or Cs⁺.

In certain embodiments of the oxidative-resistant ink solution, the perovskite crystal structure composition may be substituted (e.g., by partial substitution of the cation A and/or the metal B) with another element, which may be, for example, an alkali metal (e.g., Li⁺, Na⁺, K⁺, Rb⁺, or Cs⁺), an alkaline earth metal (e.g., Mg⁺², Ca⁺², Sr⁺², Ba⁺²) or other divalent metal, such as provided below for B, but different from B (e.g., Sn⁺², Pb²⁺ Zn⁺², Cd⁺², Ge⁺², Ni⁺², Pt⁺², Pd⁺², Hg⁺², Si⁺², Ti⁺²), or a Group 15 element, such as Sb, Bi, As, or P, or other metals, such as silver, copper, gallium, indium, thallium, molybdenum, or gold, typically in an amount of up to or less than about 1, 5, 10, 20, 25, 30, 35, 40, 45, 50, 55, 60, 65, 70, 75, 80, 85, 90, 95, 99, or 100 mol % of A or B. A may comprise a mixture of cations. B may comprise a mixture of cations.

In certain embodiments of the oxidative-resistant ink solution, B comprises at least one divalent (B⁺²) metal atom. The divalent metal (B) can be, for example, one or more divalent elements from Group 14 of the Periodic Table (e.g., divalent lead, tin, or germanium), one or more divalent transition metal elements from Groups 3-12 of the Periodic Table (e.g., divalent titanium, vanadium, chromium, manganese, iron, cobalt, nickel, copper, zinc, palladium, platinum, and cadmium), and/or one or more divalent alkaline earth elements (e.g., divalent magnesium, calcium, strontium, and barium).

In certain embodiments of the oxidative-resistant ink solution, the variable X is independently selected from one or a combination of halide atoms, wherein the halide atom (X) may be, for example, fluoride (F⁻), chloride (Cl⁻), bromide (Br⁻), and/or iodide (I⁻). In embodiments, the variable X comprises iodide.

In certain embodiments of the oxidative-resistant ink solution, y in said composition of Formula (I) is 0. In certain embodiments of the perovskite film, y in said composition of Formula (I) is 0.2, 0.5, 0.7, 0.9, 1.0, 1.3, 1.5, 1.7, 2.0, 2.3, 2.5, or 2.7. In certain embodiments of the oxidative-resistant ink solution, A in said composition of Formula (I) is selected from the group consisting of Cs, MA, FA, and a combination thereof. In certain embodiments of the oxidative-resistant ink solution, B is lead. In certain embodiments of the oxidative-resistant ink solution, the composition of Formula (I) is Cs_{z}MA_{1-x-z}FAₓPbI₃, wherein x and z are between 0 and 1, provided that the sum of x and z does not exceed 1. In certain embodiments of the oxidative-resistant ink solution, z is selected from the group consisting of 0, 0.05, 0.08, 0.09, 0.10, 0.12, and 0.15; and x is selected from the group consisting of 0, 0.2, 0.3, 0.4, and 0.5. In certain embodiments, x and z are each independently selected from the group consisting of 0, 0.1, 0.2, 0.3, 0.4, 0.5, 0.6, 0.7, 0.8, 0.9, and 1.0. In certain embodiments of the oxidative-resistant ink solution, x is 0.3 and z is 0 or x is 0.92 and z is 0.08. In certain embodiments of the oxidative-resistant ink solution, the composition of Formula (I) is MA_{0.7}FA_{0.3}PbI₃. In certain embodiments of the oxidative-resistant ink solution, said compound of Formula (II), or salt thereof is other than hydrazinium chloride or 4-fluorobenzohydrazide.

In certain embodiments of the oxidative-resistant ink solution, the compound or salt of Formula (II) is a compound of Formula (IIa):

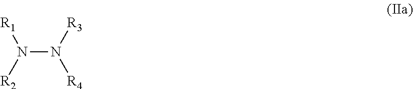

wherein, R₁, R₂, R₃, and R₄ are each independently selected from the group consisting of hydrogen, C₁-C₄₀ alkyl, C₂-C₄₀ alkenyl, C₂-C₄₀ alkynyl, C₆-C₁₂ aryl, C₃-C₇ cycloalkyl, 4- to 7-membered heterocyclyl, 5- to 10-membered heteroaryl, C₆-C₁₂ aryl-C₁-C₁₀ alkyl, C₃-C₇ cycloalkyl-C₁-C₁₀ alkyl, 4- to 7-membered heterocyclyl-C₁-C₁₀ alkyl, 5- to 10-membered heteroaryl-C₁-C₁₀ alkyl, and C₁-C₂₀ alkyl-thio-C₁-C₂₀ alkyl, each of which is optionally substituted one or more times with a substituent, each independently selected from the group consisting of halogen, cyano, C₁-C₂₀ alkyl, C₁-C₂₀ alkoxy, C₂-C₂₀ alkenyl, C₂-C₂₀ alkynyl, C₆-C₁₂ aryl, C₃-C₇ cycloalkyl, 4- to 7-membered heterocyclyl, and 5- to 10-membered heteroaryl;
wherein one or more carbon atoms in said “alkyl” of C₁-C₄₀ alkyl, C₆-C₁₂ aryl-C₁-C₁₀ alkyl, C₃-C₇ cycloalkyl-C₁-C₁₀ alkyl, 4- to 7-membered heterocyclyl-C₁-C₁₀ alkyl, 5- to 10-membered heteroaryl-C₁-C₁₀ alkyl, or C₁-C₂₀ alkyl-thio-C₁-C₂₀ alkyl are optionally:
   i. replaced with O or S; and/or
   ii. substituted with (═O);

In certain embodiments of the oxidative-resistant ink solution, in the compound or salt of Formula (II) or Formula (IIa), R₃ and R₄ are each hydrogen, R₁ is hydrogen, and R₂ is selected from the group consisting of C₁-C₄₀ alkyl, C₂-C₄₀ alkenyl, C₂-C₄₀ alkynyl, aminoalkyl, C₆-C₁₂ aryl, C₃-C₇ cycloalkyl, 4- to 7-membered heterocyclyl, 5- to 7-membered heteroaryl, C₆-C₁₂ aryl-C₁-C₁₀ alkyl, C₃-C₇ cycloalkyl-C₁-C₁₀ alkyl, 4- to 7-membered heterocyclyl-C₁-C₁₀ alkyl, 5- to 10-membered heteroaryl-C₁-C₁₀ alkyl, and C₁-C₂₀ alkyl-thio-C₁-C₂₀ alkyl, each of which is optionally substituted one or more times with a substituent, each independently selected from the group consisting of halogen, cyano, hydrazino, C₁-C₂₀ alkyl, amino, C₁-C₂₀ alkoxy, C₂-C₂₀ alkenyl, C₂-C₂₀ alkynyl, C₆-C₁₂ aryl, C₃-C₇ cycloalkyl, 4- to 7-membered heterocyclyl, and 5- to 10-membered heteroaryl;
wherein one or more carbon atoms in said “alkyl” of C₁-C₄₀ alkyl, aminoalkyl, C₆-C₁₂ aryl-C₁-C₁₀ alkyl, C₃-C₇ cycloalkyl-C₁-C₁₀ alkyl, 4- to 7-membered heterocyclyl-C₁-C₁₀ alkyl, 5- to 10-membered heteroaryl-C₁-C₁₀ alkyl, C₁-C₂₀ alkyl-thio-C₁-C₂₀ alkyl are optionally:
i. replaced with O or S; and/or
ii. substituted with (═O).

In certain embodiments of the oxidative-resistant ink solution, the compound or salt of Formula (II) is a compound of Formula (IIb):

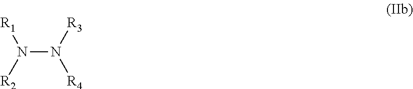

wherein, R₁, R₂, R₃, and R₄ are each independently selected from the group consisting of hydrogen, C₁-C₄₀ alkyl, C₂-C₄₀ alkenyl, C₂-C₄₀ alkynyl, aminoalkyl, C₆-C₁₂ aryl, C₃-C₇ cycloalkyl, 4- to 7-membered heterocyclyl, 5- to 10-membered heteroaryl, each of which is optionally substituted one or more times with a substituent, each independently selected from the group consisting of halogen, cyano, hydrazino, C₁-C₂₀ alkyl, amino, C₁-C₂₀ alkoxy, C₂-C₂₀ alkenyl, C₂-C₂₀ alkynyl, C₆-C₁₂ aryl, C₃-C₇ cycloalkyl, 4- to 7-membered heterocyclyl, and 5- to 10-membered heteroaryl;
wherein one or more carbon atoms in said “alkyl” of C₁-C₄₀ alkyl, aminoalkyl, C₆-C₁₂ aryl-C₁-C₁₀ alkyl, C₃-C₇ cycloalkyl-C₁-C₁₀ alkyl, 4- to 7-membered heterocyclyl-C₁-C₁₀ alkyl, 5- to 10-membered heteroaryl-C₁-C₁₀ alkyl, or C₁-C₂₀ alkyl-thio-C₁-C₂₀ alkyl are optionally:
i. replaced with O or S; and/or
ii. substituted with (═O);

In certain embodiments of the oxidative-resistant ink solution, in the compound or salt of Formula (II) or Formula (IIb), R₂ is C₁-C₁₀ alkyl optionally substituted with hydrazino, wherein one of more carbon atoms in C₁-C₁₀ alkyl are substituted with (═O). In certain embodiments, R₂ is C₁ alkyl, substituted with (═O) and hydrazino. In certain embodiments, R₂ is

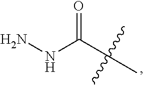 [SMILES: *C(=O)NN]

and R₁, R₄, and R₃ are each hydrogen. In certain embodiments of the oxidative-resistant ink solution, the compound of Formula (II) or Formula (IIb) is

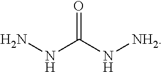

In certain embodiments of the oxidative-resistant ink solution, in the compound or salt of Formula (II), R₂ is selected from the group consisting of C₁-C₁₀ alkyl, C₆-C₁₂ aryl-C₁-C₆ alkyl, and 5- to 10-membered heteroaryl-C₁-C₆ alkyl. In certain embodiments of the oxidative-resistant ink solution, in the compound or salt of Formula (II), R₂ is C₆-C₁₂ aryl-C₁-C₆ alkyl. In certain embodiments of the oxidative-resistant ink solution, in the compound or salt of Formula (II), R₂ is benzyl. In certain embodiments of the oxidative-resistant ink solution, in the compound or salt of Formula (II), R₂ is C₁-C₁₀ alkyl. In certain embodiments of the oxidative-resistant ink solution, in the compound or salt of Formula (II), R₂ is selected from the group consisting of methyl, ethyl, propyl, and butyl. In certain embodiments of the oxidative-resistant ink solution, in the compound or salt of Formula (II), R₂ is propyl. In certain embodiments of the oxidative-resistant ink solution, in the compound or salt of Formula (II), R₂ is 5- to 10-membered heteroaryl-C₁-C₆ alkyl. In certain embodiments of the oxidative-resistant ink solution, in the compound or salt of Formula (II), R₂ is thiophene-methyl.

In certain embodiments of the oxidative-resistant ink solution, the compound of Formula (II) is a salt. In certain embodiments of the oxidative-resistant ink solution. wherein the compound of Formula (II) is a salt, the salt is

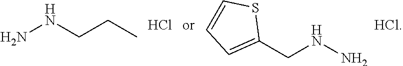

In certain embodiments of the oxidative-resistant ink solution, wherein the compound of Formula (II) is a salt, the salt is

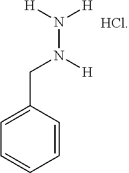

In certain embodiments of the oxidative-resistant ink solution, the composition of Formula (I) is MA_{0.7}FA_{0.3}PbI₃ and the compound of Formula (II) or salt thereof is

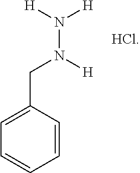

In certain embodiments of the oxidative-resistant ink solution, the solution contains a compound of Formula (I) and one or more compounds of Formula (II). In certain embodiments of the oxidative-resistant ink solution, the compound of Formula (I) is MA_{0.6}FA_{0.4}PbI₃, and the compounds of Formula (II) are

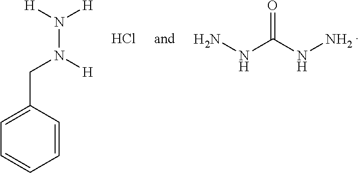 [SMILES: NNCc1ccccc1 ; Cl ; "and" ; NNC(=O)NN ; "."]

In certain embodiments of the oxidative-resistant ink solution, the compound of Formula (II), or salt thereof, is present in said ink solution in a molar percent of about 0.01 to about 5 relative to said composition of Formula (I). In certain embodiments of the oxidative-resistant ink solution, the compound of Formula (II), or salt thereof, is present in about 0.01 mol % to about 2 mol %, about 0.10 mol % to about 5 mol %, about 0.5 mol % to about 3 mol %, about 0.01 mol % to about 0.10 mol %, about 0.01 mol % to about 1.5 mol %, about 0.01 mol % to about 0.50 mol %, about 0.10 mol % to about 0.25 mol %, about 0.15 mol % to about 0.75 mol % about 0.15 mol % to about 1.0 mol %, about 0.50 mol % to about 2.0 mol %, about 0.50 mol % to about 1.0 mol %, about 0.35 mol % to about 0.75 mol %, about 0.50 mol % to about 1.50 mol %, about 0.80 mol % to about 1.25 mol %, about 1.0 mol % to about 2.0 mol %, about 0.65 mol % to about 2.0 mol %, or about 0.75 mol % to about 1.75 mol % relative to said composition of Formula (I) in said ink solution. In certain embodiments of the oxidative-resistant ink solution, the compound of Formula (II), or salt thereof, is present in about 0.05 mol %, 0.10 mol %, 0.15 mol %, 0.16 mol %, 0.17 mol %, 0.18 mol %, 0.19 mol %, 0.20 mol %, 0.21 mol %, 0.22 mol %, 0.23 mol %, 0.24 mol %, 0.25 mol %, 0.26 mol %, 0.27 mol %, 0.28 mol %, 0.29 mol %, 0.30 mol %, 0.31 mol %, 0.32 mol %, 0.33 mol %, 0.34 mol %, 0.35 mol %, 0.36 mol %, 0.37 mol %, 0.38 mol %, 0.39 mol %, 0.40 mol %, 0.41 mol %, 0.42 mol %, 0.43 mol %, 0.44 mol %, 0.45 mol %, 0.50 mol %, 0.6 mol %, 0.65 mol %, 0.7 mol %, 0.75 mol %, 0.8 mol %, 0.85 mol %, 0.9. mol %, 0.95 mol %, 1.0 mol %, 1.05 mol %, 1.10 mol %, 1.15 mol %, 1.20 mol %, 1.25 mol %, 1.30 mol %, 1.35 mol %, 1.40 mol %, 1.45 mol %, 1.50 mol %, 1.55 mol %, 1.60 mol %, 1.65 mol %, 1.70 mol %, 1.75 mol %, 1.80 mol %, 1.85 mol %, 1.90 mol %, 1.95 mol %, 2.0 mol %, 2.5 mol %, 3 mol %, 3.5 mol %, 4 mol %, 4.5 mol %, or 5.0 mol % in said ink solution relative to said composition of Formula (I).

In certain embodiments of the oxidative-resistant ink solution, the ink solution comprises one of more solvents selected from the group consisting of dimethylformamide, dimethyl sulfoxide, acetonitrile, propionitrile, acetone, ethylacetate, methylene chloride, chloroform, methanol, ethanol, propanol, butanol, isopropanol, ethylene glycol, diethyl ether, glyme, diglyme, propylene carbonate, N-methyl-2-pyrrolidinone, γ-Butyrolactone (gamma-butyrolactone), tetrahydrofuran, benzene, toluene, decalin, hexamethylphosphoramide, pyridine, alkylpyridine, pyrrolidine, chlorobenzene, dichlorobenzene, dichloromethane, chloroform, water, carbon disulfide, supercritical carbon dioxide, carbon tetrachloride, 2-Methoxyethanol, and sulfuryl chloride fluoride. In certain embodiments, the ink solution comprises one or more solvents selected from the group consisting of dimethyl sulfoxide, dimethylformamide, γ-Butyrolactone, 2-Methoxyethanol, acetonitrile, methanol, ethanol, propanol, butanol, tetrahydrofuran, pyridine, alkylpyridine, water, pyrrolidine, chlorobenzene, dichlorobenzene, dichloromethane, and chloroform. In certain embodiments, the oxidative-resistant ink solution comprises one or more solvents selected from the group consisting of dimethyl sulfoxide, dimethylformamide, N-methyl-2-pyrrolidone, γ-butyrolactone, 2-methoxyethanol, and acetonitrile. In certain embodiments, the oxidative-resistant ink solution comprises one or more solvents selected from 2-methoxyethanol. In certain embodiments, the oxidative-resistant ink solution comprises 2-methoxyethanol and dimethyl sulfoxide, wherein the amount of dimethyl sulfoxide comprises about 0.5% v/v to about 5% v/v. In certain embodiments, the amount of dimethyl sulfoxide comprises about 1.5%, 1.6%, 1.7%, 1.8%, 1.9%, 2.0%, 2.1%, 2.2%, 2.3%, 2.4%, 2.5%, 2.6%, 2.7%, 2.8%, 2.9%, 3.0%, 3.1%, 3.2%, 3.3%, 3.4%, 3.5%, 3.6%, 3.7%, 3.8%, 3.9%, or 4% (each % v/v).

In certain embodiments, the oxidative resistant perovskite ink solution can contain one or more additional additives selected from the group consisting of n-dodecylammonium iodide (about 0.0 to about 10 mg/ml), L-α-phosphatidylcholine (about 0.0 to about 5 mg/ml), MAH₂PO₂ (about 0.0 to about 10 mg/ml), and 4-fluoro-phenylammonium iodide (p-F-PEAI) (about 0.0 to about 10 mg/ml).

In certain embodiments, the oxidative resistant perovskite ink solution has a vapor pressure in a range of about 5 to 100 kPa. In certain embodiments, oxidative resistant=ink solution has a vapor pressure in a range of about 2 to 80 kPa, about 5 to 70 kPa, about 10 to 60 kPa, about 15 to 50 kPa, about 20 to 40 kPa, about 25 to 40 kPa, about 5 to 15 kPa, about 7 to 10 kPa, about 10 to 20 kPa, or about 8 to 9 kPa.

### IV. Methods for Preparing the Ink Solutions

In certain embodiments, the subject matter described herein is directed to a method of preparing an oxidative-resistant ink solution, comprising:
contacting an ink solution comprising a composition of Formula (I) with a compound of Formula (II), or a salt thereof;

ABI_{3-y}X_{y} (I)
wherein A is a cation selected from the group consisting of methylammonium (MA), tetramethylammonium, formamidinium (FA), cesium (Cs), rubidium (Rb), potassium (K), sodium (Na), butylammonium (BA), phenethylammonium (PEA), phenylammonium (PA), guanidinium (GA), and a combination thereof;
B is a metal cation selected from the group consisting of lead, tin, calcium, cadmium, germanium, zinc, nickel, platinum, palladium, mercury, titanium, silicon, and a combination thereof;
X is selected from the group consisting of Cl⁻, Br⁻, F⁻, SCN⁻, and a combination thereof;
and
   y is between 0 and 3;

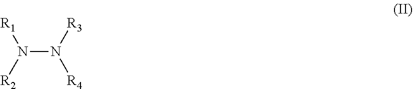

wherein, R₁, R₂, R₃, and R₄ are each independently selected from the group consisting of hydrogen, C₁-C₄₀ alkyl, C₂-C₄₀ alkenyl, C₂-C₄₀ alkynyl, aminoalkyl, C₆-C₁₂ aryl, C₃-C₇ cycloalkyl, 4- to 7-membered heterocyclyl, 5- to 10-membered heteroaryl, C₆-C₁₂ aryl-C₁-C₁₀ alkyl, C₃-C₇ cycloalkyl-C₁-C₁₀ alkyl, 4- to 7-membered heterocyclyl-C₁-C₁₀ alkyl, 5- to 10-membered heteroaryl-C₁-C₁₀ alkyl, and C₁-C₂₀ alkyl-thio-C₁-C₂₀ alkyl, each of which is optionally substituted one or more times with a substituent, each independently selected from the group consisting of halogen, cyano, hydrazino, C₁-C₂₀ alkyl, amino, C₁-C₂₀ alkoxy, C₂-C₂₀ alkenyl, C₂-C₂₀ alkynyl, C₆-C₁₂ aryl, C₃-C₇ cycloalkyl, 4- to 7-membered heterocyclyl, and 5- to 10-membered heteroaryl;
wherein one or more carbon atoms in said “alkyl” of C₁-C₄₀ alkyl, aminoalkyl, C₆-C₁₂ aryl-C₁-C₁₀ alkyl, C₃-C₇ cycloalkyl-C₁-C₁₀ alkyl, 4- to 7-membered heterocyclyl-C₁-C₁₀ alkyl, 5- to 10-membered heteroaryl-C₁-C₁₀ alkyl, or C₁-C₂₀ alkyl-thio-C₁-C₂₀ alkyl are optionally:
   i. replaced with O or S; and/or
   ii. substituted with (═O);
provided that when B is tin, said compound of Formula (II), or salt thereof, is other than hydrazinium chloride or 4-fluorobenzohydrazide, wherein said oxidative-resistant ink solution is prepared.

In certain embodiments of the above method, the compound of Formula (II), or salt thereof, is other than hydrazinium chloride or 4-fluorobenzohydrazide.

In certain embodiments, the subject matter described herein is directed to a method of reducing oxidation in an ink solution, comprising contacting an ink solution comprising a composition of Formula (I) with an oxidative reducing amount of a compound of Formula (II), or a salt thereof;

ABI_{3-y}X_{y} (I)
wherein A is a cation selected from the group consisting of methylammonium (MA), tetramethylammonium, formamidinium (FA), cesium (Cs), rubidium (Rb), potassium (K), sodium (Na), butylammonium (BA), phenethylammonium (PEA), phenylammonium (PA), guanidinium (GA), and a combination thereof;
B is a metal cation selected from the group consisting of lead, tin, calcium, cadmium, germanium, zinc, nickel, platinum, palladium, mercury, titanium, silicon, and a combination thereof;
X is selected from the group consisting of Cl⁻, Br⁻, F⁻, SCN⁻, and a combination thereof;
and
y is between 0 and 3.

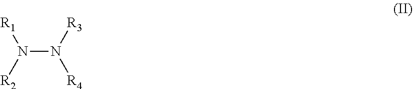

wherein, R₁, R₂, R₃, and R₄ are each independently selected from the group consisting of hydrogen, C₁-C₄₀ alkyl, C₂-C₄₀ alkenyl, C₂-C₄₀ alkynyl, aminoalkyl, C₆-C₁₂ aryl, C₃-C₇ cycloalkyl, 4- to 7-membered heterocyclyl, 5- to 10-membered heteroaryl, C₆-C₁₂ aryl-C₁-C₁₀ alkyl, C₃-C₇ cycloalkyl-C₁-C₁₀ alkyl, 4- to 7-membered heterocyclyl-C₁-C₁₀ alkyl, 5- to 10-membered heteroaryl-C₁-C₁₀ alkyl, and C₁-C₂₀ alkyl-thio-C₁-C₂₀ alkyl, each of which is optionally substituted one or more times with a substituent, each independently selected from the group consisting of halogen, cyano, hydrazino, C₁-C₂₀ alkyl, amino, C₁-C₂₀ alkoxy, C₂-C₂₀ alkenyl, C₂-C₂₀ alkynyl, C₆-C₁₂ aryl, C₃-C₇ cycloalkyl, 4- to 7-membered heterocyclyl, and 5- to 10-membered heteroaryl;
   wherein one or more carbon atoms in said “alkyl” of C₁-C₄₀ alkyl, aminoalkyl, C₆-C₁₂ aryl-C₁-C₁₀ alkyl, C₃-C₇ cycloalkyl-C₁-C₁₀ alkyl, 4- to 7-membered heterocyclyl-C₁-C₁₀ alkyl, 5- to 10-membered heteroaryl-C₁-C₁₀ alkyl, or C₁-C₂₀ alkyl-thio-C₁-C₂₀ alkyl are optionally:
      i. replaced with O or S; and/or
      ii. substituted with (═O);
provided that when B is tin, said compound of Formula (II), or salt thereof, is other than hydrazinium chloride or 4-fluorobenzohydrazide.

In certain embodiments of the above method, the compound of Formula (II), or salt thereof, is other than hydrazinium chloride or 4-fluorobenzohydrazide.

In certain embodiments of the above method, the compound or salt of Formula (II) is a compound of Formula (IIa):

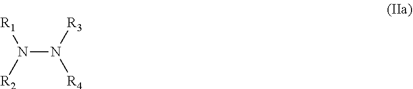

wherein, R₁, R₂, R₃, and R₄ are each independently selected from the group consisting of hydrogen, C₁-C₄₀ alkyl, C₂-C₄₀ alkenyl, C₂-C₄₀ alkynyl, C₆-C₁₂ aryl, C₃-C₇ cycloalkyl, 4- to 7-membered heterocyclyl, 5- to 10-membered heteroaryl, C₆-C₁₂ aryl-C₁-C₁₀ alkyl, C₃-C₇ cycloalkyl-C₁-C₁₀ alkyl, 4- to 7-membered heterocyclyl-C₁-C₁₀ alkyl, 5- to 10-membered heteroaryl-C₁-C₁₀ alkyl, and C₁-C₂₀ alkyl-thio-C₁-C₂₀ alkyl, each of which is optionally substituted one or more times with a substituent, each independently selected from the group consisting of halogen, cyano, C₁-C₂₀ alkyl, C₁-C₂₀ alkoxy, C₂-C₂₀ alkenyl, C₂-C₂₀ alkynyl, C₆-C₁₂ aryl, C₃-C₇ cycloalkyl, 4- to 7-membered heterocyclyl, and 5- to 10-membered heteroaryl;
wherein one or more carbon atoms in said “alkyl” of C₁-C₄₀ alkyl, C₆-C₁₂ aryl-C₁-C₁₀ alkyl, C₃-C₇ cycloalkyl-C₁-C₁₀ alkyl, 4- to 7-membered heterocyclyl-C₁-C₁₀ alkyl, 5- to 10-membered heteroaryl-C₁-C₁₀ alkyl, or C₁-C₂₀ alkyl-thio-C₁-C₂₀ alkyl are optionally:
   i. replaced with O or S; and/or
   ii. substituted with (═O);

As used herein, “oxidative reducing amount” refers to an amount of a compound of Formula (II) that is sufficient to reduce I₂ to I⁻ in solution. In certain embodiments, the oxidative reducing amount of the compound of formula (II) is about 0.01 mol % to about 5 mol % relative to said composition of Formula (I). In certain embodiments, the oxidative reducing amount of the compound of formula (II) is about 0.01 mol % to about 2 mol %, about 0.10 mol % to about 5 mol %, about 0.5 mol % to about 3 mol %, about 0.01 mol % to about 0.10 mol %, about 0.01 mol % to about 1.5 mol %, about 0.01 mol % to about 0.50 mol %, about 0.10 mol % to about 0.25 mol %, about 0.15 mol % to about 0.75 mol % about 0.15 mol % to about 1.0 mol %, about 0.50 mol % to about 2.0 mol %, about 0.50 mol % to about 1.0 mol %, about 0.35 mol % to about 0.75 mol %, about 0.50 mol % to about 1.50 mol %, about 0.80 mol % to about 1.25 mol %, about 1.0 mol % to about 2.0 mol %, about 0.65 mol % to about 2.0 mol %, or about 0.75 mol % to about 1.75 mol % relative to said composition of Formula (I). In certain embodiments, the oxidative reducing amount of the compound of formula (II) is about 0.05 mol %, 0.10 mol %, 0.15 mol %, 0.16 mol %, 0.17 mol %, 0.18 mol %, 0.19 mol %, 0.20 mol %, 0.21 mol %, 0.22 mol %, 0.23 mol %, 0.24 mol %, 0.25 mol %, 0.26 mol %, 0.27 mol %, 0.28 mol %, 0.29 mol %, 0.30 mol %, 0.31 mol %, 0.32 mol %, 0.33 mol %, 0.34 mol %, 0.35 mol %, 0.36 mol %, 0.37 mol %, 0.38 mol %, 0.39 mol %, 0.40 mol %, 0.41 mol %, 0.42 mol %, 0.43 mol %, 0.44 mol %, 0.45 mol %, 0.50 mol %, 0.6 mol %, 0.65 mol %, 0.7 mol %, 0.75 mol %, 0.8 mol %, 0.85 mol %, 0.9. mol %, 0.95 mol %, 1.0 mol %, 1.05 mol %, 1.10 mol %, 1.15 mol %, 1.20 mol %, 1.25 mol %, 1.30 mol %, 1.35 mol %, 1.40 mol %, 1.45 mol %, 1.50 mol %, 1.55 mol %, 1.60 mol %, 1.65 mol %, 1.70 mol %, 1.75 mol %, 1.80 mol %, 1.85 mol %, 1.90 mol %, 1.95 mol %, 2.0 mol %, 2.5 mol %, 3 mol %, 3.5 mol %, 4 mol %, 4.5 mol %, or 5.0 mol % relative to said composition of Formula (I).

In certain embodiments of the above methods, the ink solution comprises one of more solvents selected from the group consisting of dimethylformamide, dimethyl sulfoxide, acetonitrile, propionitrile, acetone, ethylacetate, methylene chloride, chloroform, methanol, ethanol, propanol, butanol, isopropanol, ethylene glycol, diethyl ether, glyme, diglyme, propylene carbonate, N-methyl-2-pyrrolidinone, γ-Butyrolactone (gamma-butyrolactone), tetrahydrofuran, benzene, toluene, decalin, hexamethylphosphoramide, pyridine, alkylpyridine, pyrrolidine, chlorobenzene, dichlorobenzene, dichloromethane, chloroform, water, carbon disulfide, supercritical carbon dioxide, carbon tetrachloride, 2-Methoxyethanol, and sulfuryl chloride fluoride. In certain embodiments, the ink solution comprises one or more solvents selected from the group consisting of dimethyl sulfoxide, dimethylformamide, γ-Butyrolactone, 2-Methoxyethanol, acetonitrile, methanol, ethanol, propanol, butanol, tetrahydrofuran, pyridine, alkylpyridine, water, pyrrolidine, chlorobenzene, dichlorobenzene, dichloromethane, and chloroform. In certain embodiments of the above methods, the ink solution comprises one or more solvents selected from the group consisting of dimethyl sulfoxide, dimethylformamide, N-methyl-2-pyrrolidone, γ-butyrolactone, 2-methoxyethanol, and acetonitrile. In certain embodiments of the above methods, the ink solution comprises one or more solvents selected from 2-methoxyethanol.

In certain embodiments of the above methods, y in said composition of Formula (I) is 0. In certain embodiments of the perovskite film, y in said composition of Formula (I) is 0.2, 0.5, 0.7, 0.9, 1.0, 1.3, 1.5, 1.7, 2.0, 2.3, 2.5, or 2.7. In certain embodiments of the above methods, A in said composition of Formula (I) is selected from the group consisting of Cs, MA, FA, and a combination thereof. In certain embodiments of the above methods, B is lead. In certain embodiments of the above methods, the composition of Formula (I) is Cs_{z}MA_{1-x-z}FAₓPbI₃, wherein x and z are between 0 and 1, provided that the sum of x and z does not exceed 1. In certain embodiments of the above methods, z is selected from the group consisting of 0, 0.05, 0.08, 0.09, 0.10, 0.12, and 0.15; and x is selected from the group consisting of 0, 0.2, 0.3, 0.4, and 0.5. In certain embodiments, x and z are each independently selected from the group consisting of 0, 0.1, 0.2, 0.3, 0.4, 0.5, 0.6, 0.7, 0.8, 0.9, and 1.0. In certain embodiments of the above methods, x is 0.3 and z is 0 or x is 0.92 and z is 0.08. In certain embodiments of the above methods, the composition of Formula (I) is MA_{0.7}FA_{0.3}PbI₃. In certain embodiments of the above methods, said compound of Formula (II), or salt thereof is other than hydrazinium chloride or 4-fluorobenzohydrazide.

In certain embodiments of the above methods, in the compound or salt of Formula (II), R₃ and R₄ are each hydrogen, R₁ is hydrogen, and R₂ is selected from the group consisting of C₁-C₄₀ alkyl, C₂-C₄₀ alkenyl, C₂-C₄₀ alkynyl, aminoalkyl, C₆-C₁₂ aryl, C₃-C₇ cycloalkyl, 4- to 7-membered heterocyclyl, 5- to 7-membered heteroaryl, C₆-C₁₂ aryl-C₁-C₁₀ alkyl, C₃-C₇ cycloalkyl-C₁-C₁₀ alkyl, 4- to 7-membered heterocyclyl-C₁-C₁₀ alkyl, 5- to 10-membered heteroaryl-C₁-C₁₀ alkyl, and C₁-C₂₀ alkyl-thio-C₁-C₂₀ alkyl, each of which is optionally substituted one or more times with a substituent, each independently selected from the group consisting of halogen, cyano, hydrazino, C₁-C₂₀ alkyl, amino, C₁-C₂₀ alkoxy, C₂-C₂₀ alkenyl, C₂-C₂₀ alkynyl, C₆-C₁₂ aryl, C₃-C₇ cycloalkyl, 4- to 7-membered heterocyclyl, and 5- to 10-membered heteroaryl;
wherein one or more carbon atoms in said “alkyl” of C₁-C₄₀ alkyl, aminoalkyl, C₆-C₁₂ aryl-C₁-C₁₀ alkyl, C₃-C₇ cycloalkyl-C₁-C₁₀ alkyl, 4- to 7-membered heterocyclyl-C₁-C₁₀ alkyl, 5- to 10-membered heteroaryl-C₁-C₁₀ alkyl, C₁-C₂₀ alkyl-thio-C₁-C₂₀ alkyl are optionally:
   i. replaced with O or S; and/or
   ii. substituted with (═O).

In certain embodiments of the above methods, in the compound or salt of Formula (II), R₂ is C₁-C₁₀ alkyl optionally substituted with hydrazino, wherein one of more carbon atoms in C₁-C₁₀ alkyl are substituted with (═O). In certain embodiments, R₂ is C₁ alkyl, substituted with (═O) and hydrazino. In certain embodiments, R₂ is

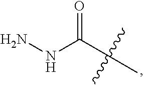 [SMILES: *C(=O)NN]

and R₁, R₄, and R₃ are each hydrogen. In certain embodiments of the above methods, the compound of Formula (II) is

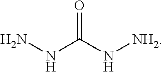

In certain embodiments of the above methods, in the compound or salt of Formula (II), R₂ is selected from the group consisting of C₁-C₁₀ alkyl, C₆-C₁₂ aryl-C₁-C₆ alkyl, and 5- to 10-membered heteroaryl-C₁-C₆ alkyl. In certain embodiments of the above methods, in the compound or salt of Formula (II), R₂ is C₆-C₁₂ aryl-C₁-C₆ alkyl. In certain embodiments of the above methods, in the compound or salt of Formula (II), R₂ is benzyl. In certain embodiments of the above methods, in the compound or salt of Formula (II), R₂ is C₁-C₁₀ alkyl. In certain embodiments of the above methods, in the compound or salt of Formula (II), R₂ is selected from the group consisting of methyl, ethyl, propyl, and butyl. In certain embodiments of the above methods, in the compound or salt of Formula (II), R₂ is propyl. In certain embodiments of the above methods, in the compound or salt of Formula (II), R₂ is 5- to 10-membered heteroaryl-C₁-C₆ alkyl. In certain embodiments of the above methods, in the compound or salt of Formula (II), R₂ is thiophene-methyl.

In certain embodiments of the above methods, the compound of Formula (II) is a salt. In certain embodiments of the oxidative-resistant ink solution. wherein the compound of Formula (II) is a salt, the salt is

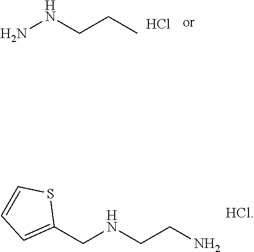

In certain embodiments of the above methods, wherein the compound of Formula (II) is a salt, the salt is

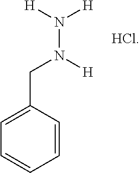

In certain embodiments of the above methods, the composition of Formula (I) is MA_{0.7}FA_{0.3}PbI₃ and the compound of Formula (II) or salt thereof is

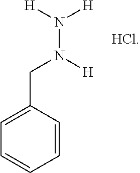

In certain embodiments of the above methods, the compound of Formula (II), or salt thereof, is contacted with said ink solution comprising said composition of Formula (I) in a molar percent of about 0.01 to about 5 relative to said composition of Formula (I). In certain embodiments of the above methods, the compound of Formula (II), or salt thereof, is contacted with said ink solution comprising said composition of Formula (I) in a molar percent present in about 0.01 mol % to about 2 mol %, about 0.10 mol % to about 5 mol %, about 0.5 mol % to about 3 mol %, about 0.01 mol % to about 0.10 mol %, about 0.01 mol % to about 1.5 mol %, about 0.01 mol % to about 0.50 mol %, about 0.10 mol % to about 0.25 mol %, about 0.15 mol % to about 0.75 mol % about 0.15 mol % to about 1.0 mol %, about 0.50 mol % to about 2.0 mol %, about 0.50 mol % to about 1.0 mol %, about 0.35 mol % to about 0.75 mol %, about 0.50 mol % to about 1.50 mol %, about 0.80 mol % to about 1.25 mol %, about 1.0 mol % to about 2.0 mol %, about 0.65 mol % to about 2.0 mol %, or about 0.75 mol % to about 1.75 mol % relative to said composition of Formula (I). In certain embodiments of the above methods, the compound of Formula (II), or salt thereof, is contacted with said ink solution comprising said composition of Formula (I) in a molar percent in about 0.05 mol %, 0.10 mol %, 0.15 mol %, 0.16 mol %, 0.17 mol %, 0.18 mol %, 0.19 mol %, 0.20 mol %, 0.21 mol %, 0.22 mol %, 0.23 mol %, 0.24 mol %, 0.25 mol %, 0.26 mol %, 0.27 mol %, 0.28 mol %, 0.29 mol %, 0.30 mol %, 0.31 mol %, 0.32 mol %, 0.33 mol %, 0.34 mol %, 0.35 mol %, 0.36 mol %, 0.37 mol %, 0.38 mol %, 0.39 mol %, 0.40 mol %, 0.41 mol %, 0.42 mol %, 0.43 mol %, 0.44 mol %, 0.45 mol %, 0.50 mol %, 0.6 mol %, 0.65 mol %, 0.7 mol %, 0.75 mol %, 0.8 mol %, 0.85 mol %, 0.9. mol %, 0.95 mol %, 1.0 mol %, 1.05 mol %, 1.10 mol %, 1.15 mol %, 1.20 mol %, 1.25 mol %, 1.30 mol %, 1.35 mol %, 1.40 mol %, 1.45 mol %, 1.50 mol %, 1.55 mol %, 1.60 mol %, 1.65 mol %, 1.70 mol %, 1.75 mol %, 1.80 mol %, 1.85 mol %, 1.90 mol %, 1.95 mol %, 2.0 mol %, 2.5 mol %, 3 mol %, 3.5 mol %, 4 mol %, 4.5 mol %, or 5.0 mol % relative to said composition of Formula (I).

### V. Methods for Producing Films

In certain embodiments, the subject matter disclosed herein is directed to a method for producing a polycrystalline perovskite film using the oxidative-resistant ink solutions described herein. In certain embodiments, the method comprises: contacting the ink solution using a fast coating process onto a substrate to form a film, wherein the fast coating process is selected from the group consisting of blade coating, slot die coating, shear coating, gravure coating, brush coating, syringe coating, and screen printing.

Utilizing a fast coating process is advantageous because of increased scalability for perovskite device roll-to-roll production, simplicity, and cost effectiveness. Furthermore, fast coating processes also provide advantages due to high-throughput deposition, high material usage, and application onto flexible substrates. In particular, perovskite films and devices fabricated using a fast coating process, such as blade coating, can have advantageously long carrier diffusion lengths (e.g., up to 3 μm thick) due to the dramatically higher carrier mobility in the blade-coated films. Such doctor-blade deposition can be utilized for large area perovskite cells fabricated with high volume roll-to-roll production.

In certain embodiments, a device is used in the fast coating process for contacting the ink solution onto the substrate. In the blade coating process, a “blade coater” may be used. As used herein, “blade coater” is synonymous with “doctor blade.” In certain embodiments, doctor blade coating techniques are used to facilitate formation of the polycrystalline perovskite film during the fabrication process.

In certain embodiments, the method for producing a polycrystalline perovskite film using the fast coating process can take place at a temperature between about 25° C. to about 250° C. In certain embodiments, the process takes place at about room temperature (about 25° C.).

In certain embodiments of the fast coating process, the substrate is moving and the device is stationary. In certain embodiments, the device is a doctor blade. In certain aspects, the substrate is moving at a rate of about 2 mm/s relative to the device. In certain aspects, the substrate is moving at a rate of about 20 mm/s relative to the device. In certain aspects, the substrate is moving at a rate of about 40 mm/s relative to the device. In certain aspects, the substrate is moving at a rate of about 99 mm/s relative to the device. In certain aspects, the substrate is stationary and the device moves relative to the substrate. In certain aspects, the device is moving at a rate of about 2 mm/s relative to the substrate. In certain aspects, the device is moving at a rate of about 20 mm/s relative to the substrate. In certain aspects, the device is moving at a rate of about 40 mm/s relative to the substrate. In certain aspects, the device is moving at a rate of about 99 mm/s relative to the substrate.

In certain embodiments, the fast coating process described herein takes place at about 2 to about 15,000 mm/s. In certain embodiments, the fast coating process described herein takes place at about 2 to about 10,000 mm/s. In certain embodiments, the fast coating process described herein takes place at about 2 to about 99 mm/s. In certain embodiments, the fast coating process takes place at least or at about 2 mm/s, 20 mm/s, 40 mm/s, 60 mm/s, 80 mm/s, 99 mm/s, 150 mm/s, 275 mm/s, 500 mm/s, 700 mm/s, 800 mm/s, 900 mm/s, 1000 mm/s, 2000 mm/s, 3000 mm/s, 4000 mm/s, 5000 mm/s, 6000 mm/s, 7000 mm/s, 8000 mm/s, 9000 mm/s, 10,000 mm/s, 11,000 mm/s, 12,000 mm/s, 13,000 mm/s, 14,000 mm/s, or 15,000 mm/s.

In certain embodiments, the distance between the device used in the fast coating process for contacting the ink solution onto the substrate is between about 10 μm and 1 cm. In certain embodiments, the distance between the device and the substrate is between about 150 and about 350 μm. In certain embodiments, the distance between the device and the substrate is between about 200 and about 300 μm. In certain embodiments, the distance between the device and the substrate is about 200 μm, 225 μm, about 250 μm, about 275 μm, or about 300 μm.

In certain embodiments, the methods described herein to produce polycrystalline perovskite films further comprise knife-assisted drying. Knife drying comprises applying a high velocity, low pressure gas to the ink solution to form a perovskite film on the substrate. An advantage of knife drying in the polycrystalline perovskite film production process is that it helps produces uniform and smooth films. As used herein, an “air knife,” “N₂ knife,” or “air doctor” may be used to describe the device that performs knife-assisted drying in the perovskite film production process. The knife may have a gas manifold with a plurality of nozzles that direct a high velocity stream of air or other gas at the perovskite ink on the substrate. The gas used in the knife-assisted drying process may be air, nitrogen, argon, helium, oxygen, neon, hydrogen, and a combination thereof.

In certain embodiments, the knife-assisted drying takes place at a temperature of about 25° C. to about 250° C. In certain embodiments, the knife-assisted drying takes place at room temperature (about 25° C.). In certain embodiments, the knife-assisted drying takes place at a temperature of about 50° C. to about 100° C.

In certain embodiments, the knife-assisted drying takes place at a pressure in a range of about 0 to 500 psi. In certain embodiments, the knife-assisted drying takes place at a pressure in a range of about 5 to 400 psi, about 20 to 300 psi, about 50 to 200 psi, about 100 to 150 psi, about 5 to 25 psi, about 5 to 20 psi, about 10 to 20 psi, about 10 to 19 psi, about 12 to 18 psi, about 12-16 psi, or about 13-16 psi. In certain embodiments, the knife-assisted drying takes place at about 14 psi, about 15, psi, about 16 psi, at about 17 psi, at about 18 psi, or at about 19 psi.

In certain embodiments, the knife is angled against the device used in the fast coating process and the substrate to create a unidirectional air flow over the as-coated film for enhanced blowing uniformity. In certain embodiments, the knife is angled 0°, 5°, 10°, 15°, 20°, 25°, 30°, 35° 40°, 45° 50°, 55° 60°, 65°, 70°, 75° 80°, 90°, 100°, 120°, 150°, 155°, 170°, or 180° against the device or the substrate.

In certain embodiments, after fast coating and/or knife-assisted drying, the film created from the ink solution (while on the substrate) may undergo annealing. The film is annealed at a temperature of at least or above 30° C. for a time period effective to convert the perovskite precursor components in the ink solution to a film of a crystalline halide perovskite within the scope of Formula (I) above. In certain embodiments, annealing employs a temperature of about, at least, above, up to, or less than 40° C., 50° C., 60° C., 70° C., 80° C., 90° C., 100° C., 110° C., 120° C., 130° C., 140° C., 150° C., 160° C., 170° C., 180° C., 190° C., or 200° C., or a temperature within a range bounded by any two of the foregoing values. In various embodiments, annealing may take place in a range of, for example, 30-200° C., 50-150° C., 30-180° C., 30-150° C., 30-140° C., 30-130° C., 30-120° C., 30-110° C., or 30-100° C.

Annealing may take place for a period of time, for example, in a range of about 0 seconds to 400 minutes, about 5 seconds to 30 seconds, about 5 minutes to about 10 minutes, about 10 minutes to 20 minutes, or about 20 minutes to 30 minutes. Annealing can take place for a period of time, for example, of at least 5 seconds, 10 seconds, 20 seconds, 30 seconds, 1, minute, 5 minutes, 10 minutes, 20 minutes, 30 minutes, 60 minutes, 90 minutes, 120 minutes, 180 minutes, 240 minutes, or 360 minutes.

In certain embodiments, the subject matter disclosed herein is directed to a method of preparing a perovskite film having reduced interfacial voids, comprising contacting a precursor solution comprising one or more non-coordinating solvents and a composition of Formula (I)

ABI_{3-y}X_{y} (I)
wherein A is a cation selected from the group consisting of methylammonium (MA), tetramethylammonium, formamidinium (FA), cesium (Cs), rubidium (Rb), potassium (K), sodium (Na), butylammonium (BA), phenethylammonium (PEA), phenylammonium (PA), guanidinium (GA), and a combination thereof;
B is a metal cation selected from the group consisting of lead, tin, calcium, cadmium, germanium, zinc, nickel, platinum, palladium, mercury, titanium, silicon, and a combination thereof;
X is selected from the group consisting of Cl⁻, Br⁻, F⁻, SCN⁻, and a combination thereof;
y is between 0 and 3;
   with:
(i) a compound of Formula (II), or a salt thereof,

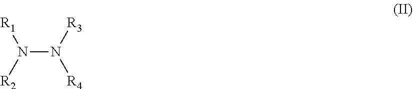

R₁, R₂, R₃, and R₄ are each independently selected from the group consisting of hydrogen, C₁-C₄₀ alkyl, C₂-C₄₀ alkenyl, C₂-C₄₀ alkynyl, aminoalkyl, C₆-C₁₂ aryl, C₃-C₇ cycloalkyl, 4- to 7-membered heterocyclyl, 5- to 10-membered heteroaryl, C₆-C₁₂ aryl-C₁-C₁₀ alkyl, C₃-C₇ cycloalkyl-C₁-C₁₀ alkyl, 4- to 7-membered heterocyclyl-C₁-C₁₀ alkyl, 5- to 10-membered heteroaryl-C₁-C₁₀ alkyl, and C₁-C₂₀ alkyl-thio-C₁-C₂₀ alkyl, each of which is optionally substituted one or more times with a substituent, each independently selected from the group consisting of halogen, cyano, hydrazino, C₁-C₂₀ alkyl, amino, C₁-C₂₀ alkoxy, C₂-C₂₀ alkenyl, C₂-C₂₀ alkynyl, C₆-C₁₂ aryl, C₃-C₇ cycloalkyl, 4- to 7-membered heterocyclyl, and 5- to 10-membered heteroaryl;
wherein one or more carbon atoms in said “alkyl” of C₁-C₄₀ alkyl, aminoalkyl, C₆-C₁₂ aryl-C₁-C₁₀ alkyl, C₃-C₇ cycloalkyl-C₁-C₁₀ alkyl, 4- to 7-membered heterocyclyl-C₁-C₁₀ alkyl, 5- to 10-membered heteroaryl-C₁-C₁₀ alkyl, or C₁-C₂₀ alkyl-thio-C₁-C₂₀ alkyl are optionally:
i. replaced with O or S; and/or
ii. substituted with (═O);
   and
(ii) a coordinating solvent, to prepare a modified precursor solution; and contacting said modified precursor solution onto a substrate to prepare a perovskite film,
wherein said perovskite film prepared has reduced interfacial voids.

In certain embodiments of the method of preparing a perovskite film having reduced interfacial voids, the coordinating solvent is dimethyl sulfoxide. In certain embodiments, the coordinating solvent is dimethylformamide.

In certain embodiments of the method of preparing a perovskite film having reduced interfacial voids, R₃ and R₄ are each hydrogen, R₁ is hydrogen, and R₂ is selected from the group consisting of C₁-C₄₀ alkyl, C₂-C₄₀ alkenyl, C₂-C₄₀ alkynyl, aminoalkyl, C₆-C₁₂ aryl, C₃-C₇ cycloalkyl, 4- to 7-membered heterocyclyl, 5- to 7-membered heteroaryl, C₆-C₁₂ aryl-C₁-C₁₀ alkyl, C₃-C₇ cycloalkyl-C₁-C₁₀ alkyl, 4- to 7-membered heterocyclyl-C₁-C₁₀ alkyl, 5- to 10-membered heteroaryl-C₁-C₁₀ alkyl, and C₁-C₂₀ alkyl-thio-C₁-C₂₀ alkyl, each of which is optionally substituted one or more times with a substituent, each independently selected from the group consisting of halogen, cyano, hydrazino, C₁-C₂₀ alkyl, amino, C₁-C₂₀ alkoxy, C₂-C₂₀ alkenyl, C₂-C₂₀ alkynyl, C₆-C₁₂ aryl, C₃-C₇ cycloalkyl, 4- to 7-membered heterocyclyl, and 5- to 10-membered heteroaryl;
wherein one or more carbon atoms in said “alkyl” of C₁-C₄₀ alkyl, aminoalkyl, C₆-C₁₂ aryl-C₁-C₁₀ alkyl, C₃-C₇ cycloalkyl-C₁-C₁₀ alkyl, 4- to 7-membered heterocyclyl-C₁-C₁₀ alkyl, 5- to 10-membered heteroaryl-C₁-C₁₀ alkyl, C₁-C₂₀ alkyl-thio-C₁-C₂₀ alkyl are optionally:
i. replaced with O or S; and/or
ii. substituted with (═O).

In certain embodiments of the method of preparing a perovskite film having reduced interfacial voids, R₂ is C₁-C₁₀ alkyl, optionally substituted with hydrazino, and wherein one or more atoms in said alkyl are substituted with (═O).

In certain embodiments of the method of preparing a perovskite film having reduced interfacial voids, R₂ is

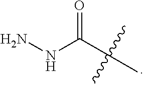 [SMILES: *C(=O)NN]

In certain embodiments of the method of preparing a perovskite film having reduced interfacial voids, said compound of Formula II is

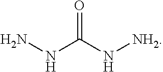

In certain embodiments of the method of preparing a perovskite film having reduced interfacial voids, said composition of Formula (I) is APbI₃, wherein A is a cation selected from the group consisting of methylammonium (MA), formamidinium (FA), cesium (Cs), and a combination thereof.

In certain embodiments of the method of preparing a perovskite film having reduced interfacial voids, said composition of Formula (I) is MA_{1-X}FA_{X}PbI₃, wherein x is between 0 and 0.6.

In certain embodiments of the method of preparing a perovskite film having reduced interfacial voids, said composition of Formula (I) is MA_{0.6}FA_{0.4}PbI₃.

In certain embodiments of the method of preparing a perovskite film having reduced interfacial voids, the method further comprises annealing said perovskite film, wherein the presence of said compound of Formula (II), or salt thereof, reduces time required for annealing. In certain embodiments, the presence of said compound of Formula (II) reduces the time required for annealing by 5, 10, 15, 20, 25, 30, 35, 40, 45, 50, 55, 60, 65, 70, or 75 times.

In certain embodiments of the method of preparing a perovskite film having reduced interfacial voids, said compound or salt of Formula II is present in said modified precursor solution at about 0.25 to 5 mol % relative to said composition of Formula I; and said coordinating solvent is present in said modified precursor solution at about 5 to 40 mol % relative to said composition of Formula I. In certain other embodiments, said compound or salt of Formula II is present in said modified precursor solution at about 0.5, 0.6, 0.7, 0.8, 0.9, 1.0, 1.1, 1.2, 1.3, 1.4, 1.5, 1.6, 1.7, 1.8, 1.9, 2.0, 2.1, 2.2, 2.3, 2.4, or 2.5 mol % relative to said composition of Formula I; and said coordinating solvent is present in said modified precursor solution at about 15, 16, 17, 18, 19, 20, 21, 22, 23, 24, 25, 26, 27, 28, 29, 30, 31, 32, 33, 34, or 35 mol % relative to said composition of Formula I.

The coordinating ability of a solvent, in one aspect, may refer to its strength as a Lewis base. As defined herein, a Lewis base is a compound or ionic species that can donate an electron pair to an acceptor compound. A Lewis acid is a substance that can accept a pair of nonbonding electrons. In one aspect, a “coordinating solvent” is a strong Lewis base, while a “non-coordinating solvent” is a weak Lewis base.

In another aspect, the coordinating ability of a solvent may refer to how well it coordinates or bonds to a metal ion. In certain embodiments described herein, the coordinating ability of a solvent is related to how well it coordinates or bonds to Pb²⁺ or Sn²⁺. In certain embodiments, a coordinating solvent exhibits strong bonding to Pb²⁺ or Sn²⁺. In certain embodiments, a non-coordinating solvent exhibits weak bonding to Pb²⁺ or Sn²⁺. The donor number (DN) is often used to quantify a solvent's coordination ability. Donor number is defined as the negative enthalpy value for the 1:1 adduct formation between a Lewis base and the standard Lewis acid SbCl₅ (antimony pentachloride), in dilute solution in the non-coordinating solvent 1,2-dichloroethane, which has a donor number of zero. The donor number is typically reported in units of kcal/mol. In certain embodiments, a coordinating solvent has a donor number of at least 20 kcal/mol. In certain embodiments, a coordinating solvent has a donor number in the range of 20 kcal/mol to 25 kcal/mol. In certain embodiments, a coordinating solvent has a donor number greater than 25 kcal/mol. In some embodiments, a non-coordinating solvent has a donor number less than 20 kcal/mol. Acetonitrile, for example, has a donor number of 14.1 kcal/mol. Acetonitrile is therefore classified as a non-coordinating solvent. Dimethyl sulfoxide has a donor number of 29.8 kcal/mol, and is referred to herein as a coordinating solvent.

In certain embodiments of the method of preparing a perovskite film having reduced interfacial voids, said one or more non-coordinating solvents are selected from the group consisting of gamma-butyrolactone, 2-methoxyethanol, acetonitrile, and a combination thereof. In certain embodiments of the method of preparing a perovskite film having reduced interfacial voids, said one or more non-coordinating solvents are 2-methoxyethanol or dimethylformamide.

In certain embodiments of the method of preparing a perovskite film having reduced interfacial voids, said composition of Formula (I) is APbI₃, wherein A is a cation selected from the group consisting of methylammonium (MA), formamidinium (FA), cesium (Cs), and a combination thereof;
said compound of Formula II, or salt thereof, is

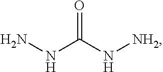

wherein said compound of Formula II is present in said modified precursor solution at about 1.5 mol % relative to said composition of Formula I; and
said coordinating solvent is dimethyl sulfoxide, wherein said coordinating solvent is present in said modified precursor solution at about 25 mol % relative to said composition of Formula I.

In certain embodiments of the method of preparing a perovskite film having reduced interfacial voids, said contacting said modified precursor solution onto a substrate to prepare a perovskite film comprises blade-coating said modified precursor solution onto said substrate.

In certain embodiments of the method of preparing a perovskite film having reduced interfacial voids, the method further comprises contacting said modified precursor solution with one or more additives selected from the group consisting of n-dodecylammonium iodide (about 0.0 to about 10 mg/ml), L-α-phosphatidylcholine (about 0.0 to about 1.0 mg/ml), MAH₂PO₂ (about 0.0 to about 10 mg/ml), and 4-fluoro-phenylammonium iodide (p-F-PEAI) (about 0.0 to about 10 mg/ml).

In certain embodiments of the method of preparing a perovskite film having reduced interfacial voids, the perovskite film prepared by the method described herein contains at least 1%, 2%, 3%, 4%, 5%, 6%, 7%, 8%, 9%, 10%, 11%, 12%, 13%, 14%, 15%, 16%, 17%, 18%, 19%, 20%, 25%, 30%, 35%, 40%, 45%, 50%, 55%, 60%, 65%, 70%, 75%, 80%, 85%, 90%, 91%, 92%, 93%, 94%, 95%, 96%, 97%, 98%, 99%, or 100% fewer interfacial voids compared to a perovskite film prepared by other methods of the art.

In certain embodiments, the methods described herein produce polycrystalline perovskite films having a film thickness in a range of about 10 nm to about 1 cm. In certain embodiments, the methods described herein produce polycrystalline perovskite films having a film thickness in a range of about 300 nm to about 1000 nm. In certain embodiments, the methods described herein produce polycrystalline perovskite films having a film thickness in a range of about 80 nm to about 300 nm. In certain embodiments, the methods described herein produce polycrystalline perovskite films having a film thickness in a range of about 0.1 mm to about 50 mm. In certain embodiments, the methods described herein produce polycrystalline perovskite films having a film thickness in a range of about 100 nm to about 1000 nm. In certain embodiments, the methods described herein produce polycrystalline perovskite films having a film thickness in a range of about, at least, above, up to, or less than, for example, 200 nm, 300 nm, 400 nm, 500 nm, 600 nm, 700 nm, 800 nm, 900 nm, 1000 nm (1 μm), 2 μm, 3 μm, 4 μm, 5 μm, 6 μm, 7 μm, 8 μm, 9 μm, or 10 μm.

In certain embodiments, the methods described herein produce polycrystalline perovskite films capable of achieving compact, pin-hole free, and uniform structures with an average grain size of about 10 nm to about 1 mm. In certain embodiments, the polycrystalline films have an average grain size of about, at least, or above 0.01 μm, 10 μm, 20 μm, 30 μm, 40 μm, 50 μm, 60 μm, 70 μm, 80 μm, 90 μm, 100 μm, 120 μm, 150 μm, 180 μm, 200 μm, 220 μm, 250 μm, 280 μm, 300 μm, 350 μm, 400 μm, 450 μm, 500 μm, 550 μm, 600 μm, 650 μm, 700 μm, 800 μm, 850 μm, 900 μm, 1000 μm, or an average grain size within a range bounded by any two of the foregoing exemplary values. It is generally known in the art that large grain sizes are suitable for films in photoactive or photovoltaic applications.

### VI. Devices

The polycrystalline perovskite films described herein are useful in a variety of photoactive and photovoltaic applications. The perovskite films can be integrated into, for example, photoluminescent devices, photoelectrochemical devices, thermoelectric devices, and photocatalytic devices. Some non-limiting examples in which the polycrystalline perovskite films can be applied include solar cells, solar panels, solar modules, light-emitting diodes, lasers, photodetectors, x-ray detectors, batteries, hybrid PV batteries, field effect transistors, memristors, or synapses.

In certain embodiments, the subject matter described herein is directed to semiconductor device comprising:
one or more anode layers;
one or more cathode layers; and
one or more active layers, wherein at least one of said one or more active layers comprises the polycrystalline film described herein.

In certain embodiments of the semiconductor device, the device is selected from the group consisting of solar cell, light emitting diode, photodiode, photoelectrochemical cell, photoresistor, phototransistor, photomultiplier, photoelectric cell, electrochromic cell, and radiation detector. In certain embodiments, the solar cell is a single junction solar cell. In certain embodiments the solar cell is a tandem solar cell, such as a perovskite-perovskite or perovskite-silicon tandem solar cell.

In certain embodiments, the subject matter described herein is directed to a solar cell, comprising:
one or more transparent conductive oxide layers;
one or more conductive electrode layers; and
one or more active layers, wherein at least one of said one or more active layers comprises the polycrystalline film described herein.

In certain embodiments of the above solar cell, the solar cell further comprises:
one or more hole transport layers; and
one or more electron transport layers.

In certain embodiments of the above solar cell, the solar cell comprises:
one transparent conductive oxide layer;
one conductive electrode layer;
one hole transport layer;
one electron transport layer; and
one active layer, wherein said active layer comprises the polycrystalline film described herein.

In certain embodiments of the above solar cell,
said hole transport layer is disposed on said transparent conductive oxide layer;
said active layer comprising the polycrystalline film is disposed on said hole transport layer;
said electron transport layer is disposed on said active layer; and
said conductive electrode layer is disposed on said electron transport layer.

In certain embodiments of the above solar cell,
said electron transport layer is disposed on said transparent conductive oxide layer;
said active layer comprising the polycrystalline film is disposed on said electron transport layer;
said hole transport layer is disposed on said active layer; and
said conductive electrode layer is disposed on said hole transport layer.

The transparent conductive oxide layer and the conductive electrode layer comprise the anode and cathode (or vice versa) in the solar cell. In certain embodiments, the cathode and anode each comprise at least one of lithium, sodium, potassium, rubidium, cesium, francium, beryllium, magnesium, calcium, strontium, barium, radium, boron, aluminum, gallium, indium, thallium, tin, lead, flerovium, bismuth, antimony, tellurium, polonium, scandium, titanium, vanadium, chromium, manganese, iron, cobalt, nickel, copper, zinc, yttrium, zirconium, niobium, molybdenum, technetium, ruthenium, rhodium, palladium, silver, cadmium, hafnium, tantalum, tungsten, rhenium, osmium, iridium, platinum, gold, mercury, rutherfordium, dubnium, seaborgium, bohrium, hassium, copernicium, samarium, neodymium, ytterbium, an alkali metal fluoride, an alkaline-earth metal fluoride, an alkali metal chloride, an alkaline-earth metal chloride, an alkali metal oxide, an alkaline-earth metal oxide, a metal carbonate, a metal acetate, carbon nanowire, carbon nanosheet, carbon nanorod, carbon nanotube, graphite, indium tin oxide (ITO), fluorine-doped tin oxide (FTO), aluminum doped zinc oxide (AZO), antimony-tin mixed oxide (ATO), network of metal/alloy nanowire, or a combination of two or more of the above materials. In certain embodiments, the transparent conductive oxide layer is selected from the group consisting of ITO, FTO, ZITO, and AZO. In certain embodiments, the metal electrode is selected from the group consisting of Al, Au, Cu, Cr, Ca, Mg, Bi, Ag, Ti, and carbon.

The transport layers in the solar cell are each a hole transport layer or an electron transport layer.

In certain embodiments, the hole transport layer comprises at least one of poly(3,4-ethylene dioxithiophene) (PEDOT) doped with poly(styrene sulfon icacid) (PSS), Spiro-OMeTAD, pm-spiro-OMeTAD, po-spiro-OMeTAD, dopants in spiro-OMeTAD, 4,4′-biskptrichlorosilylpropylphenyl)phenylamino Thiphenyl (TPD-Si2), poly(3-hexyl-2,5-thienylene vinylene) (P3HTV), C₆₀, carbon, carbon nanotube, graphene quantum dot, graphene oxide, copper phthalocyanine (CuPc), Polythiophene, poly(3,4-(1hydroxymethyl)ethylenedioxythiophene (PHMEDOT), n-dodecylbenzenesulfonic acid/hydrochloric acid doped poly(aniline) nanotubes (a-PANIN)s, poly(styrene sulfonic acid)-graft-poly(aniline) (PSSA-g-PANI), poly(9. 9-dioctylfluorene)-co-N-(4-(1-methylpropyl)phenyl) diphenylamine (PFT), 4,4′-bis(p-trichlorosilylpropylphenyl) phenylaminobiphenyl (TSPP), 5,5′-bis(p-trichlorosilylpropylphenyl) phenylamino-2,20 bithiophene (TSPT), N-propyltriethoxysilane, 3,3,3-trifluo ropropyltrichlorosilane or 3-aminopropyltriethoxysilane, Poly(bis(4-phenyl)(2,4,6-trimethylphenyl)amine) (PTAA), (Poly[[(2,4-dimethylphenyl)imino]-1,4-phenylene(9,9-dioctyl-9H-fluorene-2,7-diyl)-1,4phenylene], (PF8-TAA)), (Poly [[(2,4-dimethylphenyl)imino]-1,4-phenylene (6,12-dihydro-6,6,12,12tetraoctylindeno[1,2-b]fluorene-2,8-diyl)-1,4-phenylene]) (PIF8-TAA), poly[[4,8-bis[(2-ethylhexyl)oxy]benzo[1,2-b:4,5-b]dithiophene-2,6-diyl][3-fluoro-2-[(2-ethylhexyl)carbonyl]thieno[3,4-b]thiophenediyl]] (PTB7), poly[N-90-heptadecanyl-2,7-carbazole-alt-5,5-(40,70-di-2-thienyl-20,10,30-benzothiadiazole)] (PCDTBT), Poly[2,5-bis(2-decyldodecyl)pyrrolo[3,4-c]pyrrole-1,4(2H,5H)-dione-(E)-1,2-di(2,20-bithiophen-5-yl) ethene] (PDPPDBTE), 4,8-dithien-2-yl-benzo[1,2-d;4,5-d′]bistriazole-alt-benzo[1,2-b:4,5b′]dithiophenes (pBBTa-BDTs), pBBTa-BDT1, pBBTa-BDT2 polymers, poly(3-hexylthiophene) (P3HT), poly(4,4′-bis(N-carbazolyl)-1,1′-biphenyl) (PPN), triarylamine (TAA) and/or thiophene moieties, Paracyclophane, Triptycene, and Bimesitylene, Thiophene and Furan-based hole transport materials, Dendrimer-like and star-type hole transport materials, VO, VOX, MoC, WO, ReO, NiOx, AgOx, CuO, Cu2O, V2O5, CuI, CuS, CuInS2, colloidal quantum dots, lead sulphide (PbS), CuSCN, Cu2ZnSnS4, Au nanoparticles and their derivatives. Thiophene derivatives, Triptycene derivatives, Triazine derivatives, Porphyrin derivatives, Triphenylamine derivatives, Tetrathiafulvalene derivatives, Carbazole derivatives and Phthalocyanine derivatives. As used herein, when a material is referred to a “derivate” or as “derivatives,” such as Triphenylamine derivatives, the material contains Triphenylamine in its backbone structure. In certain embodiments, the hole transport layer is selected from the group consisting of PTAA, Spiro-OMeTAD, PEDOT:PSS, NiO, MoO₃, V₂O₅, Poly-TPD, EH44, P3HT, and a combination thereof.

In certain embodiments, the electron transport layer comprises at least one of LiF, CsP, LiCoO₂, CsCO₃, TiO_{X}, TiO₂, nanorods (NRs), ZnO, ZnO nanorods (NRs), ZnO nanoparticles (NPs), Al₂O₃, CaO, bathocuproine (BCP), copper phthalocyanine (CuPc), pentacene, pyronin B, pentadecafluorooctyl phenyl-C60-butyrate (F-PCBM), C60, C60/LiF, ZnO NRS/PCBM, ZnO/cross-linked fullerene derivative (C-PCBSD), single walled carbon nanotubes (SWCNT), poly(ethylene glycol) (PEG), poly(dimethylsiloxane-block-methyl methacrylate) (PDMS-b-PMMA), polar polyfluorene (PF-EP), polyfluorene bearing lateral amino groups (PFN), polyfluorene bearing quaternary ammonium groups in the side chains (WPF-oxy-F), polyfluorene bearing quaternary ammonium groups in the side chains (WPF-6-oxy-F), fluorene alternating and random copolymer bearing cationic groups in the alkyl side chains (PFNBr DBT15), fluorene alternating and random copolymer bearing cationic groups in the alkyl side chains (PFPNBr), poly (ethylene oxide) (PEO), and fullerene derivatives. In certain embodiments, the electron transport layer is selected from the group consisting of C60, BCP, TiO₂, SnO₂, PCBM, ICBA, ICMA, ZnO, ZrAcac, LiF, TPBI, PFN, Nb₂O₅, and a combination thereof.

In certain embodiments of the above solar cells, said hole transport layer is disposed on said transparent conductive oxide layer;
said active layer comprising the polycrystalline film is disposed on said hole transport layer;
said electron transport layer is disposed on said active layer; and
said conductive electrode layer is disposed on said electron transport layer;
   wherein:
said transparent conductive oxide layer is indium tin oxide;
said hole transport layer is PTAA;
said electron transport layer is C₆₀; and
said conductive electrode layer is Cu.

In certain embodiments of the above solar cell, the cell contains a buffer layer of BCP disposed on the electron transport layer.

In any of the embodiments above wherein the first transport layer is a hole transport layer and the second transport layer is an electron transport layer, the solar cell can further comprise a buffer layer disposed on the electron transport layer, wherein the conductive electrode is disposed on the buffer layer. In certain embodiments, the buffer layer is selected from the group consisting of PDI, PDINO, PFN, PFN-Br, SnO₂, ZnO, ZrAcac, TiO₂, BCP, LiF, PPDIN6, and TPBi. In certain embodiments, the buffer layer is BCP.

In certain embodiments of the above solar cells, the solar cell further comprises a glass layer, wherein the transparent conductive oxide layer is disposed directly on the glass layer. In certain embodiments, the glass is used to encapsulate the solar cell. In embodiments, the glass layer comprises silica (SiO₂). In certain aspects, the solar cells comprise a first glass layer and a second glass layer, wherein the conductive oxide layer is disposed on said first glass layer and said second glass layer is disposed on said conductive electrode. In certain embodiments, the glass layer has a thickness of about 1.1 mm. In certain embodiment, the glass layer has a thickness of about 0.5, 0.6, 0.7, 0.8, 0.9, 1.0, 1.1, 1.2, 1.3. 1.4, or 1.5 mm. In certain embodiments, the glass encapsulates the solar cell or solar module by coating the edges of the glass with epoxy and contacting them with the cell or module.

In certain embodiments, the subject matter described herein is directed to a solar module, comprising a plurality of any one of the solar cells described herein.

In certain embodiments the conductive electrode layer has a thickness of about 1 nm to about 1000 μm, about 100 nm to about 500 nm, about 1 m to about 500 μm, about 250 m to about 1000 μm, or about 250 nm to about 250 μm. In certain embodiments, the metal electrode has a thickness of about 10 nm, 50 nm, 100 nm, 150 nm, 200 nm, 300 nm, 400 nm, 500 nm, 550 nm, 1 μm, 10 μm, 20 μm, 30 μm, 40 μm, 50 μm, 60 μm, 70 μm, 80 μm, 100 μm, 150 μm, 200 μm, 250 μm, 300 μm, 350 μm, 400 μm, 450 μm, 500 μm, 550 μm, 600 μm, 700 μm, 800 μm, 900 μm, or 100 μm.

In certain embodiments, the transparent conductive oxide layer has a thickness of about 1 nm to about 1000 μm, about 100 nm to about 500 nm, about 1 m to about 500 μm, about 250 m to about 1000 μm, or about 250 nm to about 250 μm. In certain embodiments, the transparent conductive layer has a thickness of about 10 nm, 50 nm, 100 nm, 150 nm, 200 nm, 300 nm, 400 nm, 500 nm, 550 nm, 1 μm, 10 μm, 20 μm, 30 μm, 40 μm, 50 μm, 60 μm, 70 μm, 80 μm, 100 μm, 150 μm, 200 μm, 250 μm, 300 μm, 350 μm, 400 μm, 450 μm, 500 μm, 550 μm, 600 μm, 700 μm, 800 μm, 900 μm, or 100 m.

In certain embodiments, the first and second transport layers each individually have a thickness of about 0.1 nm to about 10 μm, about 0.5 nm to about 100 nm, about 10 nm to about 500 nm, about 300 nm to about 700 nm, about 100 nm to about 1 μm, about 1 μm to about 10 μm, or about 800 nm to about 5 μm. In certain embodiments, the first and second transport layers each individually have a thickness of about 0.1 nm, 0.5 nm, 1.0 nm, 2.0 nm, 5.0 nm, 10 nm, 20 nm, 30 nm, 40 nm, 50 nm, 60 nm, 70 nm, 80 nm, 90 nm, 100 nm, 150 nm, 200 nm, 250 nm, 300 nm, 350 nm, 400 nm, 450 nm, 500 nm, 550 nm, 600 nm, 650 nm, 700 nm, 750 nm, 800 nm, 850 nm, 900 nm, 950 nm, 1000 nm, 1 μm, 2 μm, 3 μm, 4 μm, 5 μm, 6 μm, 7 μm, 8 μm, 9 μm, or 10 μm.

In certain embodiments, the solar cell described herein exhibits a Power Conversion Efficiency (PCE) of at least 17%, 18%, 19%, 20%, 20.1%, 20.2%, 20.3%, 20.4%, 20.5%, 20.6%, 20.7%, 20.8%, 20.9%, 21%, 21.1%, 21.2%, 21.3%, 21.4%, 21.5%, 21.6%, 21.7%, 21.8%, 21.9%, 22%, 22.1%, 22.2%, 22.3%, 22.4%, 22.5%, 22.6%, 22.7%, 22.8%, 22.9%, 23%, 23.1%, 23.2%, 23.3%, 23.4%, 23.5%, 23.6%, 23.7%, 23.8%, 23.9%, 24%, 24.1%, 24.2%, 24.3%, 24.4%, 24.5%, 24.6%, 24.7%, 24.8%, 24.9%, or 25%. Conditions and methods under which the solar cell exhibits its PCE can be found in the Examples below.

In certain embodiments, the solar modules described herein have an aperture area of at least 1 cm², 2 cm², 3 cm², 4 cm², 5 cm², 6 cm², 7 cm², 8 cm², 9 cm², 10 cm², 11 cm² 12 cm², 13 cm², 14 cm², 15 cm², 16 cm², 17 cm², 18 cm², 19 cm², 20 cm², 21 cm², 22 cm², 23 cm², 24 cm², 25 cm², 26 cm², 27 cm², 28 cm², 29 cm², 30 cm², 31 cm², 32 cm² 33 cm², 34 cm², 35 cm², 36 cm², 36.5 cm², 36.6 cm², 36.7 cm², 36.8 cm², 36.9 cm², 37 cm², 37.1 cm², 37.2 cm², 37.3 cm², 37.4 cm², 37.5 cm², 37.6 cm², 37.8 cm², 37.9 cm², 38 cm², 38.1 cm². 38.2 cm², 38.3 cm², 38.4 cm², 38.5 cm², 38.6 cm², 38.7 cm², 38.8 cm², 38.9 cm², 39 cm², 39.1 cm², 39.2 cm², 39.3 cm², 39.4 cm², 39.5 cm², 39.6 cm², 39.7 cm², 39.8 cm², 39.9 cm², 40 cm², 41 cm², 42 cm², 43 cm², 44 cm², 45 cm², 46 cm², 47 cm², 48 cm², 49 cm², 50 cm², 51 cm², 52 cm², 53 cm², 54 cm², 55 cm², 56 cm², 57 cm², 58 cm², 59 cm², 60 cm², 61 cm², 62 cm², 63 cm², 64 cm², 65 cm², 66 cm², 67 cm², 68 cm², 69 cm², 70 cm², 75 cm², 80 cm², 85 cm², 90 cm², 95 cm², or 100 cm². In certain embodiments, the solar modules described herein exhibit a Power Conversion Efficiency of at least 16%, 16.5%, 17%, 17.5%, 18%, 18.1%, 18.2%, 18.3%, 18.4%, 18.5%, 18.6%, 18.7%, 18.8%, 18.9%, 19%, 20%, 20.1%, 20.2%, 20.3%, 20.4%, 20.5%, 20.6%, 20.7%, 20.8%, 20.9%, or 21%. Conditions and methods under which the solar module exhibits its PCE can be found in the Examples below.

### VII. Articles of Manufacture

In certain embodiments, the subject matter described herein is directed to a kit, comprising:
i) a vial containing a perovskite precursor solution comprising a solvent and a composition of Formula (I)

ABI_{3-y}X_{y} (I)
wherein A is a cation selected from the group consisting of methylammonium (MA), tetramethylammonium, formamidinium (FA), cesium (Cs), rubidium (Rb), potassium (K), sodium (Na), butylammonium (BA), phenethylammonium (PEA), phenylammonium (PA), guanidinium (GA), and a combination thereof;
B is a metal cation selected from the group consisting of lead, tin, calcium, cadmium, germanium, zinc, nickel, platinum, palladium, mercury, titanium, silicon, and a combination thereof;
X is selected from the group consisting of Cl⁻, Br⁻, F⁻, SCN⁻, and a combination thereof;
and
   y is between 0 and 3; and
ii) a vial containing a compound of Formula (II):

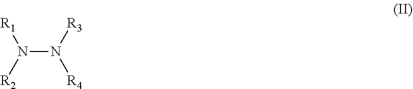

wherein, R₁, R₂, R₃, and R₄ are each independently selected from the group consisting of hydrogen, C₁-C₄₀ alkyl, C₂-C₄₀ alkenyl, C₂-C₄₀ alkynyl, aminoalkyl, C₆-C₁₂ aryl, C₃-C₇ cycloalkyl, 4- to 7-membered heterocyclyl, 5- to 10-membered heteroaryl, C₆-C₁₂ aryl-C₁-C₁₀ alkyl, C₃-C₇ cycloalkyl-C₁-C₁₀ alkyl, 4- to 7-membered heterocyclyl-C₁-C₁₀ alkyl, 5- to 10-membered heteroaryl-C₁-C₁₀ alkyl, and C₁-C₂₀ alkyl-thio-C₁-C₂₀ alkyl, each of which is optionally substituted one or more times with a substituent, each independently selected from the group consisting of halogen, cyano, hydrazino, C₁-C₂₀ alkyl, amino, C₁-C₂₀ alkoxy, C₂-C₂₀ alkenyl, C₂-C₂₀ alkynyl, C₆-C₁₂ aryl, C₃-C₇ cycloalkyl, 4- to 7-membered heterocyclyl, and 5- to 10-membered heteroaryl;
   wherein one or more carbon atoms in said “alkyl” of C₁-C₄₀ alkyl, aminoalkyl, C₆-C₁₂ aryl-C₁-C₁₀ alkyl, C₃-C₇ cycloalkyl-C₁-C₁₀ alkyl, 4- to 7-membered heterocyclyl-C₁-C₁₀ alkyl, 5- to 10-membered heteroaryl-C₁-C₁₀ alkyl, or C₁-C₂₀ alkyl-thio-C₁-C₂₀ alkyl are optionally:
      i. replaced with O or S; and/or
      ii. substituted with (═O);
         or, a salt thereof.
         The subject matter described herein is directed to the following embodiments:

1. An oxidative-resistant ink solution, comprising:
a) a composition of Formula (I):

ABI_{3-y}X_{y} (I)
wherein A is a cation selected from the group consisting of methylammonium (MA), tetramethylammonium, formamidinium (FA), cesium (Cs), rubidium (Rb), potassium (K), sodium (Na), butylammonium (BA), phenethylammonium (PEA), phenylammonium (PA), guanidinium (GA), and a combination thereof;
B is a metal cation selected from the group consisting of lead, tin, calcium, cadmium, germanium, zinc, nickel, platinum, palladium, mercury, titanium, silicon, and a combination thereof;
X is selected from the group consisting of Cl⁻, Br⁻, F⁻, SCN⁻, and a combination thereof;
and
   y is between 0 and 3;
b) one or more solvents;
   and
c) a compound of Formula (II):

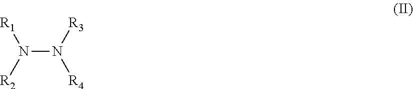

wherein, R₁, R₂, R₃, and R₄ are each independently selected from the group consisting of hydrogen, C₁-C₄₀ alkyl, C₂-C₄₀ alkenyl, C₂-C₄₀ alkynyl, aminoalkyl, C₆-C₁₂ aryl, C₃-C₇ cycloalkyl, 4- to 7-membered heterocyclyl, 5- to 10-membered heteroaryl, C₆-C₁₂ aryl-C₁-C₁₀ alkyl, C₃-C₇ cycloalkyl-C₁-C₁₀ alkyl, 4- to 7-membered heterocyclyl-C₁-C₁₀ alkyl, 5- to 10-membered heteroaryl-C₁-C₁₀ alkyl, and C₁-C₂₀ alkyl-thio-C₁-C₂₀ alkyl, each of which is optionally substituted one or more times with a substituent, each independently selected from the group consisting of halogen, cyano, hydrazino, C₁-C₂₀ alkyl, amino, C₁-C₂₀ alkoxy, C₂-C₂₀ alkenyl, C₂-C₂₀ alkynyl, C₆-C₁₂ aryl, C₃-C₇ cycloalkyl, 4- to 7-membered heterocyclyl, and 5- to 10-membered heteroaryl;
wherein one or more carbon atoms in said “alkyl” of C₁-C₄₀ alkyl, aminoalkyl, C₆-C₁₂ aryl-C₁-C₁₀ alkyl, C₃-C₇ cycloalkyl-C₁-C₁₀ alkyl, 4- to 7-membered heterocyclyl-C₁-C₁₀ alkyl, 5- to 10-membered heteroaryl-C₁-C₁₀ alkyl, or C₁-C₂₀ alkyl-thio-C₁-C₂₀ alkyl are optionally:
   i. replaced with O or S; and/or
   ii. substituted with (═O);
or, a salt thereof,
provided that when B is tin, said compound of Formula (II), or salt thereof, is other than hydrazinium chloride.

2. The oxidative-resistant ink solution of embodiment 1, wherein y in said composition of Formula (I) is 0.

3. The oxidative-resistant ink solution of embodiment 1 or 2, wherein A in said composition of Formula (I) is selected from the group consisting of Cs, MA, FA, and a combination thereof.

4. The oxidative-resistant ink solution of any one of embodiments 1-3, wherein B is lead.

5. The oxidative-resistant ink solution of embodiment 1, wherein said composition of Formula (I) is Cs_{z}MA_{1-x-z}FAₓPbI₃, wherein x and z are each individually between 0 and 1.

6. The oxidative-resistant ink solution of embodiment 5, wherein z is selected from the group consisting of 0, 0.05, 0.08, 0.09, 0.1, 0.12, 0.15.

7. The oxidative-resistant ink solution of embodiment 5 or 6, wherein x is 0.3 and z is 0.

8. The oxidative-resistant ink solution of any one of embodiments 1-7, wherein said one or more solvents are selected from the group consisting of dimethyl sulfoxide, dimethylformamide, N-methyl-2-pyrrolidone, γ-butyrolactone, 2-methoxyethanol, and acetonitrile.

9. The oxidative-resistant ink solution of any one of embodiments 1-8, wherein said one or more solvents is 2-methoxyethanol.

9a. The oxidative-resistant ink solution of any one of embodiments 1-8, wherein said one or more solvents are 2-methoxyethanol and dimethyl sulfoxide.

9b. The oxidative-resistant ink solution of embodiment 9a, wherein said dimethyl sulfoxide is present in said solution in a range of about 0.5% v/v to about 5% v/v.

10. The oxidative-resistant ink solution of any one of embodiments 1-9, wherein in said compound or salt of Formula (II), R₃ and R₄ are each hydrogen, R₁ is hydrogen, and R₂ is selected from the group consisting of C₁-C₄₀ alkyl, C₂-C₄₀ alkenyl, C₂-C₄₀ alkynyl, aminoalkyl, C₆-C₁₂ aryl, C₃-C₇ cycloalkyl, 4- to 7-membered heterocyclyl, 5- to 7-membered heteroaryl, C₆-C₁₂ aryl-C₁-C₁₀ alkyl, C₃-C₇ cycloalkyl-C₁-C₁₀ alkyl, 4- to 7-membered heterocyclyl-C₁-C₁₀ alkyl, 5- to 10-membered heteroaryl-C₁-C₁₀ alkyl, and C₁-C₂₀ alkyl-thio-C₁-C₂₀ alkyl, each of which is optionally substituted one or more times with a substituent, each independently selected from the group consisting of halogen, cyano, hydrazino, C₁-C₂₀ alkyl, amino, C₁-C₂₀ alkoxy, C₂-C₂₀ alkenyl, C₂-C₂₀ alkynyl, C₆-C₁₂ aryl, C₃-C₇ cycloalkyl, 4- to 7-membered heterocyclyl, and 5- to 10-membered heteroaryl;
wherein one or more carbon atoms in said “alkyl” of C₁-C₄₀ alkyl, aminoalkyl, C₆-C₁₂ aryl-C₁-C₁₀ alkyl, C₃-C₇ cycloalkyl-C₁-C₁₀ alkyl, 4- to 7-membered heterocyclyl-C₁-C₁₀ alkyl, 5- to 10-membered heteroaryl-C₁-C₁₀ alkyl, C₁-C₂₀ alkyl-thio-C₁-C₂₀ alkyl are optionally:
i. replaced with O or S; and/or
ii. substituted with (═O).

10a. The oxidative-resistant ink solution of embodiment 10, wherein R₂ is C₁-C₁₀ alkyl, optionally substituted with hydrazino, and wherein one or more atoms in said alkyl are substituted with (═O).

10b. The oxidative-resistant ink solution of embodiment 10a, wherein R₂ is

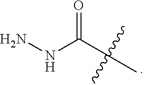 [SMILES: *C(=O)NN]

11. The oxidative-resistant ink solution of any one of embodiments 1-10, wherein R₂ is selected from the group consisting of C₁-C₁₀ alkyl, C₆-C₁₂ aryl-C₁-C₆ alkyl, and 5- to 10-membered heteroaryl-C₁-C₆ alkyl.

12. The oxidative-resistant ink solution of any one of embodiments 1-11, wherein R₂ is C₆-C₁₂ aryl-C₁-C₆ alkyl.

13. The oxidative-resistant ink solution of any one of embodiments 1-12, wherein R₂ is benzyl.

14. The oxidative-resistant ink solution of any one of embodiments 1-13, wherein R₂ is C₁-C₁₀ alkyl.

15. The oxidative-resistant ink solution of any one of embodiments 1-14, wherein R₂ is selected from the group consisting of methyl, ethyl, propyl, and butyl.

16. The oxidative-resistant ink solution of any one of embodiments 1-15, wherein R₂ is propyl.

17. The oxidative-resistant ink solution of any one of embodiments 1-16, wherein R₂ is 5- to 10-membered heteroaryl-C₁-C₆ alkyl.

18. The oxidative-resistant ink solution of any one of embodiments 1-17, wherein R₂ is thiophene-methyl.

19. The oxidative-resistant ink solution of any one of embodiments 1-18, wherein said compound of Formula (II) is a salt.

20. The oxidative-resistant ink solution of embodiment 19, wherein said salt is

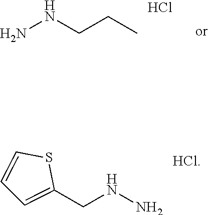

21. The oxidative-resistant ink solution of embodiment 19, wherein said salt is

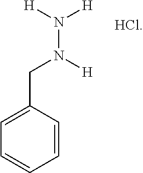

22. The oxidative-resistant ink solution of embodiment 1, wherein said composition of Formula (I) is MA_{0.7}FA_{0.3}PbI₃, said compound of Formula (II) or salt thereof is

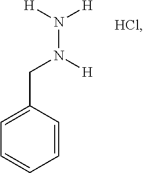

and said one or more solvents is 2-methoxyethanol.

22a. The oxidative-resistant ink solution of embodiment 1, wherein said composition of Formula (I) is MA_{0.7}FA_{0.3}PbI₃, said compound of Formula (II) or salt thereof is

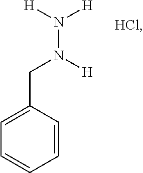

and said one or more solvents are 2-methoxyethanol and dimethyl sulfoxide, wherein said dimethyl sulfoxide is present in said solution at about 2.8% v/v.

22b. The oxidative-resistant ink solution of any one of embodiments 1-19, wherein said compound of Formula (II), or salt thereof is

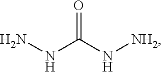

wherein said compound of Formula (II) is present in said solution at about 0.5 mol % to about 5 mol % relative to said composition of Formula I; said composition of Formula I is APbI₃, wherein A is a cation selected from the group consisting of methylammonium (MA), formamidinium (FA), cesium (Cs), and a combination thereof, said one or more solvents are 2-methoxyethanol and dimethyl sulfoxide, and wherein said dimethyl sulfoxide is present in said solution at about 5 to 40 mol % relative to said composition of Formula I.

22c. The oxidative-resistant ink solution of embodiment 22b, wherein said compound of Formula (II) is present in said solution at about 1.5 mol % relative to said composition of Formula I; and said dimethyl sulfoxide is present in said solution at about 25 mol % relative to said composition of Formula I.

23. The oxidative-resistant ink solution of any one of embodiments 1-19, wherein said compound of Formula (II), or salt thereof, is present in said ink solution in a molar percent of about 0.01 to about 5 relative to said composition of Formula (I).

24. The oxidative-resistant ink solution of any one of embodiments 1-19 or 23, wherein said compound of Formula (II), or salt thereof, is present in said ink solution in a molar percent of about 0.01 to about 1.5 relative to said composition of Formula (I).

25. The oxidative-resistant ink solution of any one of embodiments 1-19 or 23-24, wherein said compound of Formula (II), or salt thereof, is present in said ink solution in a molar percent of about 0.15 to about 0.75 relative to said composition of Formula (I).

26. The oxidative-resistant ink solution of any one of embodiments 1-19 or 23-25, wherein said compound of Formula (II), or salt thereof, is present in said ink solution in a molar percent of about 0.26 relative to said composition of Formula (I).

27. A method of preparing an oxidative-resistant ink solution, comprising:
contacting an ink solution comprising a composition of Formula (I) with a compound of Formula (II), or a salt thereof;

ABI_{3-y}X_{y} (I)
wherein A is a cation selected from the group consisting of methylammonium (MA), tetramethylammonium, formamidinium (FA), cesium (Cs), rubidium (Rb), potassium (K), sodium (Na), butylammonium (BA), phenethylammonium (PEA), phenylammonium (PA), guanidinium (GA), and a combination thereof;
B is a metal cation selected from the group consisting of lead, tin, calcium, cadmium, germanium, zinc, nickel, platinum, palladium, mercury, titanium, silicon, and a combination thereof;
X is selected from the group consisting of Cl⁻, Br⁻, F⁻, SCN⁻, and a combination thereof;
and
   y is between 0 and 3;

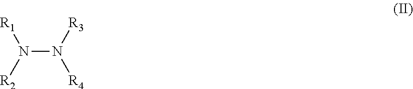

wherein, R₁, R₂, R₃, and R₄ are each independently selected from the group consisting of hydrogen, C₁-C₄₀ alkyl, C₂-C₄₀ alkenyl, C₂-C₄₀ alkynyl, aminoalkyl, C₆-C₁₂ aryl, C₃-C₇ cycloalkyl, 4- to 7-membered heterocyclyl, 5- to 10-membered heteroaryl, C₆-C₁₂ aryl-C₁-C₁₀ alkyl, C₃-C₇ cycloalkyl-C₁-C₁₀ alkyl, 4- to 7-membered heterocyclyl-C₁-C₁₀ alkyl, 5- to 10-membered heteroaryl-C₁-C₁₀ alkyl, and C₁-C₂₀ alkyl-thio-C₁-C₂₀ alkyl, each of which is optionally substituted one or more times with a substituent, each independently selected from the group consisting of halogen, cyano, hydrazino, C₁-C₂₀ alkyl, amino, C₁-C₂₀ alkoxy, C₂-C₂₀ alkenyl, C₂-C₂₀ alkynyl, C₆-C₁₂ aryl, C₃-C₇ cycloalkyl, 4- to 7-membered heterocyclyl, and 5- to 10-membered heteroaryl;
   wherein one or more carbon atoms in said “alkyl” of C₁-C₄₀ alkyl, aminoalkyl, C₆-C₁₂ aryl-C₁-C₁₀ alkyl, C₃-C₇ cycloalkyl-C₁-C₁₀ alkyl, 4- to 7-membered heterocyclyl-C₁-C₁₀ alkyl, 5- to 10-membered heteroaryl-C₁-C₁₀ alkyl, or C₁-C₂₀ alkyl-thio-C₁-C₂₀ alkyl are optionally:
      i. replaced with O or S; and/or
      ii. substituted with (═O);
provided that when B is tin, said compound of Formula (II), or salt thereof, is other than hydrazinium chloride or 4-fluorobenzohydrazide, wherein said oxidative-resistant ink solution is prepared.

28. A method of reducing oxidation in an ink solution, comprising contacting an ink solution comprising a composition of Formula (I) with an oxidative reducing amount of a compound of Formula (II), or a salt thereof;

ABI_{3-y}X_{y} (I)
wherein A is a cation selected from the group consisting of methylammonium (MA), tetramethylammonium, formamidinium (FA), cesium (Cs), rubidium (Rb), potassium (K), sodium (Na), butylammonium (BA), phenethylammonium (PEA), phenylammonium (PA), guanidinium (GA), and a combination thereof;
B is a metal cation selected from the group consisting of lead, tin, calcium, cadmium, germanium, zinc, nickel, platinum, palladium, mercury, titanium, silicon, and a combination thereof;
X is selected from the group consisting of Cl⁻, Br⁻, F⁻, SCN⁻, and a combination thereof;
and
y is between 0 and 3.

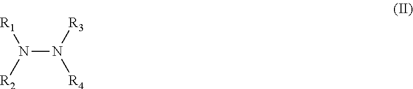

wherein, R₁, R₂, R₃, and R₄ are each independently selected from the group consisting of hydrogen, C₁-C₄₀ alkyl, C₂-C₄₀ alkenyl, C₂-C₄₀ alkynyl, aminoalkyl, C₆-C₁₂ aryl, C₃-C₇ cycloalkyl, 4- to 7-membered heterocyclyl, 5- to 10-membered heteroaryl, C₆-C₁₂ aryl-C₁-C₁₀ alkyl, C₃-C₇ cycloalkyl-C₁-C₁₀ alkyl, 4- to 7-membered heterocyclyl-C₁-C₁₀ alkyl, 5- to 10-membered heteroaryl-C₁-C₁₀ alkyl, and C₁-C₂₀ alkyl-thio-C₁-C₂₀ alkyl, each of which is optionally substituted one or more times with a substituent, each independently selected from the group consisting of halogen, cyano, hydrazino, C₁-C₂₀ alkyl, amino, C₁-C₂₀ alkoxy, C₂-C₂₀ alkenyl, C₂-C₂₀ alkynyl, C₆-C₁₂ aryl, C₃-C₇ cycloalkyl, 4- to 7-membered heterocyclyl, and 5- to 10-membered heteroaryl;
   wherein one or more carbon atoms in said “alkyl” of C₁-C₄₀ alkyl, aminoalkyl, C₆-C₁₂ aryl-C₁-C₁₀ alkyl, C₃-C₇ cycloalkyl-C₁-C₁₀ alkyl, 4- to 7-membered heterocyclyl-C₁-C₁₀ alkyl, 5- to 10-membered heteroaryl-C₁-C₁₀ alkyl, or C₁-C₂₀ alkyl-thio-C₁-C₂₀ alkyl are optionally:
   i. replaced with O or S; and/or
   ii. substituted with (═O);
provided that when B is tin, said compound of Formula (II), or salt thereof, is other than hydrazinium chloride or 4-fluorobenzohydrazide.

29. The method of embodiment 27 or 28, wherein said ink solution comprises one or more solvents selected from the group consisting of dimethyl sulfoxide, dimethylformamide, N-methyl-2-pyrrolidone, γ-butyrolactone, 2-methoxyethanol, and acetonitrile.

30. The method of any one of embodiments 27-29, wherein said solvent is 2-methoxyethanol.

30a. The method of any one of embodiments 27-29, wherein said one or more solvents are 2-methoxyethanol and dimethyl sulfoxide.

31. The method of any one of embodiments 27-30, wherein y in said composition of Formula (I) is 0.

32. The method of any one of embodiments 27-31, wherein A in said composition of Formula (I) is selected from the group consisting of Cs, MA, FA, and a combination thereof.

33. The method of any one of embodiments 27-32, wherein B is lead.

34. The method of any one of embodiments 27-33, wherein said composition of Formula (I) is Cs_{z}MA_{1-x-z}FAₓPbI₃, wherein x and z are each independently between 0 and 1.

35. The method of embodiment 34, wherein z is selected from the group consisting of 0, 0.05, 0.08, 0.09, 0.10, 0.12, and 0.15; and x is selected from the group consisting of 0, 0.2, 0.3, 0.4, and 0.5.

36. The method of embodiment 34 or 35, wherein x is 0.3 and z is 0.

37. The method of any one of embodiments 27-36, wherein in said compound or salt of Formula (II), R₃ and R₄ are each hydrogen, R₁ is hydrogen, and R₂ is selected from the group consisting of C₁-C₄₀ alkyl, C₂-C₄₀ alkenyl, C₂-C₄₀ alkynyl, aminoalkyl, C₆-C₁₂ aryl, C₃-C₇ cycloalkyl, 4- to 7-membered heterocyclyl, 5- to 7-membered heteroaryl, C₆-C₁₂ aryl-C₁-C₁₀ alkyl, C₃-C₇ cycloalkyl-C₁-C₁₀ alkyl, 4- to 7-membered heterocyclyl-C₁-C₁₀ alkyl, 5- to 10-membered heteroaryl-C₁-C₁₀ alkyl, and C₁-C₂₀ alkyl-thio-C₁-C₂₀ alkyl, each of which is optionally substituted one or more times with a substituent, each independently selected from the group consisting of halogen, cyano, hydrazino, C₁-C₂₀ alkyl, amino, C₁-C₂₀ alkoxy, C₂-C₂₀ alkenyl, C₂-C₂₀ alkynyl, C₆-C₁₂ aryl, C₃-C₇ cycloalkyl, 4- to 7-membered heterocyclyl, and 5- to 10-membered heteroaryl;
wherein one or more carbon atoms in said “alkyl” of C₁-C₄₀ alkyl, aminoalkyl, C₆-C₁₂ aryl-C₁-C₁₀ alkyl, C₃-C₇ cycloalkyl-C₁-C₁₀ alkyl, 4- to 7-membered heterocyclyl-C₁-C₁₀ alkyl, 5- to 10-membered heteroaryl-C₁-C₁₀ alkyl, C₁-C₂₀ alkyl-thio-C₁-C₂₀ alkyl are optionally:
i. replaced with O or S; and/or
ii. substituted with (═O).

37a. The method of embodiment 37, wherein R₂ is C₁-C₁₀ alkyl, optionally substituted with hydrazino, and wherein one or more atoms in said alkyl are substituted with (═O).

37b. The method of embodiment 37a, wherein R₂ is

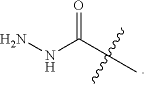 [SMILES: *C(=O)NN]

38. The method of any one of embodiments 27-27, wherein R₂ is selected from the group consisting of C₁-C₁₀ alkyl, C₆-C₁₂ aryl-C₁-C₆ alkyl, and 5- to 10-membered heteroaryl-C₁-C₆ alkyl.

39. The method of any one of embodiments 27-38, wherein R₂ is C₆-C₁₂ aryl-C₁-C₆ alkyl.

40. The method of any one of embodiments 27-39, wherein R₂ is benzyl.

41. The method of any one of embodiments 27-40, wherein R₂ is C₁-C₁₀ alkyl.

42. The method of any one of embodiments 27-41, wherein R₂ is selected from the group consisting of methyl, ethyl, propyl, and butyl.

43. The method of any one of embodiments 27-42, wherein R₂ is propyl.

44. The method of any one of embodiments 27-43, wherein R₂ is 5- to 10-membered heteroaryl-C₁-C₆ alkyl.

45. The method of any one of embodiments 27-44, wherein R₂ is thiophene-methyl.

46. The method of any one of embodiments 27-45, wherein said compound of Formula (II) is a salt.

47. The method of embodiment 46, wherein said salt is

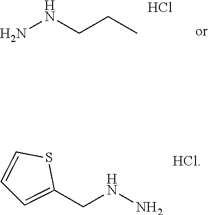

48. The method of embodiment 46, wherein said salt is

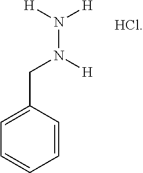

49. The method of any one of embodiments 27-48, wherein said composition of Formula (I) is MA_{0.7}FA_{0.3}PbI₃ and said compound of Formula (II) or salt thereof is

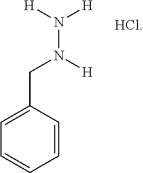

50. The method of any one of embodiments 27-49, wherein said compound of Formula (II), or salt thereof, is contacted with said ink solution comprising said composition of Formula (I) in a molar percent of about 0.01 to about 5 relative to said composition of Formula (I).

51. The method of any one of embodiments 27-49 or 50, wherein said compound of Formula (II), or salt thereof, is contacted with said ink solution comprising said composition of Formula (I) in a molar percent of about 0.01 to about 1.5 relative to said composition of Formula (I).

52. The method of any one of embodiments 27-49 or 50-51, wherein said compound of Formula (II), or salt thereof, is contacted with said ink solution comprising said composition of Formula (I) in a molar percent of about 0.15 to about 0.75 relative to said composition of Formula (I).

53. The method of any one of embodiments 27-49 or 50-52, wherein said compound of Formula (II), or salt thereof, is contacted with said ink solution comprising said composition of Formula (I) in a molar percent of about 0.26 relative to said composition of Formula (I).

54. The oxidative-resistant ink solution of any one of embodiments 1-26, having a vapor pressure of about 5 to about 100 kPa, for use in a fast-coating process, wherein said fast coating process is selected from the group consisting of blade-coating, slot die coating, shear coating, gravure coating, brush coating, syringe coating, and screen printing.

55. A method for producing a polycrystalline perovskite film using the oxidative-resistant ink solution of any one of embodiments 1-26, said method comprising: contacting said ink solution using a fast coating process onto a substrate to form a film, wherein said fast coating process is selected from the group consisting of blade coating, slot die coating, shear coating, gravure coating, brush coating, syringe coating, and screen printing.

56. The method of embodiment 55, wherein said fast-coating process is blade coating.

57. The method of embodiment 55, wherein said method produces a polycrystalline perovskite film having an area of at least 0.01 cm².

58. A polycrystalline film comprising:
a) a composition of Formula (I):

ABI_{3-y}X_{y} (I)
wherein A is a cation selected from the group consisting of methylammonium (MA), tetramethylammonium, formamidinium (FA), cesium (Cs), rubidium (Rb), potassium (K), sodium (Na), butylammonium (BA), phenethylammonium (PEA), phenylammonium (PA), guanidinium (GA), and a combination thereof;
B is a metal cation selected from the group consisting of lead, tin, calcium, cadmium, germanium, zinc, nickel, platinum, palladium, mercury, titanium, silicon, and a combination thereof;
X is selected from the group consisting of Cl⁻, Br⁻, F⁻, SCN⁻, and a combination thereof;
and
   y is between 0 and 3;
      and
b) a compound of Formula (II):

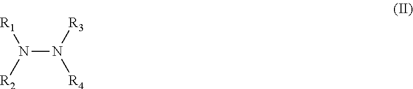

wherein, R₁, R₂, R₃, and R₄ are each independently selected from the group consisting of hydrogen, C₁-C₄₀ alkyl, C₂-C₄₀ alkenyl, C₂-C₄₀ alkynyl, aminoalkyl, C₆-C₁₂ aryl, C₃-C₇ cycloalkyl, 4- to 7-membered heterocyclyl, 5- to 10-membered heteroaryl, C₆-C₁₂ aryl-C₁-C₁₀ alkyl, C₃-C₇ cycloalkyl-C₁-C₁₀ alkyl, 4- to 7-membered heterocyclyl-C₁-C₁₀ alkyl, 5- to 10-membered heteroaryl-C₁-C₁₀ alkyl, and C₁-C₂₀ alkyl-thio-C₁-C₂₀ alkyl, each of which is optionally substituted one or more times with a substituent, each independently selected from the group consisting of halogen, cyano, hydrazino, C₁-C₂₀ alkyl, amino, C₁-C₂₀ alkoxy, C₂-C₂₀ alkenyl, C₂-C₂₀ alkynyl, C₆-C₁₂ aryl, C₃-C₇ cycloalkyl, 4- to 7-membered heterocyclyl, and 5- to 10-membered heteroaryl;
   wherein one or more carbon atoms in said “alkyl” of C₁-C₄₀ alkyl, aminoalkyl, C₆-C₁₂ aryl-C₁-C₁₀ alkyl, C₃-C₇ cycloalkyl-C₁-C₁₀ alkyl, 4- to 7-membered heterocyclyl-C₁-C₁₀ alkyl, 5- to 10-membered heteroaryl-C₁-C₁₀ alkyl, or C₁-C₂₀ alkyl-thio-C₁-C₂₀ alkyl are optionally:
      i. replaced with O or S; and/or
      ii. substituted with (═O);
or, a salt thereof;
provided that when B is tin, said compound of Formula (II), or salt thereof, is other than hydrazinium chloride or 4-fluorobenzohydrazide.

58a. The polycrystalline film of embodiment 58, wherein said film is characterized as having reduced interfacial voids.

59. The polycrystalline film of embodiment 58, wherein y in said composition of Formula (I) is 0.

60. The polycrystalline film of embodiment 58 or 59, wherein A in said composition of Formula (I) is selected from the group consisting of Cs, MA, FA, and a combination thereof.

61. The polycrystalline film of any one of embodiments 58-60, wherein B is lead.

62. The polycrystalline film of any one of embodiments 58-61, wherein said composition of Formula (I) is Cs_{z}MA_{1-x-z}FAₓPbI₃, wherein x and z are between 0 and 1.

63. The polycrystalline film of embodiment 62, wherein z is selected from the group consisting of 0, 0.05, 0.08, 0.09, 0.10, 0.12, and 0.15; and x is selected from the group consisting of 0, 0.2, 0.3, 0.4, and 0.5.

64. The polycrystalline film of embodiment 62 or 63, wherein x is 0.3 and z is 0.

65. The polycrystalline film of any one of embodiments 58-64, wherein in said compound or salt of Formula (II), R₃ and R₄ are each hydrogen, R₁ is hydrogen, and R₂ is selected from the group consisting of C₁-C₄₀ alkyl, C₂-C₄₀ alkenyl, C₂-C₄₀ alkynyl, aminoalkyl, C₆-C₁₂ aryl, C₃-C₇ cycloalkyl, 4- to 7-membered heterocyclyl, 5- to 7-membered heteroaryl, C₆-C₁₂ aryl-C₁-C₁₀ alkyl, C₃-C₇ cycloalkyl-C₁-C₁₀ alkyl, 4- to 7-membered heterocyclyl-C₁-C₁₀ alkyl, 5- to 10-membered heteroaryl-C₁-C₁₀ alkyl, and C₁-C₂₀ alkyl-thio-C₁-C₂₀ alkyl, each of which is optionally substituted one or more times with a substituent, each independently selected from the group consisting of halogen, cyano, hydrazino, C₁-C₂₀ alkyl, amino, C₁-C₂₀ alkoxy, C₂-C₂₀ alkenyl, C₂-C₂₀ alkynyl, C₆-C₁₂ aryl, C₃-C₇ cycloalkyl, 4- to 7-membered heterocyclyl, and 5- to 10-membered heteroaryl;
wherein one or more carbon atoms in said “alkyl” of C₁-C₄₀ alkyl, aminoalkyl, C₆-C₁₂ aryl-C₁-C₁₀ alkyl, C₃-C₇ cycloalkyl-C₁-C₁₀ alkyl, 4- to 7-membered heterocyclyl-C₁-C₁₀ alkyl, 5- to 10-membered heteroaryl-C₁-C₁₀ alkyl, C₁-C₂₀ alkyl-thio-C₁-C₂₀ alkyl are optionally:
i. replaced with O or S; and/or
ii. substituted with (═O).

65a. The polycrystalline film of embodiment 65, wherein R₂ is C₁-C₁₀ alkyl, optionally substituted with hydrazino, and wherein one or more atoms in said alkyl are substituted with (═O).

65b. The oxidative-resistant ink solution of embodiment 65a, wherein R₂ is

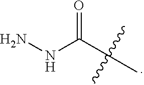 [SMILES: *C(=O)NN]

66. The polycrystalline film of any one of embodiments 58-65, wherein R₂ is selected from the group consisting of C₁-C₁₀ alkyl, C₆-C₁₂ aryl-C₁-C₆ alkyl, and 5- to 10-membered heteroaryl-C₁-C₆ alkyl.

67. The polycrystalline film of any one of embodiments 58-66, wherein R₂ is C₆-C₁₂ aryl-C₁-C₆ alkyl.

68. The polycrystalline film of any one of embodiments 58-67, wherein R₂ is benzyl.

69. The polycrystalline film of claim 66, wherein R₂ is C₁-C₁₀ alkyl.

70. The polycrystalline film of any one of embodiments 58-69, wherein R₂ is selected from the group consisting of methyl, ethyl, propyl, and butyl.

71. The polycrystalline film of any one of embodiments 58-70, wherein R₂ is propyl.

72. The polycrystalline film of any one of embodiments 58-71, wherein R₂ is 5- to 10-membered heteroaryl-C₁-C₆ alkyl.

73. The polycrystalline film of any one of embodiments 58-72, wherein R₂ is thiophene-methyl.

74. The polycrystalline film of any one of embodiments 58-73, wherein said compound of Formula (II) is a salt.

75. The polycrystalline film of embodiment 74, wherein said salt is

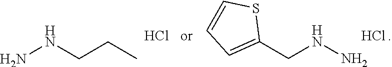

76. The polycrystalline film of embodiment 74, wherein said salt is

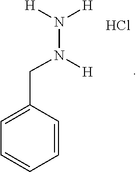

77. The polycrystalline film of embodiment 58, wherein said composition of Formula (I) is MA_{0.7}FA_{0.3}PbI₃ and said compound of Formula (II) or salt thereof is

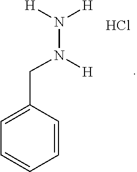

78. The polycrystalline film of any one of embodiments 58-77, wherein said compound of Formula (II), or salt thereof, is present in a molar percent of about 0.01 to about 5 relative to said composition of Formula (I).

79. The polycrystalline film of any one of embodiments 58-78, wherein said compound of Formula (II), or salt thereof, is present in a molar percent of about 0.01 to about 1.5 relative to said composition of Formula (I).

80. The polycrystalline film of any one of embodiments 58-79, wherein said compound of Formula (II), or salt thereof, is present in a molar percent of about 0.15 to about 0.75 relative to said composition of Formula (I).

81. The polycrystalline film of any one of embodiments 58-80, wherein said compound of Formula (II), or salt thereof, is present in a molar percent of about 0.26 relative to said composition of Formula (I).

82. A semiconductor device comprising:
one or more anode layers;
one or more cathode layers; and
one or more active layers, wherein at least one of said one or more active layers comprises the polycrystalline film of any one of embodiments 58-81.

83. The semiconductor device of embodiment 82, wherein said device is selected from the group consisting of solar cell, light emitting diode, photodiode, photoelectrochemical cell, photoresistor, phototransistor, photomultiplier, photoelectric cell, electrochromic cell, and radiation detector.

84. The semiconductor device of embodiment 83, wherein said solar cell is a single junction solar cell.

85. The semiconductor device of embodiment 83, wherein said solar cell is a tandem solar cell.

86. A solar cell, comprising:
one or more transparent conductive oxide layers;
one or more conductive electrode layers; and
one or more active layers, wherein at least one of said one or more active layers comprises the polycrystalline film of any one of embodiments 58-81.

87. The solar cell of embodiment 86 further comprising:
one or more hole transport layers; and
one or more electron transport layers.

88. The solar cell of embodiment 87, wherein said solar cell comprises:
one transparent conductive oxide layer;
one conductive electrode layer;
one hole transport layer;
one electron transport layer; and
one active layer, wherein said active layer comprises the polycrystalline film.

89. The solar cell of embodiment 88, wherein:
said hole transport layer is disposed on said transparent conductive oxide layer;
said active layer comprising the polycrystalline film is disposed on said hole transport layer;
said electron transport layer is disposed on said active layer; and said conductive electrode layer is disposed on said electron transport layer.

90. The solar cell of embodiment 88, wherein:
said electron transport layer is disposed on said transparent conductive oxide layer;
said active layer comprising the polycrystalline film is disposed on said electron transport layer;
said hole transport layer is disposed on said active layer; and
said conductive electrode layer is disposed on said hole transport layer.

91. The solar cell of any one of embodiments 87-90, wherein said one or more hole transport layers are selected from the group consisting of PTAA, Spiro-OMeTAD, PEDOT:PSS, NiO, MoO₃, V₂O₅, Poly-TPD, EH44, P3HT, and a combination thereof.

92. The solar cell of any one of embodiments 87-90, wherein said one or more electron transport layers are selected from the group consisting of C₆₀, BCP, TiO₂, SnO₂, PCBM, ICBA, ZnO, ZrAcac, LiF, TPBI, PFN, Nb₂O₅, and a combination thereof.

93. The solar cell of any one of embodiments 86-90, wherein said one or more transparent conductive oxide layers are selected from the group consisting of ITO, FTO, ZITO, and AZO.

94. The solar cell of any one of embodiments 86-90, wherein said one or more conductive electrode layers are selected from the group consisting of Al, Au, Cu, Cr, Ni, Zn, Ca, Mg, Ag, Ti, and carbon.

95. The solar cell of embodiment 89, wherein:
said transparent conductive oxide layer is indium tin oxide;
said hole transport layer is PTAA;
said electron transport layer is C₆₀; and
said conductive electrode layer is Cu.

96. The solar cell of embodiment 95, further comprising a buffer layer of BCP disposed between said electron transport layer and said conductive electrode layer.

97. The solar cell of any one of embodiments 86-90, wherein said solar cell exhibits a Power Conversion Efficiency of at least 20%.

98. The solar cell of any one of embodiments 86-90, wherein said solar cell exhibits a Power Conversion Efficiency of at least 23%.

99. A solar module, comprising a plurality of the solar cell of any one of embodiments 86-90.

100. The solar module of embodiment 99, having an aperture area of at least 37 cm².

101. The solar module of embodiment 99, having an aperture area of at least 39 cm².

102. The solar module of embodiment 99, wherein said module exhibits a Power Conversion Efficiency of at least 17%.

103. A kit, comprising
i) a vial containing a perovskite precursor solution comprising a solvent and a composition of Formula (I)

ABI_{3-y}X_{y} (I)
wherein A is a cation selected from the group consisting of methylammonium (MA), tetramethylammonium, formamidinium (FA), cesium (Cs), rubidium (Rb), potassium (K), sodium (Na), butylammonium (BA), phenethylammonium (PEA), phenylammonium (PA), guanidinium (GA), and a combination thereof;
B is a metal cation selected from the group consisting of lead, tin, calcium, cadmium, germanium, zinc, nickel, platinum, palladium, mercury, titanium, silicon, and a combination thereof;
X is selected from the group consisting of Cl⁻, Br⁻, F⁻, SCN⁻, and a combination thereof;
and
   y is between 0 and 3; and
ii) a vial containing a compound of Formula (II):

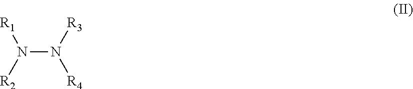

wherein, R₁, R₂, R₃, and R₄ are each independently selected from the group consisting of hydrogen, C₁-C₄₀ alkyl, C₂-C₄₀ alkenyl, C₂-C₄₀ alkynyl, aminoalkyl, C₆-C₁₂ aryl, C₃-C₇ cycloalkyl, 4- to 7-membered heterocyclyl, 5- to 10-membered heteroaryl, C₆-C₁₂ aryl-C₁-C₁₀ alkyl, C₃-C₇ cycloalkyl-C₁-C₁₀ alkyl, 4- to 7-membered heterocyclyl-C₁-C₁₀ alkyl, 5- to 10-membered heteroaryl-C₁-C₁₀ alkyl, and C₁-C₂₀ alkyl-thio-C₁-C₂₀ alkyl, each of which is optionally substituted one or more times with a substituent, each independently selected from the group consisting of halogen, cyano, hydrazino, C₁-C₂₀ alkyl, amino, C₁-C₂₀ alkoxy, C₂-C₂₀ alkenyl, C₂-C₂₀ alkynyl, C₆-C₁₂ aryl, C₃-C₇ cycloalkyl, 4- to 7-membered heterocyclyl, and 5- to 10-membered heteroaryl;
   wherein one or more carbon atoms in said “alkyl” of C₁-C₄₀ alkyl, aminoalkyl, C₆-C₁₂ aryl-C₁-C₁₀ alkyl, C₃-C₇ cycloalkyl-C₁-C₁₀ alkyl, 4- to 7-membered heterocyclyl-C₁-C₁₀ alkyl, 5- to 10-membered heteroaryl-C₁-C₁₀ alkyl, or C₁-C₂₀ alkyl-thio-C₁-C₂₀ alkyl are optionally:
   i. replaced with O or S; and/or
   ii. substituted with (═O);
or, a salt thereof.

104. The oxidative-resistant ink solution of any one of embodiments 1-26, wherein said ink solution further comprises a second compound of Formula (II), or salt thereof.

105. The method of any one of embodiments 27 or 29-53, further comprising contacting said oxidative-resistant ink solution with a second compound of Formula (II), or salt thereof.

106. The polycrystalline film of any one of embodiments 58-81, further comprising a second compound of Formula (II), or salt thereof.

107. The oxidative-resistant ink solution of embodiment 104, method of embodiment 105, or polycrystalline film of embodiment 106, wherein said second compound of Formula (II) is

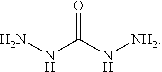

108. A method of preparing a perovskite film having reduced interfacial voids, comprising contacting a precursor solution comprising one or more non-coordinating solvents and a composition of Formula (I)

ABI_{3-y}X_{y} (I)
wherein,
A is a cation selected from the group consisting of methylammonium (MA), tetramethylammonium, formamidinium (FA), cesium (Cs), rubidium (Rb), potassium (K), sodium (Na), butylammonium (BA), phenethylammonium (PEA), phenylammonium (PA), guanidinium (GA), and a combination thereof;
B is a metal cation selected from the group consisting of lead, tin, calcium, cadmium, germanium, zinc, nickel, platinum, palladium, mercury, titanium, silicon, and a combination thereof;
X is selected from the group consisting of Cl⁻, Br⁻, F⁻, SCN⁻, and a combination thereof;
y is between 0 and 3;
   with:
(i) a compound of Formula (II), or a salt thereof,

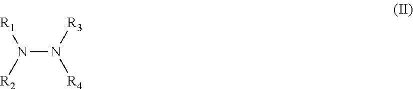

wherein,
R₁, R₂, R₃, and R₄ are each independently selected from the group consisting of hydrogen, C₁-C₄₀ alkyl, C₂-C₄₀ alkenyl, C₂-C₄₀ alkynyl, aminoalkyl, C₆-C₁₂ aryl, C₃-C₇ cycloalkyl, 4- to 7-membered heterocyclyl, 5- to 10-membered heteroaryl, C₆-C₁₂ aryl-C₁-C₁₀ alkyl, C₃-C₇ cycloalkyl-C₁-C₁₀ alkyl, 4- to 7-membered heterocyclyl-C₁-C₁₀ alkyl, 5- to 10-membered heteroaryl-C₁-C₁₀ alkyl, and C₁-C₂₀ alkyl-thio-C₁-C₂₀ alkyl, each of which is optionally substituted one or more times with a substituent, each independently selected from the group consisting of halogen, cyano, hydrazino, C₁-C₂₀ alkyl, amino, C₁-C₂₀ alkoxy, C₂-C₂₀ alkenyl, C₂-C₂₀ alkynyl, C₆-C₁₂ aryl, C₃-C₇ cycloalkyl, 4- to 7-membered heterocyclyl, and 5- to 10-membered heteroaryl;
wherein one or more carbon atoms in said “alkyl” of C₁-C₄₀ alkyl, aminoalkyl, C₆-C₁₂ aryl-C₁-C₁₀ alkyl, C₃-C₇ cycloalkyl-C₁-C₁₀ alkyl, 4- to 7-membered heterocyclyl-C₁-C₁₀ alkyl, 5- to 10-membered heteroaryl-C₁-C₁₀ alkyl, or C₁-C₂₀ alkyl-thio-C₁-C₂₀ alkyl are optionally:
i. replaced with O or S; and/or
ii. substituted with (═O);
   and
(ii) a coordinating solvent, to prepare a modified precursor solution; and contacting said modified precursor solution onto a substrate to prepare a perovskite film, wherein said perovskite film prepared has reduced interfacial voids.

109. The method of embodiment 108, wherein said coordinating solvent is dimethyl sulfoxide.

110. The method of embodiment 108, wherein in said compound or salt of Formula (II), R₃ and R₄ are each hydrogen, R₁ is hydrogen, and R₂ is selected from the group consisting of C₁-C₄₀ alkyl, C₂-C₄₀ alkenyl, C₂-C₄₀ alkynyl, aminoalkyl, C₆-C₁₂ aryl, C₃-C₇ cycloalkyl, 4- to 7-membered heterocyclyl, 5- to 7-membered heteroaryl, C₆-C₁₂ aryl-C₁-C₁₀ alkyl, C₃-C₇ cycloalkyl-C₁-C₁₀ alkyl, 4- to 7-membered heterocyclyl-C₁-C₁₀ alkyl, 5- to 10-membered heteroaryl-C₁-C₁₀ alkyl, and C₁-C₂₀ alkyl-thio-C₁-C₂₀ alkyl, each of which is optionally substituted one or more times with a substituent, each independently selected from the group consisting of halogen, cyano, hydrazino, C₁-C₂₀ alkyl, amino, C₁-C₂₀ alkoxy, C₂-C₂₀ alkenyl, C₂-C₂₀ alkynyl, C₆-C₁₂ aryl, C₃-C₇ cycloalkyl, 4- to 7-membered heterocyclyl, and 5- to 10-membered heteroaryl;
wherein one or more carbon atoms in said “alkyl” of C₁-C₄₀ alkyl, aminoalkyl, C₆-C₁₂ aryl-C₁-C₁₀ alkyl, C₃-C₇ cycloalkyl-C₁-C₁₀ alkyl, 4- to 7-membered heterocyclyl-C₁-C₁₀ alkyl, 5- to 10-membered heteroaryl-C₁-C₁₀ alkyl, C₁-C₂₀ alkyl-thio-C₁-C₂₀ alkyl are optionally:
i. replaced with O or S; and/or
ii. substituted with (═O).

111. The method of embodiment 110, wherein R₂ is C₁-C₁₀ alkyl, optionally substituted with hydrazino, and wherein one or more atoms in said alkyl are substituted with (═O).

112. The method of embodiment 111, wherein R₂ is

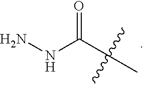 [SMILES: *C(=O)NN]

113. The method of embodiment 108, wherein said compound of Formula II is

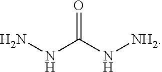

114. The method of embodiment 108, wherein said composition of Formula (I) is APbI₃, wherein A is a cation selected from the group consisting of methylammonium (MA), formamidinium (FA), cesium (Cs), and a combination thereof.

115. The method of embodiment 114, wherein said composition of Formula (I) is MA₁₋ₓFA_{X}PbI₃, wherein x is between 0 and 0.6.

116. The method of embodiment 115, wherein said composition of Formula (I) is MA_{0.6}FA_{0.4}PbI₃.

117. The method of embodiment 108, further comprising annealing said perovskite film, wherein the presence of said compound of Formula (II), or salt thereof, reduces time required for annealing.

118. The method of embodiment 108, wherein said compound or salt of Formula II is present in said modified precursor solution at about 0.25 to 5 mol % relative to said composition of Formula I; and wherein said coordinating solvent is present in said modified precursor solution at about 5 to 40 mol % relative to said composition of Formula I.

119. The method of embodiment 118, wherein said compound or salt of Formula II is present in said modified precursor solution at about 1.5 mol % relative to said composition of Formula I; and wherein said coordinating solvent is present in said modified precursor solution at about 25 mol % relative to said composition of Formula I.

120. The method of embodiment 108, wherein said one or more non-coordinating solvents are 2-methoxyethanol.

121. The method of embodiment 108, wherein:
said composition of Formula (I) is APbI₃, wherein A is a cation selected from the group consisting of methylammonium (MA), formamidinium (FA), cesium (Cs), and a combination thereof;
said compound of Formula II, or salt thereof, is

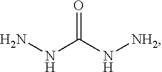

wherein said compound of Formula II is present in said modified precursor solution at about 1.5 mol % relative to said composition of Formula I; and
said coordinating solvent is dimethyl sulfoxide, wherein said coordinating solvent is present in said modified precursor solution at about 25 mol % relative to said composition of Formula I.

122. The method of embodiment 108, wherein said contacting said modified precursor solution onto a substrate to prepare a perovskite film comprises blade-coating said modified precursor solution onto said substrate.

### EXAMPLES

### Methods

Materials. BHC, PHC, THC, poly(bis(4-phenyl)(2,4,6-trimethylphenyl)amine) (PTAA, average Mₙ 7,000-10,000), bathocuproine (BCP), lead iodide (PbI₂, 99.999% trace metals), dimethyl sulfoxide (DMSO), L-α-phosphatidylcholine (LP), 2-methoxyethanol (2-ME), and toluene were purchased from Sigma-Aldrich and used without further purification. C₆₀ was purchased from Nano-C Inc. Methylammonium iodide (MAI), formamidinium iodide (FAI), 4-fluoro-phenylammonium iodide (p-F-PEAI), and n-dodecylammonium iodide were purchased from GreatCell Solar.

Device fabrication. Patterned ITO glass substrates (1.5 cm×1.5 cm for solar cells, and 13.0 cm×8.5 cm for solar modules) were first cleaned by ultrasonication with soap, DI water and IPA, and then UV-ozone treated for 15 min before use. All perovskite solar devices were prepared by blade-coating at room temperature inside a fume hood with a relative humidity of 45±5%. The hole-transporting PTAA layer with a concentration of 3.3 mg mL⁻¹ dissolved in toluene was blade-coated onto ITO glass substrates at a speed of 20 mm s⁻¹. The gap between the blade-coater and ITO substrates was 150 μm. The perovskite precursor solutions (2.5 M MAPbI₃ and 1.67 M FAPbI₃) were prepared separately by dissolving corresponding precursor materials into 2-ME and stored in a N₂-filled glovebox with an O₂ level ˜20 ppm. Before blade-coating, the MAPbI₃ and FAPbI₃ precursor solutions were mixed and diluted to a 1.37 M MA_{0.7}FA_{0.3}PbI₃ solution, and different amounts of BHC, 0.83 mg mL⁻¹ n-dodecylammonium iodide, 0.27 mg mL⁻¹ LP, 0.14% v/v MAH₂PO₂, 1.40 mg mL⁻¹ p-F-PEAI, 2.8% v/v DMSO were added into the precursor solution as additives before blade-coating. Subsequently, the precursor solution was blade-coated onto the PTAA-covered ITO glass substrates with a gap of 240 to 260 m at a movement speed of 20 mm s⁻¹. The N₂ knife worked at 20 psi during blade-coating. After that, the perovskite films were annealed at 120° C. for 3 min in air. The solar cells were completed by thermally evaporating C₆₀ (30 nm, 0.2 Å s⁻¹), BCP (6 nm, 0.1 Å s⁻¹), and 100 nm copper (1 Å s⁻¹). The devices for stability tests were coated with an octylammonium sulfate solution (annealed at 100° C. for 10 min) before evaporating electron-transporting layers and metal electrodes. For the mini-modules, laser scribing was performed twice before and after electrode deposition to complete the module fabrication. The fabricated modules had 9-14 subcells, and each subcell had a width of 6.5 mm. The total scribing line width was 0.4-0.8 mm, giving a geometry filling factor of 90-94%. A 0.5 mm-thick polydimethylsiloxane (PDMS) layer was applied to the surface of the glass substrate as an antireflection coating. The active area of the solar cells and modules was 8 mm² (4 mm×2 mm determined by a metal shadow mask) and 35.8 cm² (5.5 cm×0.65 cm×10 sub-cells), respectively.

Device characterization. The J-V characteristics of the solar cells were obtained using a Xenon-lamp-based solar simulator (Oriel Sol3A, Class AAA Solar Simulator) and the power of the simulated light was calibrated to 100 mW cm⁻² by a silicon reference cell (Newport 91150V-KG5). All devices were measured using a Keithley 2400 source meter with a backward scan rate of 0.1 V si in air at room temperature, and the delay time was 10 ms. There was no preconditioning before measurement. A metal mask with an aperture (7.3 mm²) aligned with the device area was used for measurements. Scanning electron micrograph (SEM) images were taken on a FEI Helios 600 Nanolab Dual Beam System operating at 5 kV. The XRD patterns were obtained with a Rigaku sixth generation MiniFlex X-ray diffractometer. UV-Vis absorption spectra were obtained with a Thermo Scientific Evolution 201 Spectrophotometer. Because the reaction product (Benzenemethanediazonium) between BHC and I₂ exhibited absorption between 300 and 400 nm under acidic conditions, a small amount of methylamine solution (40% wt in water) was added into the solution to obviate the interference before measuring its UV-Vis absorption spectra. The PL mapping was conducted on a PicoQuant MT100 FLIM System at room temperature with an excitation wavelength of 640 nm. The PL intensity was recorded by a hybrid PMT detector. The tDOS of solar cells were derived from the frequency-dependent capacitance (C-f) and voltage-dependent capacitance (C-V), which were obtained from the thermal admittance spectroscopy measurement performed by an LCR meter (Agilent E4980A).

Device encapsulation and stability tests. A thin layer of CYTOP was blade-coated onto the back of the PSCs for operational stability tests. After being dried at 60° C. in air for 10 min, the PSCs were then encapsulated by cover glass sealed by epoxy encapsulant on the back. A plasma lamp with a light intensity equivalent to AM 1.5G without any ultraviolet filter worked as a solar simulator in air (relative humidity ˜60±10%). The temperature of the solar cells was measured to be ˜65° C. due to the heating effects of the solar simulator. The solar cells were connected to an EnliteTech LS-6100 MPP tracker that automatically tracked the MPPs after each J-V sweeping so that the solar cells always worked at MPP conditions during the stability tests.

### Example 1: Investigation of Oxidation of I⁻ to I₂ in Precursor Solutions

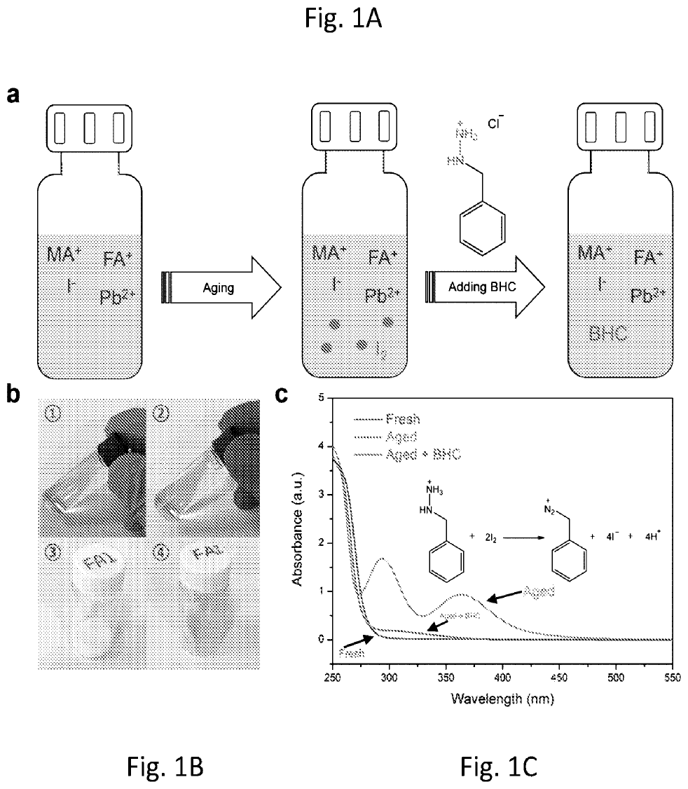

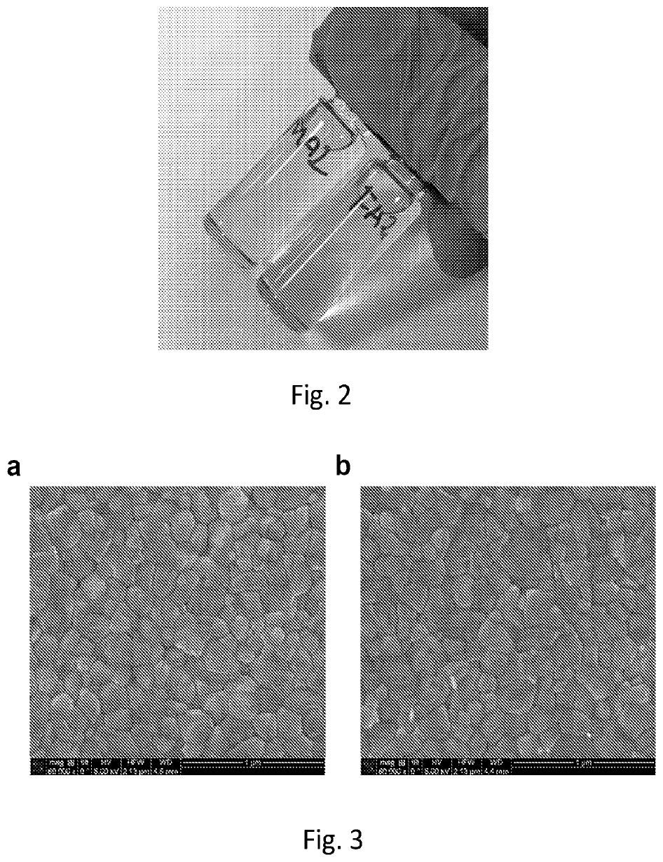

To examine the oxidation of I⁻ to I₂ during the aging of the precursor solutions, a 1.37 M MAI:FAI (molar ratio of 7:3) mixed 2-methoxyethanol (2-ME) solution was prepared, which had the same ratio and concentration of MAI and FAI as that of the perovskite precursor solution (1.37 M MA_{0.7}FA_{0.3}PbI₃ in 2-ME) for device fabrication. Lead iodide (PbI₂) was excluded in this study, because the absorption spectrum of PbI₂ overlaps with that of I₂ in these solutions. After being aged in air for two days, the color of the solution turned light yellow (FIG. 1b) and an absorption peak at 365 nm emerged in the absorption spectrum of the solution (FIG. 1c). This absorption peak could be ascribed to I₂ (Zhang, W. et al. Nat. Commun. 6, 10030, (2015)). Individual FAI or MAI solution was also found to decompose to I₂, and FAI exhibited a faster decomposition, as shown by the photos of the solutions (FIG. 2). It was also discovered that the white solid FAI powder turned yellow, an indication of its oxidization to I₂, after it was stored in the dark in air for five months (FIG. 1b). This degradation was much faster than the previously observed reaction of FA⁺ with oxygen under illumination¹¹. When 3.5 mM BHC was added to the aged MAI:FAI solution, the color of the solution immediately became transparent, and the absorption peak of I₂ completely disappeared, demonstrating the effectiveness of BHC in reducing I₂.

### Example 2: Device Performance

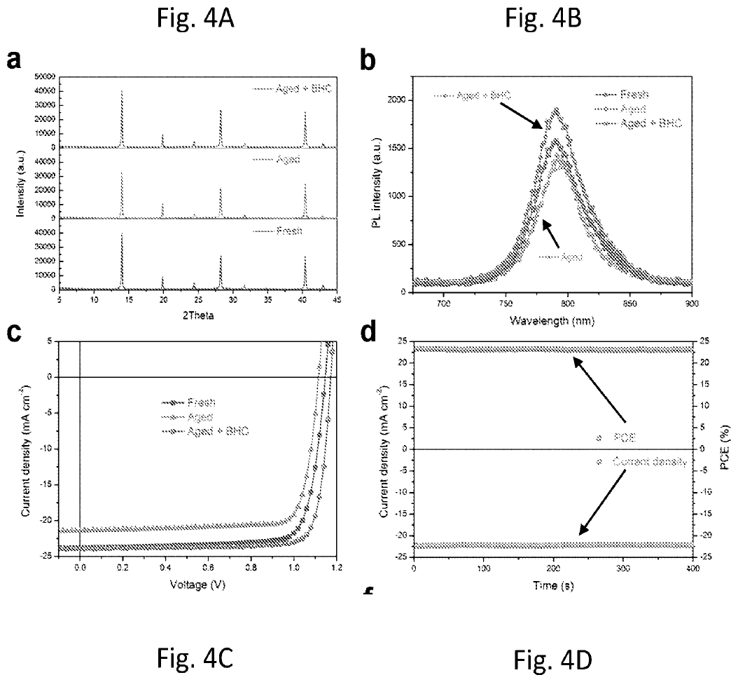

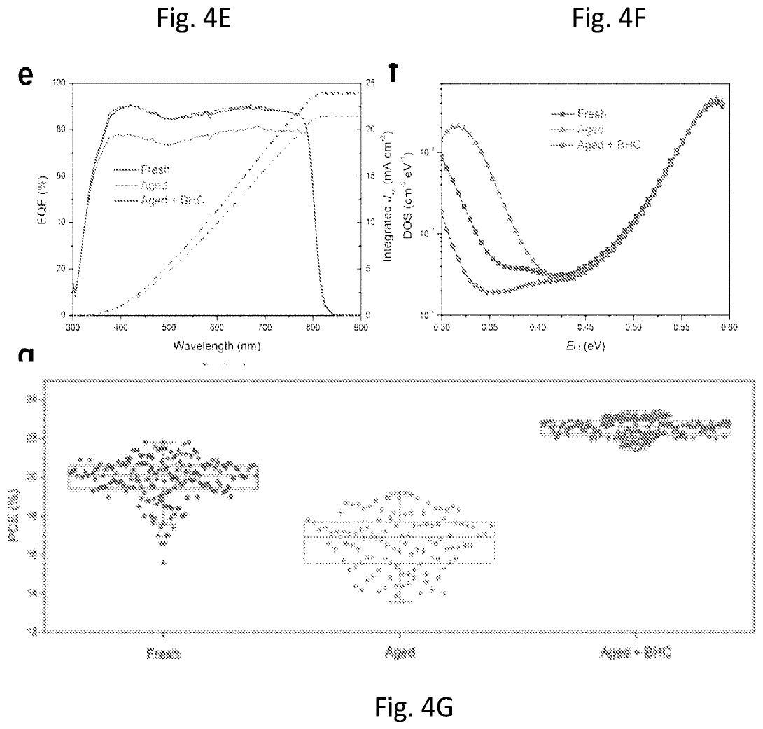

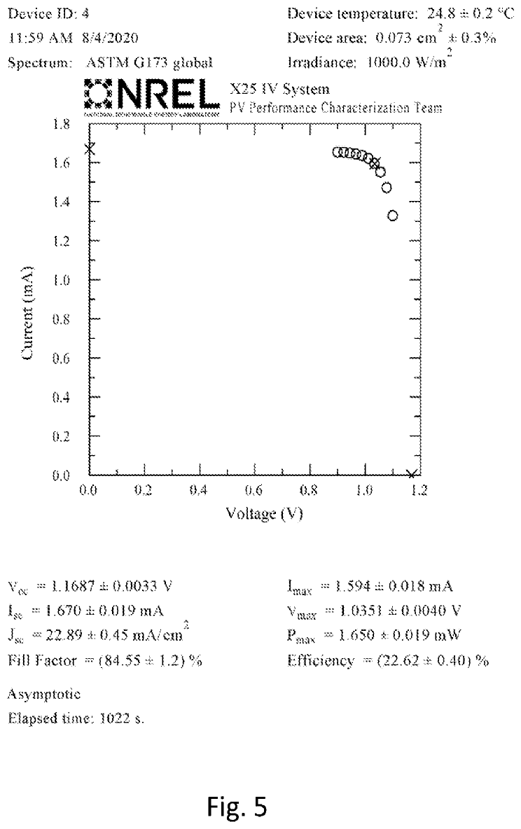

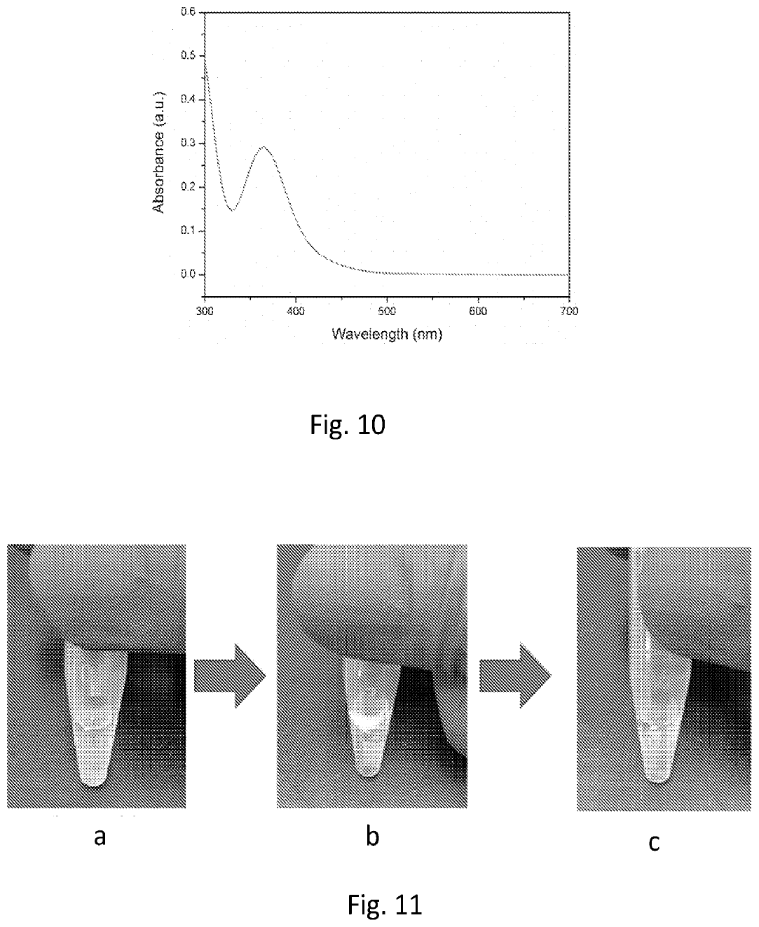

The effects of precursor solution aging and the addition of BHC on the performance of perovskite films/devices were then investigated. Perovskite films and devices were fabricated from three types of MA_{0.7}FA_{0.3}PbI₃ precursor solutions: a freshly prepared perovskite precursor solution, the precursor solution that had been aged for 2 months in an N₂-filled glovebox (O₂ level<20 ppm), and the identical aged solution with the addition of 0.26% BHC (molar ratio with respect to lead) before coating. It should be noted that the amount of I₂ in the aged precursor solution was between 10⁻⁵ M to 10⁻⁴ M, as estimated from its absorbance (FIG. 10) and absorption coefficient, which is much lower than that of the BHC (3.6×10⁻³ M) added to the precursor solution (Zhang, W. et al. Nat. Commun. 6, 10030, (2015)). These three solutions are denoted as fresh, aged, and aged+BHC hereinafter, respectively. The perovskite films were deposited onto glass substrates with a room-temperature blade-coating process as reported previously (Deng, Y. et al. Sci. Adv. 5, eaax7537, (2019)). The addition of BHC was not observed to significantly impact the film morphology (FIG. 3). The X-ray diffraction (XRD) patterns (FIG. 4a) show the decreased crystallinity of the resultant perovskite film from the aged solution, which was then restored after the addition of BHC. A similar trend was also observed in the steady state photoluminescence (PL) measurements on the films, which shows the PL intensity decreased after aging the precursor solution (FIG. 4b). The XRD results show that the addition of BHC further enhanced the PL intensity compared to that processed from the fresh precursor solution. This suggests that the residual BHC also exhibited passivation effects on the perovskite films and thus suppressed the non-radiative recombination. PSCs were then fabricated with a p-i-n planar heterojunction configuration of indium tin oxide (ITO)/poly[bis(4-phenyl)(2,4,6-trimethylphenyl)amine](PTAA)/perovskites/C₆₀/bathocuproine (BCP)/copper (Cu). As shown in FIG. 4c, the device processed from the fresh precursor solution delivered a PCE of 21.8%, along with an open-circuit voltage (V_{oc}) of 1.14 V, a short-circuit current density (J_{sc}) of 23.8 mA cm⁻² and a fill factor of 0.805. After the precursor solution was aged for two months, it was discovered that the PCE of the resulting devices was significantly reduced to 19.2%, with a deteriorated s from 23.8 to 21.4 mA cm⁻². After the addition of BHC into the aged precursor solution, however, a PCE of 23.4% was realized with a restored J_{sc} and a high V_{oc} of 1.17 V. The champion solar cell was further held at a fixed voltage of 1.04 V, and the stabilized power output for over 400 s was recorded as depicted in FIG. 4d. The current density was stabilized at 22.3 mA cm⁻², corresponding to a stabilized PCE of 23.2%. The champion devices were then shipped to National Renewable Energy Laboratory (NREL) for certification, and a stabilized PCE of (22.62±0.40) % was obtained (FIG. 5). The voltage deficit in this case was minimized to 0.33 V, calculated from the external quantum efficiency (EQE) spectrum onset of 825 nm (FIG. 4e). Table 1 summarizes the photovoltaic parameters of the PSCs processed from different precursor solutions. A reduced trap density in the “aged+BHC” device was also discovered by thermal admittance spectroscopy as shown in FIG. 4f (Shao, Y., et al. Nat. Commun. 5, 5784-5790, (2014)). The “aged+BHC” device exhibited a much lower trap density of states (tDOS) in the shallow trap depth region (0.30 to 0.40 eV). This trap peak with depth from 0.20 to 0.35 eV was confirmed by another study to be evidence of the formation of I₃⁻, which forms by the combination of I₂ and I⁻ ions. The reduced trap density is evidence for the reduction of the detrimental I₂ in the aged precursor solution. Of note, the “aged+BHC” device showed even less I₂ than the devices made from the fresh solution. This indicates that even the fresh solution had already partially degraded, which further emphasizes the importance of reducing I₂ in perovskite precursor solutions.

TABLE 1
Photovoltaic parameters of the PSCs processed
from different precursor solutions.

| | V_{OC} | J_{SC} | | PCE |
|---|---|---|---|---|
| Precursor solutions | [V] | [mA cm⁻²] | FF | [%] |
| Fresh | 1.14 | 23.8 | 0.805 | 21.8 |
| Aged for 2 months | 1.12 | 21.4 | 0.800 | 19.2 |
| Fresh + BHC | 1.17 | 24.0 | 0.829 | 23.3 |
| Aged for 2 months + BHC | 1.17 | 23.9 | 0.836 | 23.4 |

### Example 3: PHC and THC as Reducing Agents

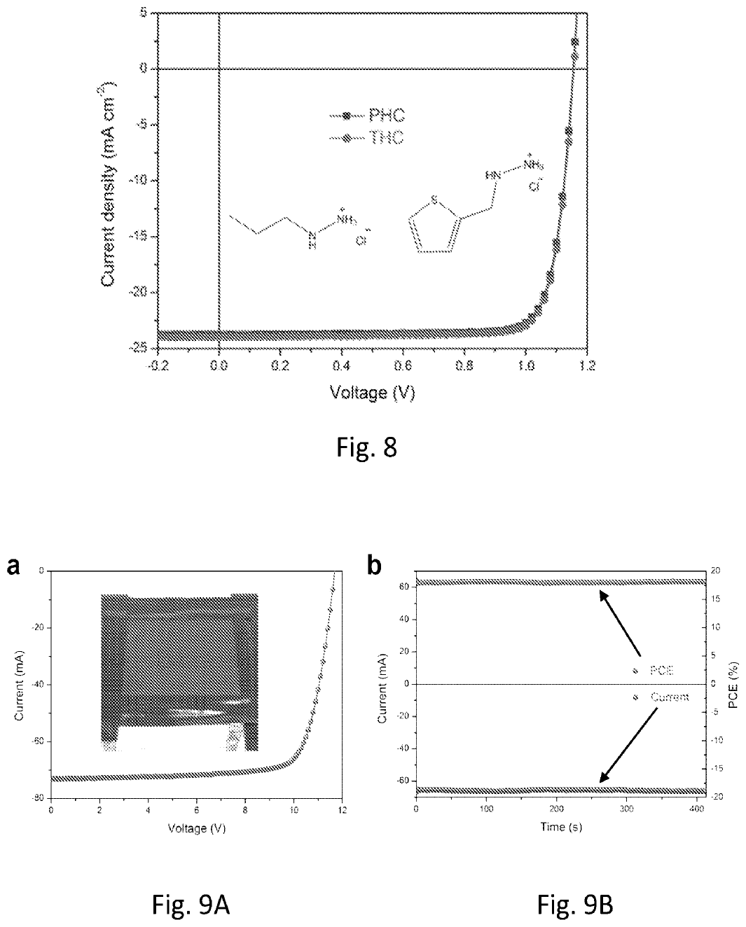

Additional reducing agents were investigated, including propylhydrazine hydrochloride (PHC) and (2-thienylmethyl)hydrazine hydrochloride (THC) having similar molecular structures. The addition of PHC and THC restored the aged precursor solutions and improved the device efficiencies to 22.6% and 23.0% (FIG. 8 and Table 2), respectively, demonstrating the universality of organic hydrazine halides in reducing I₂ in perovskite precursor solutions.

TABLE 2
Photovoltaic parameters of the PSCs fabricated from the aged precursor
solutions with the addition of PHC and THC, respectively.

| | V_{oc} | J_{sc} | | PCE |
|---|---|---|---|---|
| Reducing agents | [V] | [mA cm⁻²] | FF | [%] |
| PHC | 1.15 | 23.8 | 0.827 | 22.6 |
| THC | 1.16 | 23.9 | 0.830 | 23.0 |

### Example 4: Passivation Effects of BHC

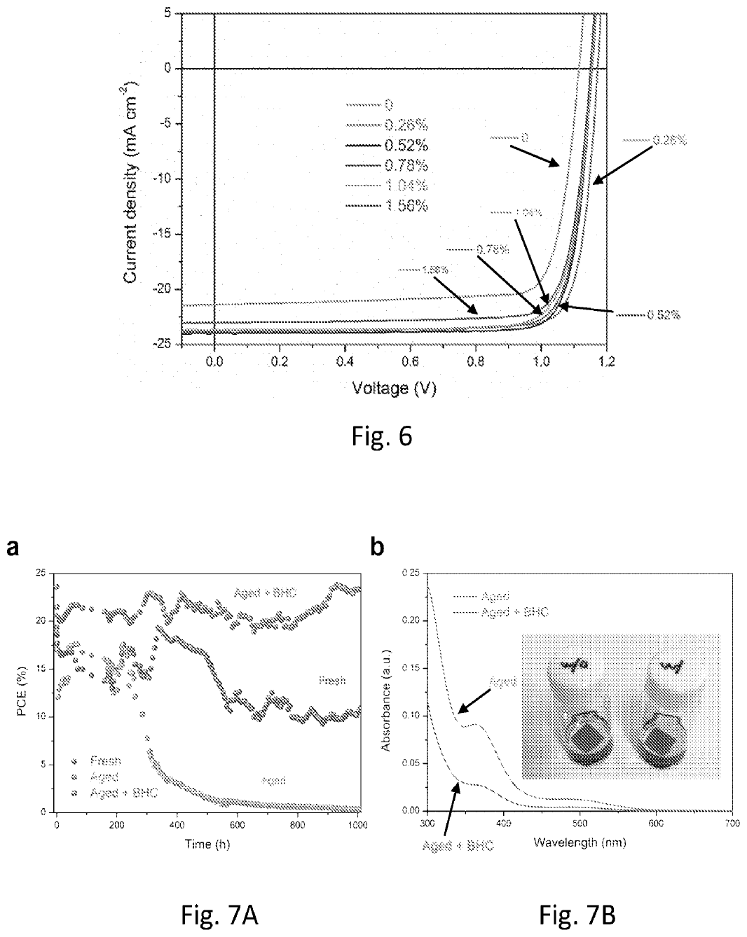

The reproducibility of the devices was investigated by fabricating “aged+BHC” devices, and the PCEs from batches of PSCs (244 devices in total) were statistically analyzed in FIG. 4g. Most devices (>80%) were able to deliver PCEs over 22%, and over half of them achieved PCEs over 22.5%, which is indicative of the good reproducibility of the PSCs generated from the BHC-added aged precursor solution. The fresh solution with the addition of BHC was further used to blade coat PSCs, which showed that the resulting devices were able to realize a PCE of 23.3% with a V_{OC} of 1.17 V, a J_{SC} of 24.0 mA cm⁻² and a FF of 0.829. This performance is almost identical to that observed for the “aged+BHC” solution, indicating that the “fresh” solution had experienced some degree of degradation already, despite the great deal of care taken to protect it. All these results demonstrate the effectiveness of BHC in restoring precursor solutions and reducing film defects, accounting for the suppressed charge recombination and thus enhanced device efficiency. It was also discovered that the blade-coated PSCs were able to tolerate a higher amount of BHC up to 1.56% (molar ratio with respect to Pb), at which the PSCs could still deliver a PCE of 21.8% (FIG. 6 and Table 3). Such a wide processing window of BHC addition is highly desirable for the large-scale fabrication of efficient and reproducible perovskite solar devices. Overall, the excellent photovoltaic performance and good reproducibility of the “aged+BHC” devices demonstrates the effectiveness of BHC in restoring precursor solutions and passivating film defects, accounting for the suppressed charge recombination and thus enhanced device efficiency.

TABLE 3
Photovoltaic parameters of PSCs based on aged precursor
solutions with different amounts of BHC.

| Molar ratio of BHC | | | | |
|---|---|---|---|---|
| with respect to Pb | V_{oc} | J_{sc} | | PCE |
| [%] | [V] | [mA cm⁻²] | FF | [%] |
| 0 | 1.12 | 21.4 | 0.800 | 19.2 |
| 0.26 | 1.17 | 23.9 | 0.836 | 23.4 |
| 0.52 | 1.16 | 23.9 | 0.835 | 23.2 |
| 0.78 | 1.16 | 23.6 | 0.828 | 22.7 |
| 1.04 | 1.15 | 23.7 | 0.816 | 22.3 |
| 1.56 | 1.15 | 23.1 | 0.822 | 21.8 |

### Example 5: Long-Term Stability Tests of PSCs

Long-term stability tests of the encapsulated perovskite devices were performed under a plasma lamp with a light intensity equivalent to AM 1.5G in air (relative humidity ˜60±10%). No UV filters were used during the tests. All devices were connected to an MPP tracker that enabled the devices to keep working under MPP conditions during light soaking. The operational stability of the PSCs prepared from different precursor solution was compared in FIG. 7A. Both devices prepared from fresh and aged precursor solutions exhibited poor operational stability, especially the device based on the aged precursor solution that lost most of its initial efficiency after 400-hours of light soaking. In contrast, the PSC fabricated from the BHC-added aged precursor solution showed excellent operational stability with almost no degradation after 1000-hours of MPP tracking. The significantly enhanced device stability could be attributed to the reduction of I₂ in the precursor solutions and decreased trap density (Dunfield, S. P. et al. Adv. Energy Mater. 10, 1904054, (2020); and Wang, F., et al., npj Flexible Electronics 2, 22, (2018)). Also, since the amount of BHC added to the precursor solution was greater than the amount of I₂, the residual BHC could potentially work as a sacrificing agent and further reduce the I₂ generated inside the perovskite films during light soaking. Formation of I₂ for iodide perovskites under illumination was observed previously, which was also shown to accelerate the degradation of PSCs (Kim, G. Y. et al., Nat. Mater. 17, 445-449, (2018); and Wang, S., et al., Nat. Energy 2, 16195, (2016)). To test the functionality of BHC, two perovskite films with and without BHC were immersed in toluene and the I₂ generated in the films was extracted during light soaking. After continuous light-soaking for 8 hours at one sun light intensity, the absorption spectra (FIG. 7b) of two toluene solutions shows that the amount of I₂ generated from the films was greatly reduced with the addition of BHC. These results indicate how residual BHC can reduce I₂ and thus stabilize perovskite films under illumination.

### Example 6: Module Fabrication and Testing

The BHC-incorporated solution was evaluated for module fabrication and performance. Accordingly, large-area perovskite solar modules were fabricated using the procedures referenced above for the PSCs. As shown in FIG. 9A, the perovskite mini-modules delivered a PCE of 18.5% from J-V scanning (aperture area of 35.8 cm²), with a V_{OC} of 11.7 V (10 sub-cells, therefore each sub-cell gave a V_{OC} of 1.17 V), a short circuit current I_{SC} of 73.20 mA, and a FF of 0.773. The champion mini-module was then held at a bias of 9.8 V for >400 s, and the current was stabilized at 66.2 mA, corresponding to a stabilized PCE of 18.2% (FIG. 9B).

### Example 7: Carbohydrazide Experiments

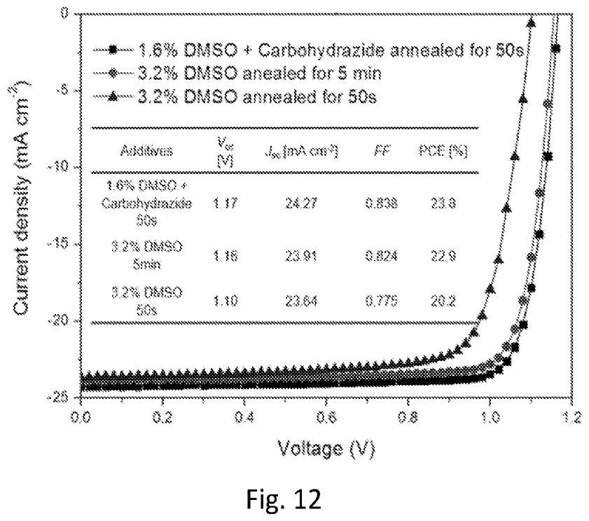

Carbohydrazide was analyzed as an additive in perovskite precursor solutions. Without wishing to be bound by theory, it is understood that carbohydrazide can coordinate with PbI₂ and MAI in the precursor solution. The presence of carbohydrazide can also reduce the amount of DMSO solvent in the precursor solution and shorten the annealing duration from 5 minutes to 50 seconds (FIG. 12). The carbohydrazide can also tune the crystallization of the perovskite grains. The experimental details for an exemplary solar cell that was generated from a perovskite solution featuring carbohydrazide as an additive are provided below.
HTL: PTAA 3.3 mg/mL in toluene, bladed coated onto ITO glass substrate at a gap of 150 m and a speed of 20 mm/s
Perovskite: 1.37 M MA_{0.6}FA_{0.4}PbI₃ in 2-ME, 0.83 mg mL⁻¹ n-dodecylammonium iodide, 0.27 mg mL⁻¹ LP, 0.14% v/v MAH₂PO₂, 1.40 mg mL⁻¹ p-F-PEAI, 3.2% v/v DMSO or (1.6% % v/v DMSO+1 mg/mL carbohydrazide in 2-ME) and 0.26% BHC as additives.

The precursor solution was swiped linearly to the gap (250 μm) between blade-coater and substrate, and blade-coated at a rate of 20 mm/s and quenched by a N₂ knife. Thermal annealing at 120° C. for 50 s or 5 min. Humidity: 35%

Solar cells: evaporate C₆₀ (30 nm)/BCP (6 nm)/Cu (100 nm).

Without wishing to be bound by theory, it is understood that the carbohydrazide is trapped at the perovskite/hole transport layer interface, which can stabilize the perovskite and suppress the formation of I₂.

### Example 8: Additional Carbohydrazide Experiments

PSCs were fabricated with a p-i-n structure of glass/indium tin oxide (ITO)/poly[bis(4-phenyl)(2,4,6-trimethylphenyl)amine (PTAA)/perovskite/fullerene (C₆₀)/bathocuproine (BCP)/copper (Cu). Both the PTAA hole-transporting layer (HTL) and perovskite films were prepared using a reported room-temperature blade-coating method^{13a}. A mixed solvent composed of volatile and nonvolatile solvents, such as volatile 2-methoxyethanol (2-ME) mixed with nonvolatile DMSO, has been adopted to coat large-area perovskite films (D.-K. Lee, et al., ACS Energy Lett. 4, 2393-2401 (2019); J. Li et al., Adv. Energy Mater. 11, 2003460 (2021); and K. H. Hendriks et al., J. Mater. Chem. A 5, 2346-2354 (2017)). During blade-coating of the perovskite films, the majority-fraction, 2-ME, quickly evaporates to leave the “wet” films under N₂ blowing at room temperature. The small fraction of the non-volatile DMSO retards the crystallization to yield large grains, as well as intimate contact with bottom substrates.

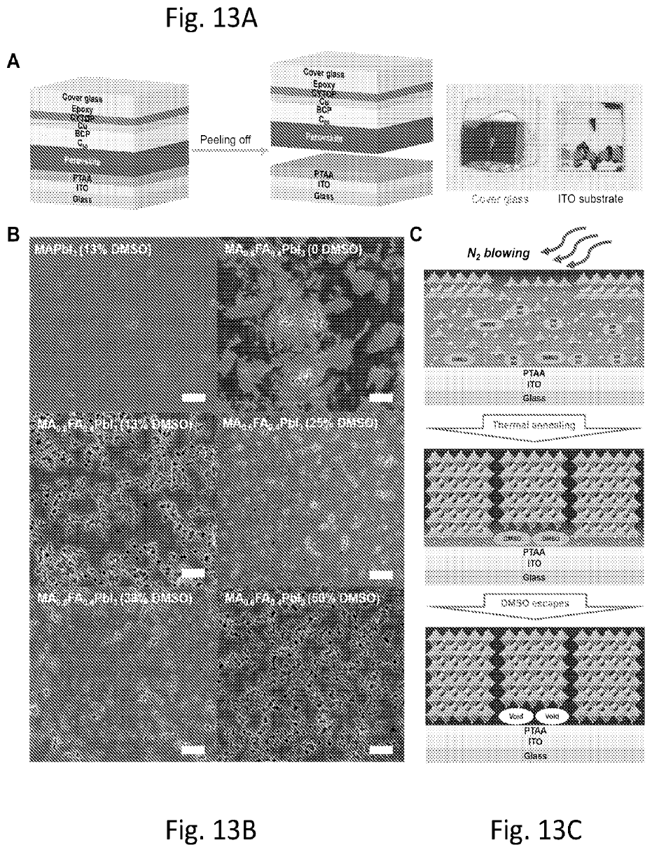

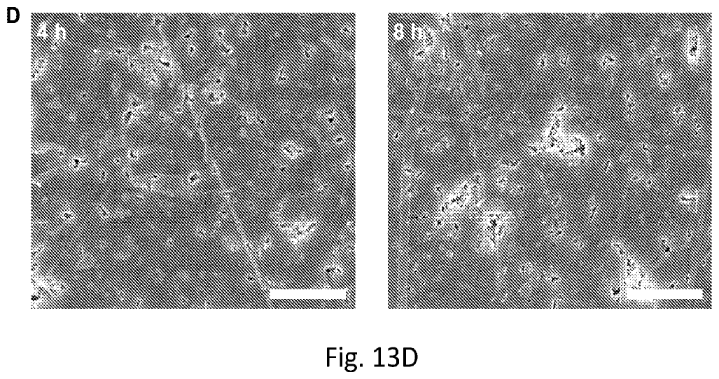

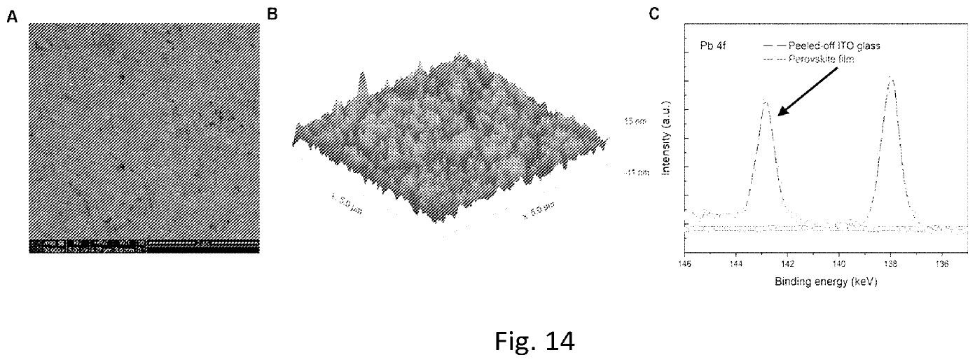

In previous studies of blade-coating efficient MAPbI₃ (MA: methylammonium) mini-modules, the addition of 13% DMSO (molar ratio to Pb) generated the formation of a crystalline intermediate phase with MAI and lead iodide (PbI₂), which then crystallized downward and converted into perovskite during thermal annealing (Y. Deng et al., Sci. Adv. 5, eaax7537 (2019); and S. Chen et al., Sci. Adv. 7, eabb2412 (2021)). A dense and mirror-like MAPbI₃ film was obtained and appeared visually to have intimate contact with the substrate. The morphology of the MAPbI₃-substrate interface was investigated by first peeling off the blade-coated MAPbI₃ films from the ITO glass substrates coated with an epoxy encapsulant (FIG. 13A). After exposing the perovskite bottom surfaces next to the PTAA HTL layer, voids were discovered in the perovskite surface with sizes of tens to hundreds of nanometers by SEM (FIG. 13B). Theses voids were not caused by the breakdown of perovskite grains during the peeling-off process. If this was so, residual particles would have been left on the ITO substrates, and none were seen in SEM, AFM, or X-ray photoelectron spectroscopy (XPS) characterization on the corresponding ITO substrates after peeling-off (FIG. 14).

In addition to MAPbI₃, other compositions, such as MAI-FAI (FAI: formamidinium iodide) mixed perovskites, exhibited similar amounts or even more voids at the perovskite-substrate interfaces. Replacing MAI partially or completely with FAI has been used to enhance material stability and broaden the absorption spectrum (S.-H. Turren-Cruz, et al., Science 362, 449-453 (2018); and Y. Deng, et al., Adv. Energy Mater. 6, 1600372 (2016)). MA_{0.6}FA_{0.4}PbI₃ was used as an exemplary perovskite composition, which remained in the black phase at room temperature. To blade-coat high-quality FAI-containing perovskite films, the percentage of DMSO had to be much higher than that for MAPbI₃. It proved much harder to form the FAI-PbI₂-DMSO intermediate phase using the same solvent system, and more DMSO had to be added to retard its crystallization. Previous reports found that pure FAPbI₃ films spun from DMSO-containing precursor solutions had no notable FAI-containing intermediate phase (M. Kim et al., Joule 3, 2179-2192 (2019)).

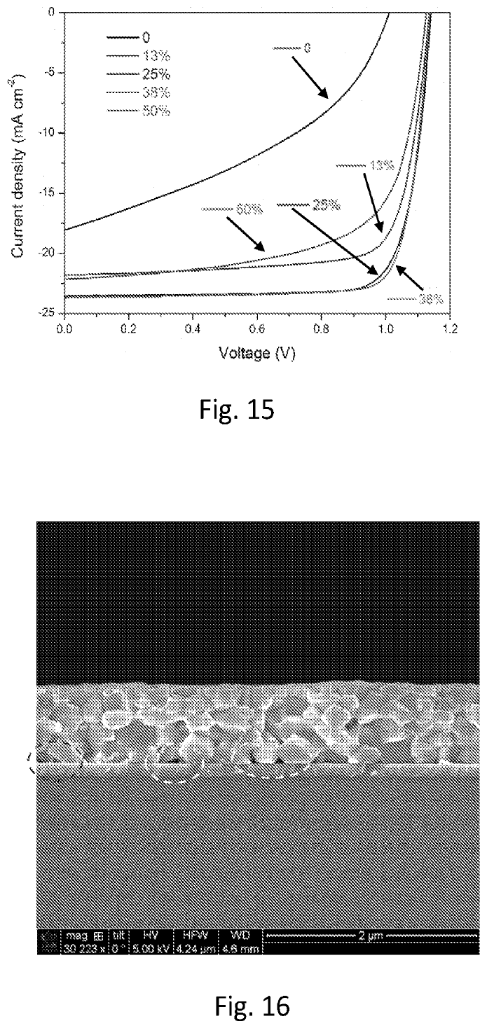

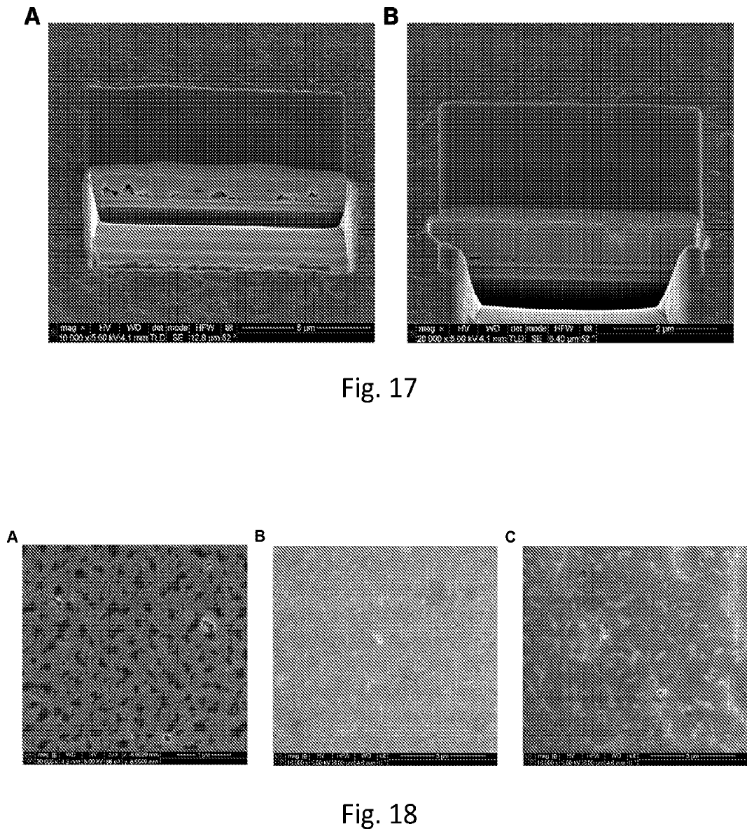

The impact of DMSO on perovskites near the HTL interface was investigated by changing the molar ratio of DMSO to Pb in MA_{0.6}FA_{0.4}PbI₃ precursor solutions from 0 to 50%. Using the same peeling technique, the bottom interface morphology (FIG. 13B) at a lower amount of DMSO (<13%), was very poor. Insufficient DMSO was present, and rapid crystallization of the precursor solution quickly created a porous film full of voids. Increasing the amount of DMSO to Pb from 13% to 25% reduced both the density and size of voids at the perovskite bottom interface. The PCEs of the corresponding PSCs increased from 19.0% to 21.5% (FIG. 15 and table 4). Further increasing the amount of DMSO to 38% yielded a maximum PCE of 22.0% (denoted as control device hereafter), despite the density of interfacial voids increasing and the reappearance of some large voids. The presence of the interfacial voids was also confirmed via cross-sectional SEM (FIG. 16) and focused ion beam (FIB)-SEM (FIG. 17) characterization. Increasing the amount of DMSO to 50% created a film with much larger interfacial voids and a PCE of 16.4%.

TABLE 4
Photovoltaic performance of PSCs processed with
different amounts of DMSO in precursor solutions

| Amount of DMSO | V_{OC} | J_{SC} | | PCE |
|---|---|---|---|---|
| (molar % to Pb) | (V) | (mA cm⁻²) | FF | (%) |
| 0 | 1.01 | 18.1 | 0.397 | 7.25 |
| 13 | 1.14 | 21.8 | 0.766 | 19.0 |
| 25 | 1.14 | 23.5 | 0.802 | 21.5 |
| 38 | 1.14 | 23.7 | 0.816 | 22.0 |
| 50 | 1.13 | 22.2 | 0.655 | 16.4 |

It was observed that the crystallization of perovskite films using one-step solution deposition methods generally started at the film-air interface as the solvents evaporate from the film top surface, quickly forming a solid shell which temporarily traps “wet” films containing high-boiling point DMSO (S. Chen et al., Sci. Adv. 7, eabb2412 (2021)). The trapped DMSO solvent would eventually escape the films, particularly after further annealing, which left voids in the perovskite films near the perovskite-substrate interface because of the volume collapse (FIG. 13C). This phenomenon was more evident in the coated thick films, which further delayed the escape of DMSO from the bottom side. Perovskite films including MAPbI₃, Cs_{0.05}FA_{0.81}MA_{0.14}PbI₃ and Cs_{0.4}FA_{0.6}PbI_{1.95}Br_{1.05} were also examined, spun from DMSO-containing precursor solutions. Voids were observed at all the perovskite-substrate interfaces (FIG. 18). These observations indicate that these voids are a general problem among perovskites prepared using DMSO-containing precursor solutions, even though many reported record performance devices are fabricated by solution processes using DMSO (M. Kim et al., Joule 3, 2179-2192 (2019); and H. Min et al., Science 366, 749-753 (2019)).

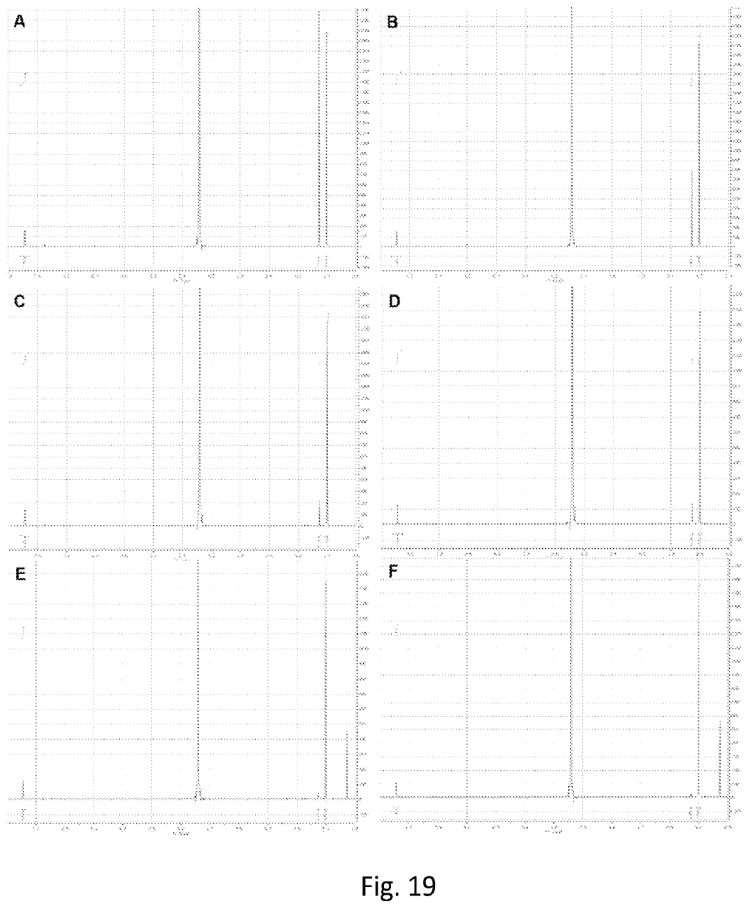

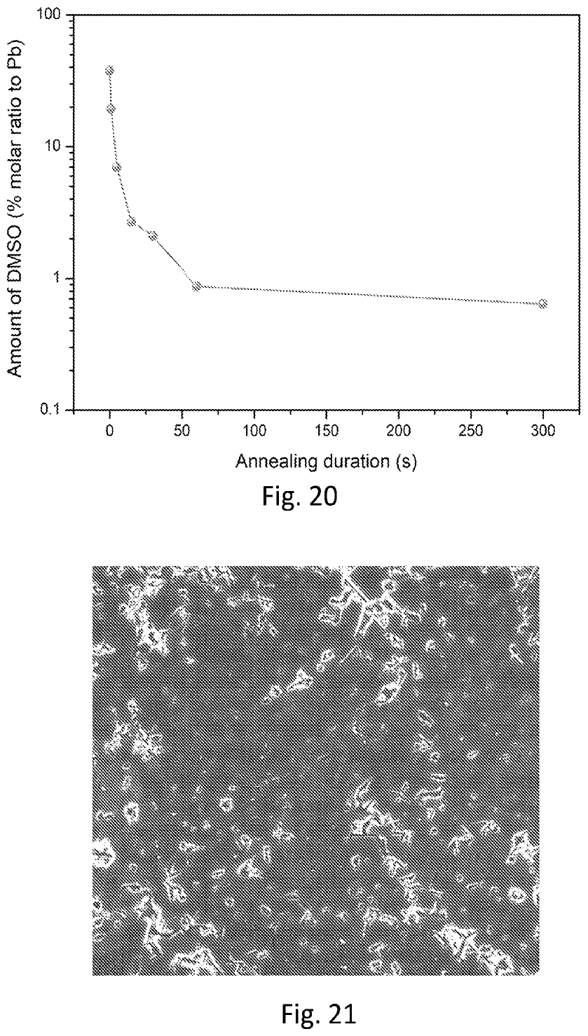

To investigate the evaporation rate of DMSO in perovskite films during thermal annealing, the perovskite films were scraped off glass substrates and then dissolved in deuterium oxide. Proton nuclear magnetic resonance (¹H NMR) characterization was performed on the solutions to determine how much DMSO was trapped in each stage of annealing. By comparing the integrated area of the DMSO ¹H NMR peak and with those of MAI and FAI (FIG. 19), the relative amount of DMSO to MA(FA)I was quantified, and then the amount of Pb in the perovskite films. As shown in FIG. 20, the evaporation of DMSO occurred in two stages: a rapid evaporation in the first few seconds, followed by a slow process from 5 s to 1 min. It is noted that the top solid shell also forms within a few seconds (S. Chen et al., Sci. Adv. 7, eabb2412 (2021)). It is understood that the slow evaporation of DMSO in the second stage is caused by hinderance from the perovskite top shell. Since nearly 90% of DMSO in the perovskite solution evaporated in the first 5 s, about 10% of DMSO, or ˜2 mol % relative to Pb, was trapped initially in the wet bottom layer. It is estimated that this causes a total void volume of 0.01 μm³ per m³ of perovskites based on the residual DMSO amount when the subsequent entrapped DMSO leaves the perovskite-substrate interface. This agrees with the results (1% volume ratio to perovskites) obtained by analyzing the relative ratio between the regions of perovskite grains and voids in the top-view SEM image (FIG. 21) and the void depth of ˜100 nm.

The impact of the interfacial voids on the stability of the perovskite films was investigated. Encapsulated MA_{0.6}FA_{0.4}PbI₃ control films were light-soaked under simulated 1-sun illumination at 60° C. for different durations, and then peeled off from ITO substrates for SEM characterization. Some small white regions started to appear around the voids after 4-hour light-soaking (FIG. 13D). These white regions are generally a result of a charging effect in electron-beam scanning caused by less conductive decomposition products. After 8 hours, the white regions expanded in number and size. However, the regions without voids did not exhibit a significant change. As such, from these results, it can be understood that interfacial voids initialized film degradation at the perovskite-substrate interface.

Several perovskite degradation mechanisms could be triggered by interfacial voids. Photogenerated holes surrounding the voids could not be quickly extracted by the HTL, which would lead to charge accumulation that accelerates perovskite degradation by increasing ion migration (Y. Lin et al., Nat. Commun. 9, 4981 (2018)). The surface of the voids would be similar to perovskite top surfaces that are generally defective, and a lack of passivation coatings would make them degrade more quickly. Voids can act as a reservoir for decomposition products such as iodine vapor, which is generated in perovskite films during light-soaking and can accelerate decomposition (S. G. Motti et al., Nat. Photonics 13, 532-539 (2019); N. Aristidou et al., Angew. Chem. Int. Ed. 54, 8208-8212 (2015); F. Fu et al., Energy Environ. Sci. 12, 3074-3088 (2019); S. Wang, et al., Nat. Energy 2, 16195 (2016); and S. Chen, et al., Sci. Adv., eabe8130 (2021)). Recent studies also show that passivating the perovskite film surfaces can effectively shift the reaction balance for iodide interstitials and thus prevent iodide generation under illumination (S. G. Motti et al., Nat. Photonics 13, 532-539 (2019)).

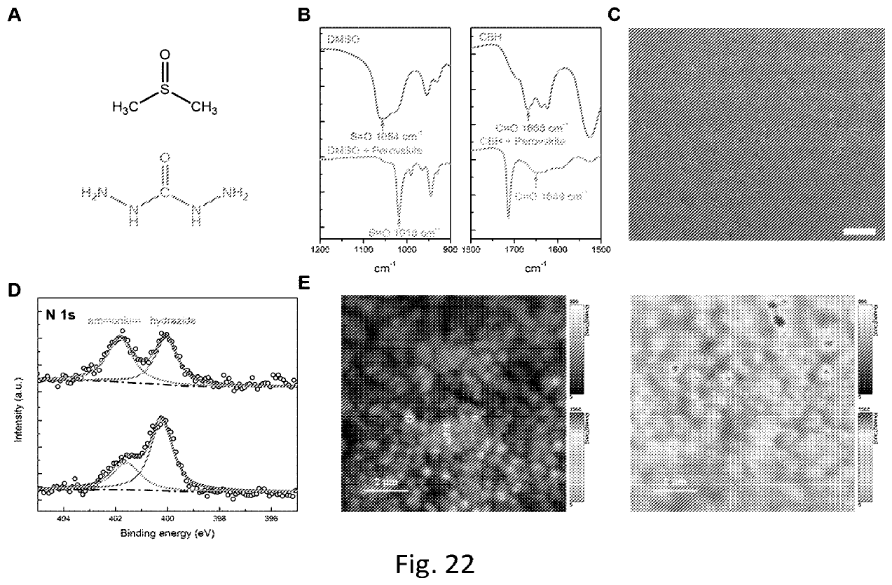

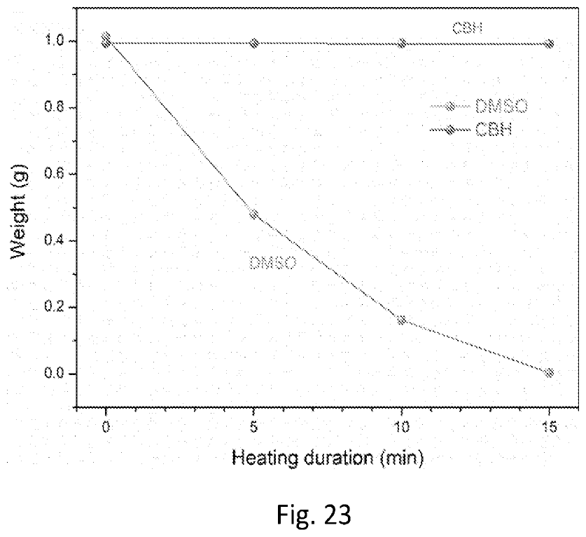

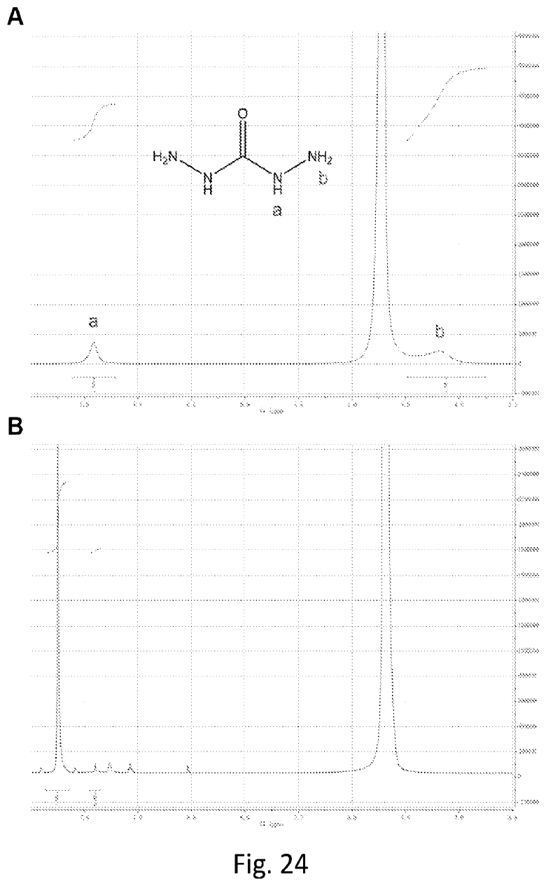

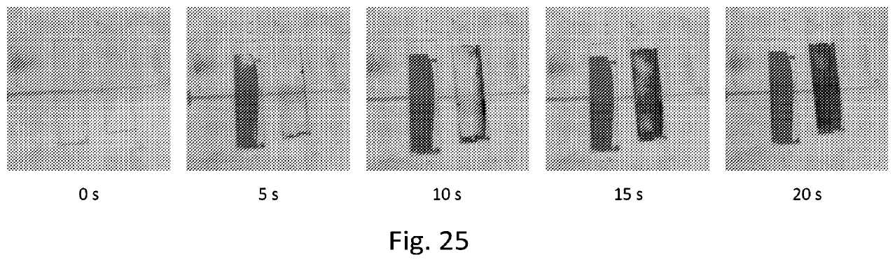

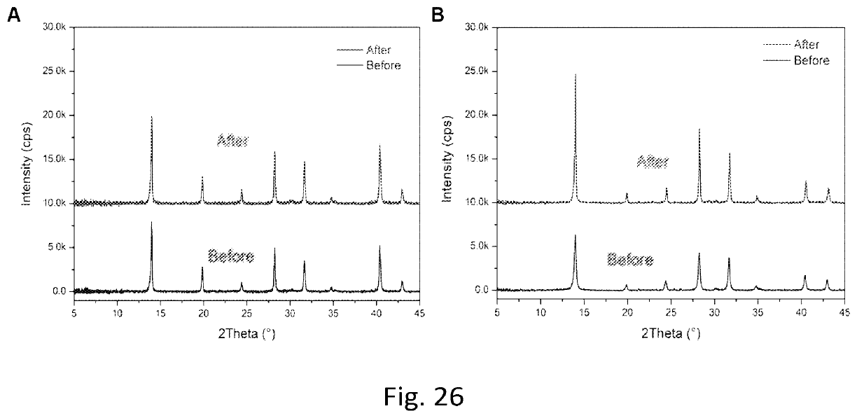

In an effort to address the above issues, DMSO was partially replaced with a solid-state CBH additive (melting point 153° C., denoted as target films or PSCs) that can also coordinate with Pb cations through its C═O bond, similar to DMSO (inset A in FIG. 22). Little CBH evaporated during thermal annealing; thus, CBH remained within the perovskite films (FIG. 23 and FIG. 24). CBH avoids the volume collapse during annealing and thus reduces void formation. Moreover, CBH can reduce the detrimental I₂ generated in perovskite films. First, the shifted Fourier-transform infrared spectroscopy (FTIR) peak of the C═O bond was confirmed after introducing CBH into the MA_{0.6}FA_{0.4}PbI₃ films (inset B of FIG. 22). Such an interaction was found to slow down the rapid crystallization and enhance the crystallization of perovskite films (FIGS. 25 and 26).

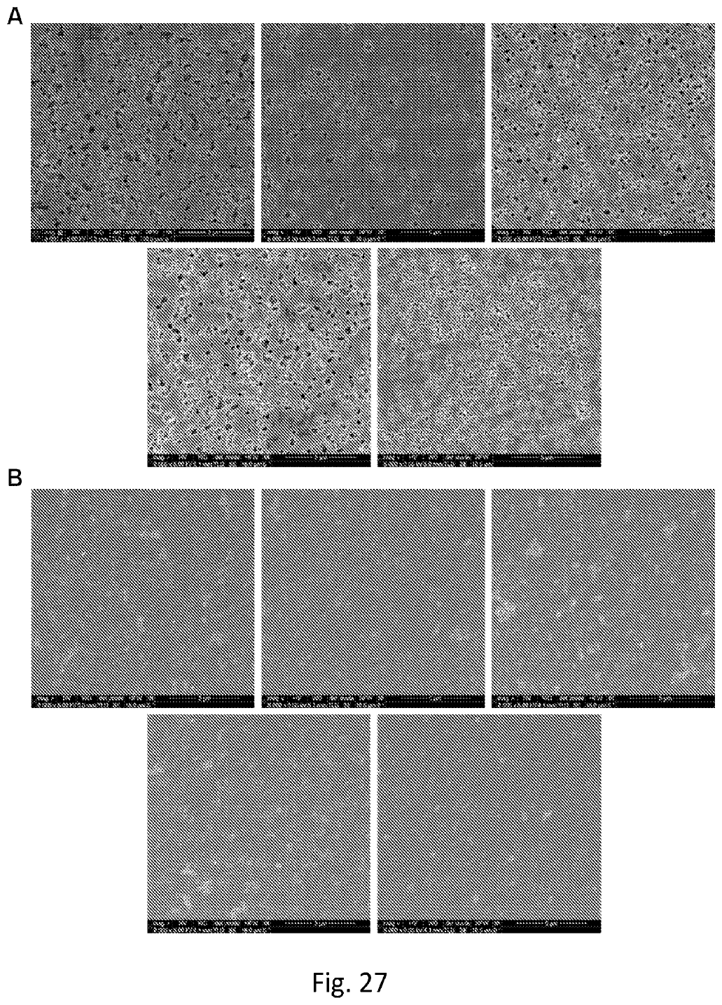

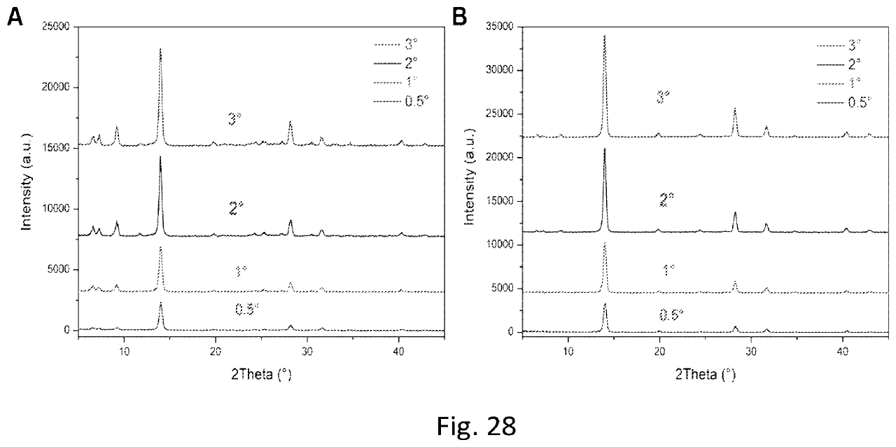

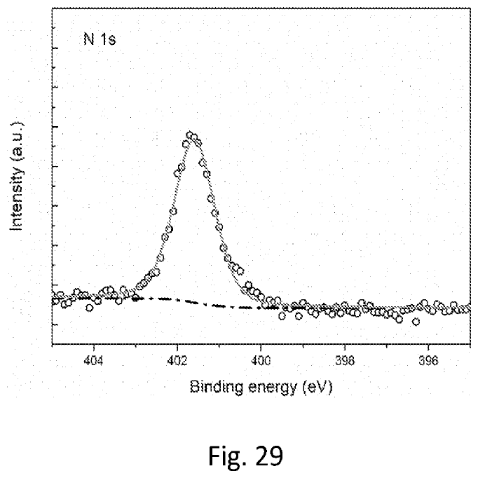

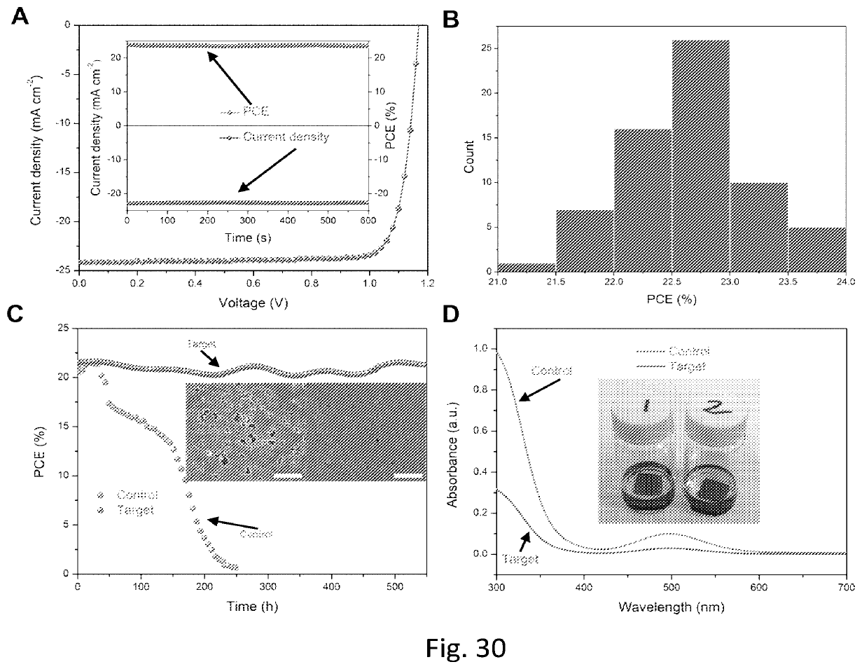

Voids were dramatically reduced with the CBH additive (inset C in FIG. 22 and FIG. 27), which could be at least partially due to CBH's non-volatility. While some amount of DMSO (˜25% to Pb) in the solution helped grain growth, it was the entrapped 10% of DMSO that caused void formation. The quick top perovskite shell formation and later release of CBH molecules from the CBH-Pb coordinates should expel some CBH molecules toward the HTL side due to the downward film crystallization, evidenced by grazing incidence X-ray diffraction (GIXRD) results (FIG. 28). XPS characterization of both perovskite-air and perovskite-HTL interfaces of the identical target perovskite films showed more CBH molecules at the perovskite-HTL interface (inset D in FIG. 22), while the control film only showed a single ammonium peak (FIG. 29). In addition, photoluminescence (PL) mapping of the perovskite films excited from the thin cover glass side was performed. The target perovskite film showed both more uniform PL emission (likely from fewer voids) and stronger PL emission (from passivation effects) than the control film (inset E in FIG. 22). Both effects should reduce charge recombination and facilitate charge extraction.

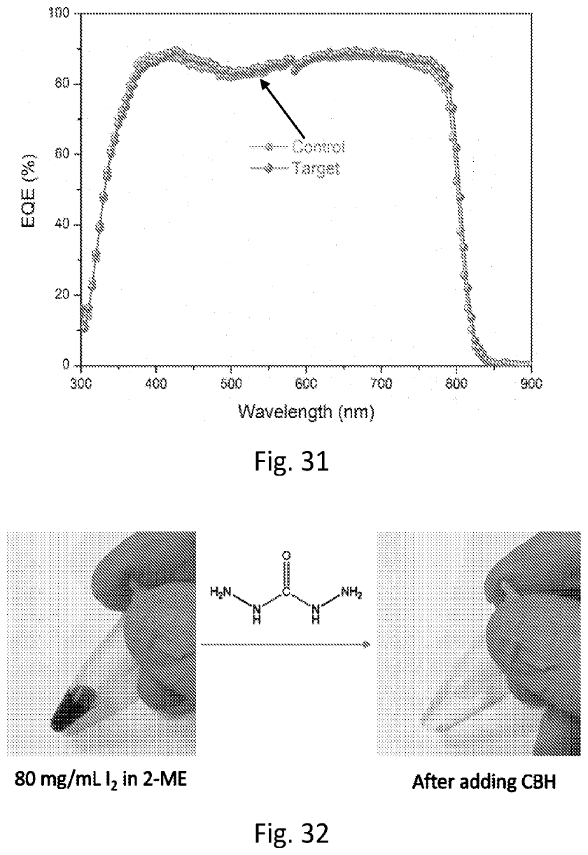

The current density-voltage (J-V) characteristics show that the target PSCs delivered a PCE of 23.8% (inset A in FIG. 30), with an elevated open-circuit voltage (V_{OC}) of 1.17 V, a short-circuit current density (J_{SC}) of 24.1 mA cm², and a fill factor (FF) of 0.842. The optical bandgap of the target PSCs determined from the absorption onset of the external quantum efficiency (EQE) spectra was 1.49 eV (FIG. 31), which gave a small V_{OC} deficit of 0.32 V. The champion PSC showed a stabilized PCE of 23.6% (inset A in FIG. 30). The PSCs also showed good reproducibility (inset B in FIG. 30), where 50% and 88% of PSCs could realize PCEs of over 22.5% and 22.0%, respectively.

The long-term stability of encapsulated perovskite devices was tested under a plasma lamp with a light intensity equivalent to AM 1.5G in air at a relative humidity ˜40±10%. No UV filter was used during the tests. All devices were connected to an automatic maximum power point (MPP) tracker so that the devices continued working under MPP conditions during light soaking. The temperature of the devices was measured to be ˜60° C. (the heating effect of light). The operational stability of control and CBH-incorporated PSCs was compared in inset C in FIG. 30. The CBH-incorporated PSC showed negligible efficiency loss after 550-hour light-soaking, whereas the control one was near zero power output after ˜200-hour light-soaking. This good stability was realized without further post-treatments on the blade-coated perovskite films.

After the stability tests, the light-soaked devices were peeled-off from the ITO glass substrates and SEM characterization was performed on the perovskite-substrate interfaces. The control device showed substantial degradation at its perovskite-substrate interface accompanied by the merging of voids, whereas the CBH device did not show notable morphology changes at the bottom interface (inset C in FIG. 30). The enhanced operational stability was attributed not only to the reduction in interfacial voids that accumulate charges and decomposition products, but also to CBH being an effective reductant (FIG. 32). The CBH residuals in perovskite films could further reduce the detrimental iodine formed in perovskites during the light-soaking back to I⁻. The target film was placed in a vial filled with 5 mL toluene and then illuminated for 15 hours. The UV-vis absorption spectra of the toluene extractions show that iodine formation was suppressed by the residual CBH (inset D in FIG. 30).

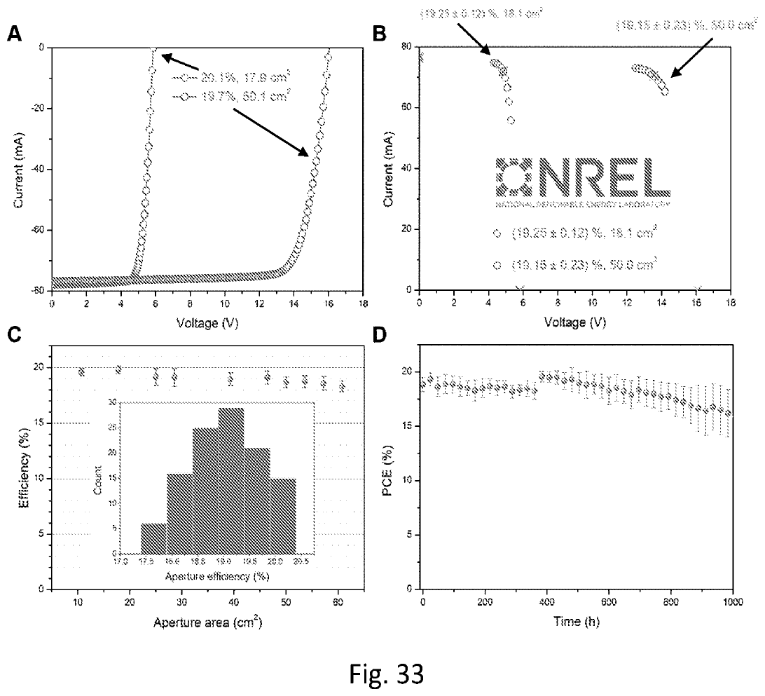

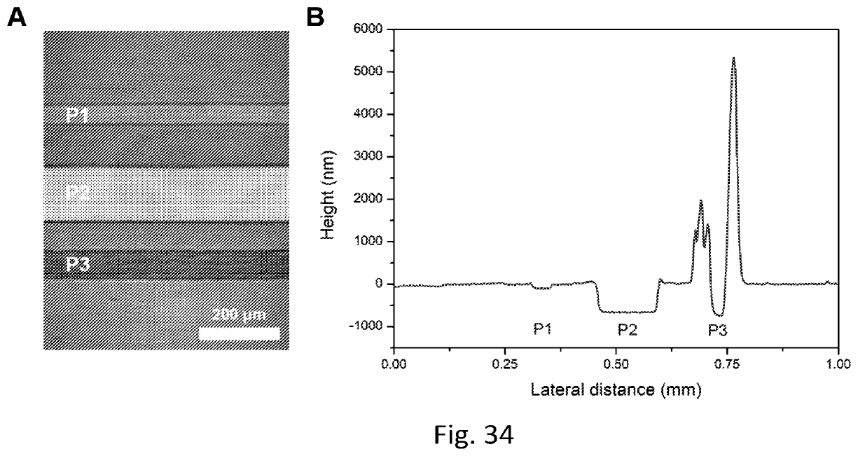

The compatibility of the CBH additive was evaluated with upscaling processes by fabricating perovskite mini-modules with aperture areas from 10.7 to 60.8 cm² by blade-coating. The mini-modules with 5 and 14 sub-cells showed high aperture efficiencies of 20.1% (V_{OC}: 1.17 V, J_{SC}: 21.8 mA cm⁻², FF: 0.786 for each sub-cell) and 19.7% (V_{OC}: 1.15 V, J_{SC}: 21.5 mA, FF: 0.798 for each sub-cell) with aperture areas of 17.9 cm² and 50.1 cm², respectively (inset A in FIG. 33), derived from J-V scanning. The geometric fill factor (GFF) of the champion mini-modules was 92% (FIG. 34); thus, each sub-cell with an area of 3.6 cm² in the best mini-module exhibited a J_{SC} of 23.7 mA cm⁻², V_{OC} of 1.17 V, and an active area efficiency of 21.8%.

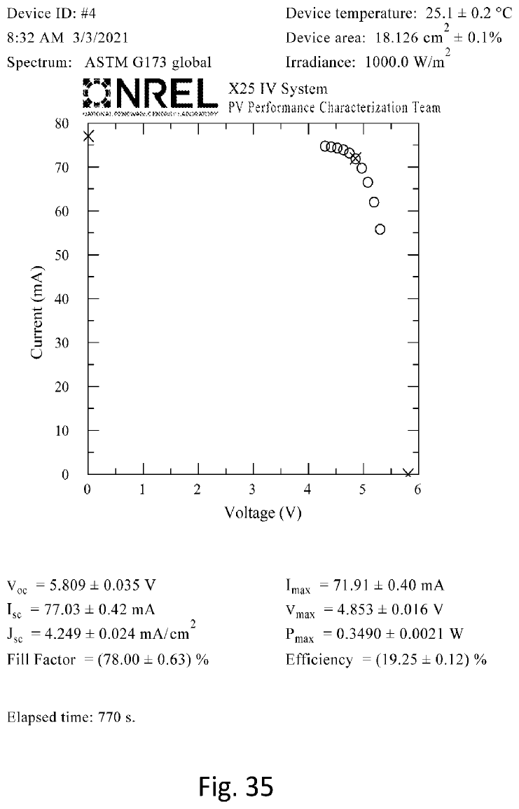

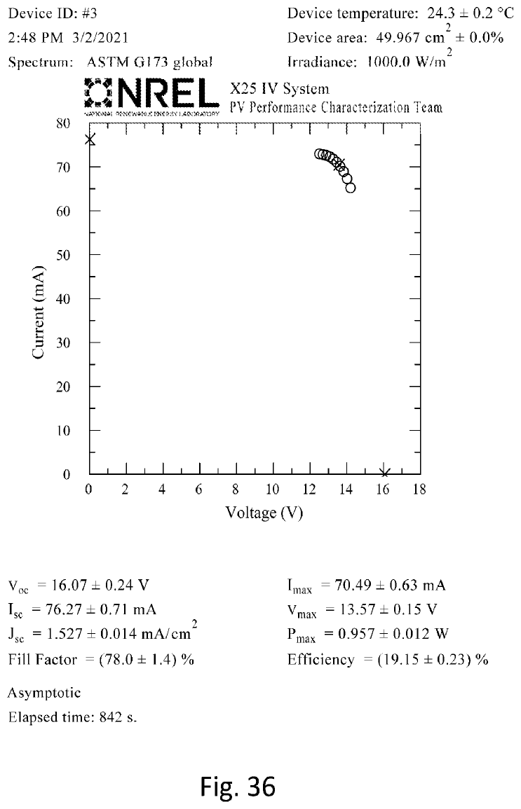

The champion mini-modules were sent to NREL for certification, and highest stabilized aperture efficiencies of 19.3% and 19.2% were attained for the mini-modules with certified aperture areas of 18.1 and 50.0 cm² (inset B in FIG. 33, FIGS. 35 and 36), respectively. Stabilizing photocurrent is needed to get an accurate efficiency for module measurement, and regular J-V scanning generally overestimates the module efficiency by 0.5 to 1% regardless of the scanning rate. The aperture efficiencies of 112 mini-modules were further analyzed statistically, and their distribution is shown in inset C of FIG. 33 with the detailed photovoltaic parameters provided in Table 5. More than 50% of mini-modules showed aperture PCEs of >19.0%, and 77% of them had efficiencies of >18.5%, indicating the method's good reproducibility. A plot of the efficiencies and aperture areas of the 112 mini-modules are shown in inset C of FIG. 33. Module efficiencies were not sensitive to the aperture area and a high efficiency of (18.3±0.48)% was maintained with increasing aperture areas to >60 cm² as a result of high film uniformity after introducing CBH. Furthermore, the long-term operational stability of the highly efficient perovskite mini-modules was also tested (inset D in FIG. 33). Five mini-modules retained 85% of initial PCEs after 1000-hour light soaking under simulated 1 sun illumination at 50° C.

TABLE 5
Photovoltaic Performance of 112 Perovskite Mini-modules

| Module | Aperture | No. of sub- | V_{OC} | I_{SC} | | PCE |
|---|---|---|---|---|---|---|
| No. | area (cm²) | cells | (V) | (mA) | FF | (%) |
| 1 | 10.7 | 3 | 3.53 | 80.3 | 0.761 | 20.1 |
| 2 | 10.7 | 3 | 3.52 | 79.0 | 0.771 | 20.0 |
| 3 | 10.7 | 3 | 3.50 | 77.3 | 0.773 | 19.5 |
| 4 | 10.7 | 3 | 3.51 | 77.6 | 0.772 | 19.6 |
| 5 | 10.7 | 3 | 3.49 | 76.9 | 0.772 | 19.3 |
| 6 | 10.7 | 3 | 3.50 | 77.7 | 0.771 | 19.6 |
| 7 | 10.7 | 3 | 3.47 | 76.4 | 0.770 | 19.1 |
| 8 | 17.9 | 5 | 5.82 | 78.5 | 0.749 | 19.1 |
| 9 | 17.9 | 5 | 5.84 | 77.8 | 0.783 | 19.9 |
| 10 | 17.9 | 5 | 5.83 | 77.9 | 0.784 | 19.9 |
| 11 | 17.9 | 5 | 5.85 | 78.1 | 0.784 | 20.0 |
| 12 | 17.9 | 5 | 5.85 | 77.9 | 0.786 | 20.1 |
| 13 | 17.9 | 5 | 5.85 | 77.1 | 0.786 | 19.8 |
| 14 | 25.0 | 7 | 8.32 | 77.5 | 0.711 | 18.3 |
| 15 | 25.0 | 7 | 8.33 | 78.4 | 0.718 | 18.7 |
| 16 | 25.0 | 7 | 8.11 | 78.9 | 0.765 | 19.5 |
| 17 | 25.0 | 7 | 8.13 | 79.0 | 0.750 | 19.3 |
| 18 | 25.0 | 7 | 8.11 | 79.2 | 0.760 | 19.5 |
| 19 | 25.0 | 7 | 8.10 | 80.2 | 0.760 | 19.7 |
| 20 | 25.0 | 7 | 8.10 | 79.2 | 0.781 | 20.0 |
| 21 | 25.0 | 7 | 8.12 | 78.9 | 0.776 | 19.9 |
| 22 | 25.0 | 7 | 8.11 | 78.9 | 0.773 | 19.8 |
| 23 | 25.0 | 7 | 8.04 | 77.1 | 0.765 | 19.0 |
| 24 | 25.0 | 7 | 8.21 | 79.3 | 0.769 | 20.0 |
| 25 | 25.0 | 7 | 8.19 | 76.3 | 0.774 | 19.3 |
| 26 | 25.0 | 7 | 8.09 | 76.5 | 0.748 | 18.5 |
| 27 | 25.0 | 7 | 8.19 | 78.9 | 0.773 | 20.0 |
| 28 | 25.0 | 7 | 8.15 | 78.5 | 0.779 | 19.9 |
| 29 | 25.0 | 7 | 8.08 | 78.0 | 0.763 | 19.2 |
| 30 | 25.0 | 7 | 8.21 | 76.6 | 0.763 | 19.2 |
| 31 | 25.0 | 7 | 7.89 | 78.4 | 0.746 | 18.4 |
| 32 | 25.0 | 7 | 8.03 | 72.8 | 0.754 | 17.6 |
| 33 | 25.0 | 7 | 8.04 | 73.0 | 0.746 | 17.5 |
| 34 | 28.6 | 8 | 9.45 | 76.5 | 0.784 | 19.8 |
| 35 | 28.6 | 8 | 9.50 | 77.1 | 0.770 | 19.7 |
| 36 | 28.6 | 8 | 9.49 | 77.5 | 0.773 | 19.9 |
| 37 | 28.6 | 8 | 9.52 | 77.7 | 0.776 | 20.1 |
| 38 | 28.6 | 8 | 9.50 | 76.9 | 0.767 | 19.6 |
| 39 | 28.6 | 8 | 9.47 | 74.1 | 0.774 | 19.0 |
| 40 | 28.6 | 8 | 9.50 | 75.2 | 0.775 | 19.3 |
| 41 | 28.6 | 8 | 9.50 | 75.3 | 0.760 | 19.0 |
| 42 | 28.6 | 8 | 9.53 | 75.5 | 0.768 | 19.3 |
| 43 | 28.6 | 8 | 9.53 | 76.2 | 0.776 | 19.7 |
| 44 | 28.6 | 8 | 9.51 | 76.1 | 0.780 | 19.7 |
| 45 | 28.6 | 8 | 9.52 | 76.3 | 0.753 | 19.1 |
| 46 | 28.6 | 8 | 9.48 | 76.6 | 0.760 | 19.3 |
| 47 | 28.6 | 8 | 9.54 | 77.0 | 0.769 | 19.8 |
| 48 | 28.6 | 8 | 9.17 | 72.9 | 0.746 | 17.4 |
| 49 | 28.6 | 8 | 9.54 | 72.8 | 0.760 | 18.5 |
| 50 | 28.6 | 8 | 9.08 | 73.6 | 0.747 | 17.5 |
| 51 | 28.6 | 8 | 9.05 | 75.8 | 0.736 | 17.6 |
| 52 | 39.3 | 11 | 12.89 | 75.2 | 0.768 | 18.9 |
| 53 | 39.3 | 11 | 12.76 | 76.8 | 0.759 | 18.9 |
| 54 | 39.3 | 11 | 12.83 | 79.3 | 0.767 | 19.8 |
| 55 | 39.3 | 11 | 12.82 | 75.8 | 0.762 | 18.8 |
| 56 | 39.3 | 11 | 12.88 | 77.6 | 0.765 | 19.4 |
| 57 | 39.3 | 11 | 12.73 | 73.9 | 0.778 | 18.6 |
| 58 | 39.3 | 11 | 12.86 | 73.8 | 0.780 | 18.8 |
| 59 | 39.3 | 11 | 12.74 | 74.2 | 0.761 | 18.3 |
| 60 | 39.3 | 11 | 12.84 | 74.9 | 0.773 | 18.9 |
| 61 | 39.3 | 11 | 12.73 | 74.7 | 0.761 | 18.4 |
| 62 | 39.3 | 11 | 12.87 | 75.3 | 0.772 | 19.0 |
| 63 | 39.3 | 11 | 12.70 | 73.5 | 0.771 | 18.3 |
| 64 | 39.3 | 11 | 12.88 | 74.3 | 0.779 | 18.9 |
| 65 | 39.3 | 11 | 12.86 | 78.6 | 0.781 | 20.1 |
| 66 | 39.3 | 11 | 12.91 | 78.2 | 0.778 | 20.0 |
| 67 | 39.3 | 11 | 12.62 | 73.3 | 0.774 | 18.2 |
| 68 | 46.5 | 13 | 15.15 | 76.2 | 0.784 | 19.5 |
| 69 | 46.5 | 13 | 15.17 | 76.6 | 0.780 | 19.5 |
| 70 | 46.5 | 13 | 15.19 | 76.5 | 0.788 | 19.7 |
| 71 | 46.5 | 13 | 15.09 | 72.2 | 0.782 | 18.3 |
| 72 | 46.5 | 13 | 15.13 | 71.9 | 0.788 | 18.5 |
| 73 | 50.1 | 14 | 16.29 | 75.2 | 0.775 | 19.0 |
| 74 | 50.1 | 14 | 16.28 | 75.3 | 0.776 | 19.0 |
| 75 | 50.1 | 14 | 16.05 | 77.0 | 0.748 | 18.5 |
| 76 | 50.1 | 14 | 16.10 | 76.9 | 0.762 | 18.8 |
| 77 | 50.1 | 14 | 16.05 | 76.8 | 0.798 | 19.7 |
| 78 | 50.1 | 14 | 16.17 | 76.9 | 0.765 | 19.0 |
| 79 | 50.1 | 14 | 16.10 | 76.8 | 0.763 | 18.8 |
| 80 | 50.1 | 14 | 15.97 | 76.8 | 0.741 | 18.2 |
| 81 | 50.1 | 14 | 15.94 | 76.8 | 0.744 | 18.2 |
| 82 | 50.1 | 14 | 15.92 | 77.0 | 0.740 | 18.1 |
| 83 | 50.1 | 14 | 15.94 | 76.8 | 0.744 | 18.2 |
| 84 | 53.6 | 15 | 17.67 | 76.8 | 0.745 | 18.9 |
| 85 | 53.6 | 15 | 17.60 | 76.4 | 0.736 | 18.5 |
| 86 | 53.6 | 15 | 17.68 | 77.2 | 0.767 | 19.5 |
| 87 | 53.6 | 15 | 17.35 | 73.2 | 0.756 | 17.9 |
| 88 | 53.6 | 15 | 17.53 | 73.3 | 0.772 | 18.5 |
| 89 | 53.6 | 15 | 17.53 | 75.9 | 0.777 | 19.3 |
| 90 | 53.6 | 15 | 17.67 | 73.1 | 0.769 | 18.5 |
| 91 | 53.6 | 15 | 17.66 | 72.8 | 0.770 | 18.5 |
| 92 | 53.6 | 15 | 17.41 | 74.0 | 0.766 | 18.4 |
| 93 | 53.6 | 15 | 17.39 | 72.6 | 0.775 | 18.3 |
| 94 | 53.6 | 15 | 17.63 | 75.3 | 0.775 | 19.2 |
| 95 | 53.6 | 15 | 17.53 | 76.0 | 0.778 | 19.3 |
| 96 | 53.6 | 15 | 17.56 | 75.9 | 0.736 | 18.3 |
| 97 | 53.6 | 15 | 17.34 | 74.1 | 0.754 | 18.1 |
| 98 | 53.6 | 15 | 17.31 | 75.1 | 0.778 | 18.9 |
| 99 | 53.6 | 15 | 17.28 | 75.5 | 0.765 | 18.6 |
| 100 | 57.2 | 16 | 18.43 | 75.9 | 0.730 | 17.9 |
| 101 | 57.2 | 16 | 18.49 | 75.5 | 0.766 | 18.7 |
| 102 | 57.2 | 16 | 18.53 | 74.7 | 0.770 | 18.6 |
| 103 | 57.2 | 16 | 18.49 | 74.4 | 0.771 | 18.5 |
| 104 | 57.2 | 16 | 18.54 | 73.9 | 0.790 | 18.9 |
| 105 | 57.2 | 16 | 18.43 | 73.7 | 0.779 | 18.5 |
| 106 | 57.2 | 16 | 18.47 | 74.4 | 0.773 | 18.6 |
| 107 | 60.8 | 17 | 19.40 | 74.0 | 0.746 | 17.6 |
| 108 | 60.8 | 17 | 19.54 | 74.2 | 0.767 | 18.3 |
| 109 | 60.8 | 17 | 19.54 | 74.6 | 0.765 | 18.4 |
| 110 | 60.8 | 17 | 19.64 | 72.0 | 0.768 | 17.9 |
| 111 | 60.8 | 17 | 19.80 | 73.0 | 0.780 | 18.6 |
| 112 | 60.8 | 17 | 19.70 | 76.7 | 0.769 | 19.1 |

### Materials and Methods for Additional Carbohydrazide Experiments

### Materials

CBH, PTAA (average Mₙ 7,000-10,000), BCP, PbI₂ (99.999% trace metals), DMSO, 2-ME, L-α-phosphatidylcholine (LP), and toluene were purchased from Sigma-Aldrich and used without further purification. C₆₀ was purchased from Nano-C Inc. MAI, FAI, 4-fluoro-phenylammonium iodide (p-F-PEAI), and n-dodecylammonium iodide were purchased from GreatCell Solar.

### Device Fabrication

Patterned ITO glass substrates (0.7 mm thick, 1.5 cm by 1.5 cm for solar cells, and 13.0 cm by 8.5 cm for solar modules) were first cleaned by ultrasonication with soap, deionized water, and isopropyl alcohol, and then UV-ozone treated for 15 min before use. All perovskite solar devices were prepared by blade-coating at room temperature inside a fume hood with a relative humidity of 40±5%. The hole-transporting PTAA layer with a concentration of 3.3 mg mL⁻¹ dissolved in toluene was blade-coated onto ITO glass substrates at a speed of 20 mm s⁻¹. The gap between the blade-coater and ITO substrates was 150 μm. The perovskite precursor solutions (2.5 M MAPbI₃ and 1.67 M FAPbI₃) were prepared separately by dissolving corresponding organic halides and lead iodide in 2-ME and stored in an N₂-filled glovebox. Before blade-coating, MAPbI₃ and FAPbI₃ precursor solutions were mixed and diluted to a 1.35 M MA_{0.6}FA_{0.4}PbI₃ solution. 1.5% molar CBH and 25% DMSO with respect to Pb were added to a target perovskite precursor solution, while 38% DMSO was added to a control precursor solution. 0.83 mg mL⁻¹ n-dodecylammonium iodide, 0.27 mg mL⁻¹ LP, 0.14% v/v MAH₂PO₂, 1.40 mg mL⁻¹ p-F-PEAI, and 25% DMSO were added into both precursor solutions as additives. These additives help achieve high-efficiency devices by tuning film drying and passivating perovskites. Subsequently, the precursor solution was blade-coated onto the PTAA-covered ITO glass substrates with a gap of 250 m at a movement speed of 20 mm s⁻¹. The N₂ knife worked at 20 psi (420 SCFH) during blade-coating. After that, the perovskite films were annealed at 120° C. for 5 min in air. The thickness of the films was ˜1 μm. The solar cells were completed by thermally evaporating C₆₀ (30 nm, 0.2 Å s⁻¹), BCP (6 nm, 0.1 Å s¹), and 100 nm copper (1 Å s¹). A 100-nm MgF₂ layer was evaporated onto the front surface of ITO glass substrates as an anti-reflection layer. The active area of solar cells was 8 mm² (4 mm by 2 mm determined by a metal shadow mask). The mini-modules were fabricated on the pre-patterned large ITO glass substrates (13.0×8.5 cm, P1 width 50 μm) following the same procedure as the solar cells. The fabricated modules typically have 3 to 17 sub-cells, and each sub-cell has a width of 6.5 mm. The laser scribing was performed twice with a Keyence laser marker (MD-U1000C, 355 nm). The final widths of P2 and P3 were measured to be 140 and 70 μm, respectively. The total scribing line width was 0.52 mm, giving a GFF of 92%. A polydimethylsiloxane (PDMS) layer was applied to the surface of the glass substrate as an anti-reflection coating.

### Device Characterization

The J-V characteristics of solar cells and mini-modules were obtained using a Xenon-lamp-based solar simulator (Oriel Sol3A, Class AAA Solar Simulator) and the power of the simulated light was calibrated to 100 mW cm⁻² by a silicon reference cell (Newport 91150V-KG5). All devices were measured using a Keithley 2400 source meter with a backward scan rate of 0.1 V s⁻¹ in air at room temperature, and the delay time was 10 ms. There was no preconditioning before measurement. A metal mask with an aperture (7.0 mm²) aligned with the device area was used for the measurement of solar cells. EQE spectra were obtained with a Newport QE measurement kit by focusing a monochromatic beam of light onto the devices. Both SEM and FIB-SEM images were taken on FEI Helios 600 Nanolab Dual Beam System. For SEM characterization, the accelerating voltage of the electron beam was 5 kV, and the current was 86 pA. Perovskite film samples were ˜1,000 nm thick coated on PTAA-covered ITO glass substrates, and a through-the-lens detector (TLD) was used to acquire the images. Except for some variations that could be caused by manual focusing, all SEM images were captured under essentially the same conditions. For FIB-SEM characterization, to prevent damage from Ga-ion imaging or milling, the regions of interest were previously coated with a 0.2-μm-thick Pt layer deposited by ion beam-induced deposition (IBID). The cross sections of the perovskite films on PTAA-covered ITO glass substrates were done with a FIB using Ga ions at an acceleration voltage of 30 kV. The ion current of 0.28 nA and 28 pA were used for regular and clean cross sections, respectively. The milling of the cross sections were performed with a gallium ion source at a 52° tilting angle. UV-vis absorption spectra were obtained with a Thermo Scientific Evolution 201 spectrophotometer. FTIR spectra were acquired with a PerkinElmer Spectrum Two FT-IR spectrometer. The precursor solutions were drop-cast onto CaF₂ substrates and measured before thermal annealing. PL mapping was conducted with PicoQuant MicroTime 100 and FluoTime 100 system at room temperature. PicoQuant PDL 828 “Sepia II” multichannel diode laser was used as the laser source and a 485 nm pulsed laser was used for the measurements. The PL signal was detected by the PicoQuant PMA Hybrid single photon counting module with TCSPC technology. The GFF of mini-modules was determined with a Brucker Dektak XT Profiler. Grazing incidence X-ray diffraction (GIXRD) measurements were carried out with a Rigaku SmartLab diffractometer using Cu Kα radiation (a wavelength of 1.5418 Å), and the height of films was calibrated before each measurement. XRD patterns were obtained with a Rigaku sixth generation MiniFlex X-ray diffractometer. XPS characterization was performed on a Kratos Axis Ultra DLD X-ray Photoelectron Spectrometer by using a monochromatized Al Kα source (hv=1486.6 eV). AFM images were scanned from an Asylum Research MFP3D Atomic Force Microscope under tapping mode. ¹H NMR spectra were acquired with a Bruker AVANCE III 600 MHz NMR Spectrometer. The NMR liquid samples were prepared as follows: first, the perovskite films were blade-coated onto glass substrates (76 mm by 51 mm), and then annealed on a hot plate for different durations. After that, the perovskite films were carefully scraped off glass substrates with a stainless-steel blade, and the perovskite powers were quickly transferred to NMR tubes filled with deuterium oxide, which were then shaken thoroughly before the characterization.

### Device Encapsulation and Stability Tests

A thin layer of CYTOP was blade-coated onto the back of the PSCs or solar modules for operational stability tests. After being dried at 60° C. in air for 10 min, the PSCs and solar modules were then encapsulated with cover glass sealed by epoxy encapsulant (Gorilla 2-part epoxy 4200130) on the back. After curing, the glass slides could be peeled off from ITO glass substrates with a glass nipping plier. A plasma lamp with a light intensity equivalent to AM 1.5G without any ultraviolet filter worked as a solar simulator in air (relative humidity ˜40±10%). The temperature of the solar cells was measured to be ˜60° C. due to the heating effects of the lamp. The solar cells were connected to an EnliteTech LS-6100 MPP tracker that automatically tracked the MPPs after each J-V sweeping every 6 hours so that the solar cells always worked at MPP conditions during the stability tests. The solar modules were connected to a resistor so that the modules worked at near MPP conditions, and the PCEs were monitored by J-V characteristics under simulated AM 1.5G one sun illumination (Oriel Sol3A, Class AAA Solar Simulator) every 24 hours.

I⁻ ions were observed to be oxidized to I₂ during the storage of perovskite precursor solutions, which deteriorated the quality of the perovskite films and the performance of the resulting PSCs. The addition of BHC can effectively reduce detrimental I₂ and restore the precursor solutions. Also, the remaining BHC can passivate the film defects and stabilize the PSCs. As a result, a stabilized PCE of 23.2% was achieved in the blade-coated PSCs. The subject matter described herein demonstrates the importance of stabilizing precursor solutions, and provides an effective strategy to improve the performance and reproducibility of perovskite solar devices.

Efforts have been made to ensure accuracy with respect to numbers used (e.g., amounts, temperature, etc.) but some experimental errors and deviations should be accounted for.

One skilled in the art will recognize many methods and materials similar or equivalent to those described herein, which could be used in the practicing the subject matter described herein. The present disclosure is in no way limited to just the methods and materials described.

Unless defined otherwise, technical and scientific terms used herein have the same meaning as commonly understood by one of ordinary skill in the art to which this subject matter belongs.

Throughout this specification and the claims, the words “comprise,” “comprises,” and “comprising” are used in a non-exclusive sense, except where the context requires otherwise. It is understood that embodiments described herein include “consisting of” and/or “consisting essentially of” embodiments.

Where a range of values is provided, it is understood that each intervening value, to the tenth of the unit of the lower limit, unless the context clearly dictates otherwise, between the upper and lower limit of the range and any other stated or intervening value in that stated range, is encompassed. The upper and lower limits of these small ranges which may independently be included in the smaller rangers is also encompassed, subject to any specifically excluded limit in the stated range. Where the stated range includes one or both of the limits, ranges excluding either or both of those included limits are also included.

Many modifications and other embodiments set forth herein will come to mind to one skilled in the art to which this subject matter pertains having the benefit of the teachings presented in the foregoing descriptions and the associated drawings. Therefore, it is to be understood that the subject matter is not to be limited to the specific embodiments disclosed and that modifications and other embodiments are intended to be included within the scope of the appended claims. Although specific terms are employed herein, they are used in a generic and descriptive sense only and not for purposes of limitation.

What is claimed is:

1. An oxidative-resistant ink solution, comprising:
a) a composition of Formula (I):
ABI_{3-y}X_{y} (I)
wherein,
A is a cation selected from the group consisting of methylammonium (MA), tetramethylammonium, formamidinium (FA), cesium (Cs), rubidium (Rb), potassium (K), sodium (Na), butylammonium (BA), phenethylammonium (PEA), phenylammonium (PA), guanidinium (GA), and a combination thereof;
B is a metal cation selected from the group consisting of lead, tin, calcium, cadmium, germanium, zinc, nickel, platinum, palladium, mercury, titanium, silicon, and a combination thereof;
X is selected from the group consisting of Cl⁻, Br⁻, F⁻, SCN⁻, and a combination thereof, and
y is between 0 and 3;
b) one or more solvents;
and
c) a compound of Formula (II): 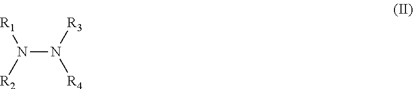
wherein, R₁, R₂, R₃, and R₄ are each independently selected from the group consisting of hydrogen, C₁-C₄₀ alkyl, C₂-C₄₀ alkenyl, C₂-C₄₀ alkynyl, aminoalkyl, C₆-C₁₂ aryl, C₃-C₇ cycloalkyl, 4- to 7-membered heterocyclyl, 5- to 10-membered heteroaryl, C₆-C₁₂ aryl-C₁-C₁₀ alkyl, C₃-C₇ cycloalkyl-C₁-C₁₀ alkyl, 4- to 7-membered heterocyclyl-C₁-C₁₀ alkyl, 5- to 10-membered heteroaryl-C₁-C₁₀ alkyl, and C₁-C₂₀ alkyl-thio-C₁-C₂₀ alkyl, each of which is optionally substituted one or more times with a substituent, each independently selected from the group consisting of halogen, cyano, hydrazino, C₁-C₂₀ alkyl, amino, C₁-C₂₀ alkoxy, C₂-C₂₀ alkenyl, C₂-C₂₀ alkynyl, C₆-C₁₂ aryl, C₃-C₇ cycloalkyl, 4- to 7-membered heterocyclyl, and 5- to 10-membered heteroaryl;
wherein one or more carbon atoms in said “alkyl” of C₁-C₄₀ alkyl, aminoalkyl, C₆-C₁₂ aryl-C₁-C₁₀ alkyl, C₃-C₇ cycloalkyl-C₁-C₁₀ alkyl, 4- to 7-membered heterocyclyl-C₁-C₁₀ alkyl, 5- to 10-membered heteroaryl-C₁-C₁₀ alkyl, or C₁-C₂₀ alkyl-thio-C₁-C₂₀ alkyl are optionally:
i. replaced with O or S; and/or
ii. substituted with (═O);
or, a salt thereof,
provided that when B is tin, said compound of Formula (II), or salt thereof, is other than hydrazinium chloride.

2. The oxidative-resistant ink solution of claim 1, wherein y in said composition of Formula (I) is 0.

3. The oxidative-resistant ink solution of claim 1, wherein A in said composition of Formula (I) is selected from the group consisting of Cs, MA, FA, and a combination thereof.

4. The oxidative-resistant ink solution of claim 1, wherein B is lead.

5. The oxidative-resistant ink solution of claim 1, wherein said composition of Formula (I) is Cs_{z}MA_{1-x-z}FAₓPbI₃, wherein x and z are each individually between 0 and 1.

6. The oxidative-resistant ink solution of claim 5, wherein z is selected from the group consisting of 0, 0.05, 0.08, 0.09, 0.1, 0.12, 0.15; and x is selected from the group consisting of 0, 0.2, 0.3, 0.4, and 0.5.

7. The oxidative-resistant ink solution of claim 6, wherein x is 0.3 and z is 0.

8. The oxidative-resistant ink solution of claim 1, wherein said one or more solvents are selected from the group consisting of dimethyl sulfoxide, dimethylformamide, N-methyl-2-pyrrolidone, γ-butyrolactone, 2-methoxyethanol, and acetonitrile.

9. The oxidative-resistant ink solution of claim 8, wherein said one or more solvents is 2-methoxyethanol.

10. The oxidative-resistant ink solution of claim 1, wherein in said compound or salt of Formula (II), R₃ and R₄ are each hydrogen, R₁ is hydrogen, and R₂ is selected from the group consisting of C₁-C₄₀ alkyl, C₂-C₄₀ alkenyl, C₂-C₄₀ alkynyl, aminoalkyl, C₆-C₁₂ aryl, C₃-C₇ cycloalkyl, 4- to 7-membered heterocyclyl, 5- to 7-membered heteroaryl, C₆-C₁₂ aryl-C₁-C₁₀ alkyl, C₃-C₇ cycloalkyl-C₁-C₁₀ alkyl, 4- to 7-membered heterocyclyl-C₁-C₁₀ alkyl, 5- to 10-membered heteroaryl-C₁-C₁₀ alkyl, and C₁-C₂₀ alkyl-thio-C₁-C₂₀ alkyl, each of which is optionally substituted one or more times with a substituent, each independently selected from the group consisting of halogen, cyano, hydrazino, C₁-C₂₀ alkyl, amino, C₁-C₂₀ alkoxy, C₂-C₂₀ alkenyl, C₂-C₂₀ alkynyl, C₆-C₁₂ aryl, C₃-C₇ cycloalkyl, 4- to 7-membered heterocyclyl, and 5- to 10-membered heteroaryl;
wherein one or more carbon atoms in said “alkyl” of C₁-C₄₀ alkyl, aminoalkyl, C₆-C₁₂ aryl-C₁-C₁₀ alkyl, C₃-C₇ cycloalkyl-C₁-C₁₀ alkyl, 4- to 7-membered heterocyclyl-C₁-C₁₀ alkyl, 5- to 10-membered heteroaryl-C₁-C₁₀ alkyl, C₁-C₂₀ alkyl-thio-C₁-C₂₀ alkyl are optionally:
i. replaced with O or S; and/or
ii. substituted with (═O).

11. The oxidative-resistant ink solution of claim 10, wherein R₂ is C₁-C₁₀ alkyl, optionally substituted with hydrazino, and wherein one or more atoms in said alkyl are substituted with (═O).

12. The oxidative-resistant ink solution of claim 11, wherein R₂ is

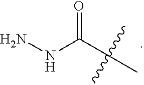 [SMILES: *C(=O)NN]

13. The oxidative-resistant ink solution of claim 10, wherein R₂ is selected from the group consisting of C₁-C₁₀ alkyl, C₆-C₁₂ aryl-C₁-C₆ alkyl, and 5- to 10-membered heteroaryl-C₁-C₆ alkyl.

14. The oxidative-resistant ink solution of claim 13, wherein R₂ is C₆-C₁₂ aryl-C₁-C₆ alkyl.

15. The oxidative-resistant ink solution of claim 14, wherein R₂ is benzyl.

16. The oxidative-resistant ink solution of claim 13, wherein R₂ is C₁-C₁₀ alkyl.

17. The oxidative-resistant ink solution of claim 16, wherein R₂ is selected from the group consisting of methyl, ethyl, propyl, and butyl.

18. The oxidative-resistant ink solution of claim 17, wherein R₂ is propyl.

19. The oxidative-resistant ink solution of claim 13, wherein R₂ is 5- to 10-membered heteroaryl-C₁-C₆ alkyl.

20. The oxidative-resistant ink solution of claim 19, wherein R₂ is thiophene-methyl.

21. The oxidative-resistant ink solution of claim 1, wherein said compound of Formula (II) is a salt.

22. The oxidative-resistant ink solution of claim 21, wherein said salt is

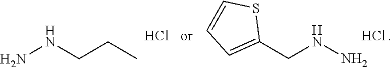

23. The oxidative-resistant ink solution of claim 21, wherein said salt is

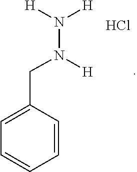

24. The oxidative-resistant ink solution of claim 1, wherein said composition of Formula (I) is MA_{0.7}FA_{0.3}PbI₃, said compound of Formula (II) or salt thereof is 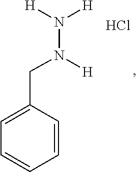
and said one or more solvents is 2-methoxyethanol.

25. The oxidative-resistant ink solution of claim 1, wherein said compound of Formula (II), or salt thereof, is present in said ink solution in a molar percent of about 0.01 to about 5 relative to said composition of Formula (I).

26. The oxidative-resistant ink solution of claim 25, wherein said compound of Formula (II), or salt thereof, is present in said ink solution in a molar percent of about 0.01 to about 1.5 relative to said composition of Formula (I).

27. The oxidative-resistant ink solution of claim 26, wherein said compound of Formula (II), or salt thereof, is present in said ink solution in a molar percent of about 0.15 to about 0.75 relative to said composition of Formula (I).

28. The oxidative-resistant ink solution of claim 27, wherein said compound of Formula (II), or salt thereof, is present in said ink solution in a molar percent of about 0.26 relative to said composition of Formula (I).

29. A method of preparing an oxidative-resistant ink solution, comprising:
contacting an ink solution comprising a composition of Formula (I) with a compound of Formula (II), or a salt thereof;
ABI_{3-y}X_{y} (I)
wherein,
A is a cation selected from the group consisting of methylammonium (MA), tetramethylammonium, formamidinium (FA), cesium (Cs), rubidium (Rb), potassium (K), sodium (Na), butylammonium (BA), phenethylammonium (PEA), phenylammonium (PA), guanidinium (GA), and a combination thereof;
B is a metal cation selected from the group consisting of lead, tin, calcium, cadmium, germanium, zinc, nickel, platinum, palladium, mercury, titanium, silicon, and a combination thereof;
X is selected from the group consisting of Cl⁻, Br⁻, F⁻, SCN⁻, and a combination thereof;
and
y is between 0 and 3; 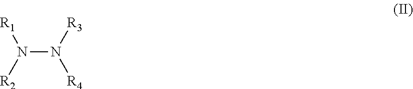
wherein,
R₁, R₂, R₃, and R₄ are each independently selected from the group consisting of hydrogen, C₁-C₄₀ alkyl, C₂-C₄₀ alkenyl, C₂-C₄₀ alkynyl, aminoalkyl, C₆-C₁₂ aryl, C₃-C₇ cycloalkyl, 4- to 7-membered heterocyclyl, 5- to 10-membered heteroaryl, C₆-C₁₂ aryl-C₁-C₁₀ alkyl, C₃-C₇ cycloalkyl-C₁-C₁₀ alkyl, 4- to 7-membered heterocyclyl-C₁-C₁₀ alkyl, 5- to 10-membered heteroaryl-C₁-C₁₀ alkyl, and C₁-C₂₀ alkyl-thio-C₁-C₂₀ alkyl, each of which is optionally substituted one or more times with a substituent, each independently selected from the group consisting of halogen, cyano, hydrazino, C₁-C₂₀ alkyl, amino, C₁-C₂₀ alkoxy, C₂-C₂₀ alkenyl, C₂-C₂₀ alkynyl, C₆-C₁₂ aryl, C₃-C₇ cycloalkyl, 4- to 7-membered heterocyclyl, and 5- to 10-membered heteroaryl;
wherein one or more carbon atoms in said “alkyl” of C₁-C₄₀ alkyl, aminoalkyl, C₆-C₁₂ aryl-C₁-C₁₀ alkyl, C₃-C₇ cycloalkyl-C₁-C₁₀ alkyl, 4- to 7-membered heterocyclyl-C₁-C₁₀ alkyl, 5- to 10-membered heteroaryl-C₁-C₁₀ alkyl, or C₁-C₂₀ alkyl-thio-C₁-C₂₀ alkyl are optionally:
i. replaced with O or S; and/or
ii. substituted with (═O);
provided that when B is tin, said compound of Formula (II), or salt thereof, is other than hydrazinium chloride or 4-fluorobenzohydrazide,
wherein said oxidative-resistant ink solution is prepared.

30. A method of reducing oxidation in an ink solution, comprising contacting an ink solution comprising a composition of Formula (I) with an oxidative reducing amount of a compound of Formula (II), or a salt thereof;
ABI_{3-y}X_{y} (I)
wherein,
A is a cation selected from the group consisting of methylammonium (MA), tetramethylammonium, formamidinium (FA), cesium (Cs), rubidium (Rb), potassium (K), sodium (Na), butylammonium (BA), phenethylammonium (PEA), phenylammonium (PA), guanidinium (GA), and a combination thereof;
B is a metal cation selected from the group consisting of lead, tin, calcium, cadmium, germanium, zinc, nickel, platinum, palladium, mercury, titanium, silicon, and a combination thereof;
X is selected from the group consisting of Cl⁻, Br⁻, F⁻, SCN⁻, and a combination thereof;
and
y is between 0 and 3. 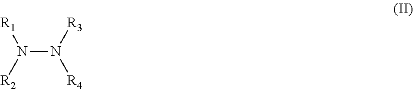
wherein, R₁, R₂, R₃, and R₄ are each independently selected from the group consisting of hydrogen, C₁-C₄₀ alkyl, C₂-C₄₀ alkenyl, C₂-C₄₀ alkynyl, aminoalkyl, C₆-C₁₂ aryl, C₃-C₇ cycloalkyl, 4- to 7-membered heterocyclyl, 5- to 10-membered heteroaryl, C₆-C₁₂ aryl-C₁-C₁₀ alkyl, C₃-C₇ cycloalkyl-C₁-C₁₀ alkyl, 4- to 7-membered heterocyclyl-C₁-C₁₀ alkyl, 5- to 10-membered heteroaryl-C₁-C₁₀ alkyl, and C₁-C₂₀ alkyl-thio-C₁-C₂₀ alkyl, each of which is optionally substituted one or more times with a substituent, each independently selected from the group consisting of halogen, cyano, hydrazino, C₁-C₂₀ alkyl, amino, C₁-C₂₀ alkoxy, C₂-C₂₀ alkenyl, C₂-C₂₀ alkynyl, C₆-C₁₂ aryl, C₃-C₇ cycloalkyl, 4- to 7-membered heterocyclyl, and 5- to 10-membered heteroaryl;
wherein one or more carbon atoms in said “alkyl” of C₁-C₄₀ alkyl, aminoalkyl, C₆-C₁₂ aryl-C₁-C₁₀ alkyl, C₃-C₇ cycloalkyl-C₁-C₁₀ alkyl, 4- to 7-membered heterocyclyl-C₁-C₁₀ alkyl, 5- to 10-membered heteroaryl-C₁-C₁₀ alkyl, or C₁-C₂₀ alkyl-thio-C₁-C₂₀ alkyl are optionally:
i. replaced with O or S; and/or
ii. substituted with (═O);
provided that when B is tin, said compound of Formula (II), or salt thereof, is other than hydrazinium chloride or 4-fluorobenzohydrazide.

31. The method of claim 29 or 30, wherein said ink solution comprises one or more solvents selected from the group consisting of dimethyl sulfoxide, dimethylformamide, N-methyl-2-pyrrolidone, γ-butyrolactone, 2-methoxyethanol, and acetonitrile.

32. The method of claim 31, wherein said solvent is 2-methoxyethanol.

33. The method of claim 29 or 30, wherein y in said composition of Formula (I) is 0.

34. The method of claim 29 or 30, wherein A in said composition of Formula (I) is selected from the group consisting of Cs, MA, FA, and a combination thereof.

35. The method of claim 29 or 30, wherein B is lead.

36. The method of claim 29 or 30, wherein said composition of Formula (I) is Cs_{z}MA_{1-x-z}FAₓPbI₃, wherein x and z are each independently between 0 and 1.

37. The method of claim 36, wherein z is selected from the group consisting of 0, 0.05, 0.08, 0.09, 0.10, 0.12, and 0.15; and x is selected from the group consisting of 0, 0.2, 0.3, 0.4, and 0.5.

38. The method of claim 37, wherein x is 0.3 and z is 0.

39. The method of claim 29 or 30, wherein in said compound or salt of Formula (II), R₃ and R₄ are each hydrogen, R₁ is hydrogen, and R₂ is selected from the group consisting of C₁-C₄₀ alkyl, C₂-C₄₀ alkenyl, C₂-C₄₀ alkynyl, aminoalkyl, C₆-C₁₂ aryl, C₃-C₇ cycloalkyl, 4- to 7-membered heterocyclyl, 5- to 7-membered heteroaryl, C₆-C₁₂ aryl-C₁-C₁₀ alkyl, C₃-C₇ cycloalkyl-C₁-C₁₀ alkyl, 4- to 7-membered heterocyclyl-C₁-C₁₀ alkyl, 5- to 10-membered heteroaryl-C₁-C₁₀ alkyl, and C₁-C₂₀ alkyl-thio-C₁-C₂₀ alkyl, each of which is optionally substituted one or more times with a substituent, each independently selected from the group consisting of halogen, cyano, hydrazino, C₁-C₂₀ alkyl, amino, C₁-C₂₀ alkoxy, C₂-C₂₀ alkenyl, C₂-C₂₀ alkynyl, C₆-C₁₂ aryl, C₃-C₇ cycloalkyl, 4- to 7-membered heterocyclyl, and 5- to 10-membered heteroaryl;
wherein one or more carbon atoms in said “alkyl” of C₁-C₄₀ alkyl, aminoalkyl, C₆-C₁₂ aryl-C₁-C₁₀ alkyl, C₃-C₇ cycloalkyl-C₁-C₁₀ alkyl, 4- to 7-membered heterocyclyl-C₁-C₁₀ alkyl, 5- to 10-membered heteroaryl-C₁-C₁₀ alkyl, C₁-C₂₀ alkyl-thio-C₁-C₂₀ alkyl are optionally:
i. replaced with O or S; and/or
ii. substituted with (═O).

40. The method of claim 39, wherein R₂ is C₁-C₁₀ alkyl, optionally substituted with hydrazino, and wherein one or more atoms in said alkyl are substituted with (═O).

41. The method of claim 40, wherein R₂ is

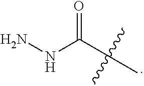 [SMILES: *C(=O)NN]

42. The method of claim 39, wherein R₂ is selected from the group consisting of C₁-C₁₀ alkyl, C₆-C₁₂ aryl-C₁-C₆ alkyl, and 5- to 10-membered heteroaryl-C₁-C₆ alkyl.

43. The method of claim 42, wherein R₂ is C₆-C₁₂ aryl-C₁-C₆ alkyl.

44. The method of claim 43, wherein R₂ is benzyl.

45. The method of claim 42, wherein R₂ is C₁-C₁₀ alkyl.

46. The method of claim 45, wherein R₂ is selected from the group consisting of methyl, ethyl, propyl, and butyl.

47. The method of claim 46, wherein R₂ is propyl.

48. The method of claim 42, wherein R₂ is 5- to 10-membered heteroaryl-C₁-C₆ alkyl.

49. The method of claim 48, wherein R₂ is thiophene-methyl.

50. The method of claim 29 or 30, wherein said compound of Formula (II) is a salt.

51. The method of claim 50, wherein said salt is

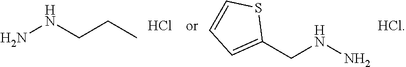

52. The method of claim 50, wherein said salt is

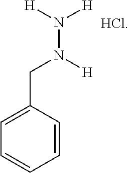

53. The method of claim 29 or 30, wherein said composition of Formula (I) is MA_{0.7}FA_{0.3}PbI₃ and said compound of Formula (II) or salt thereof is

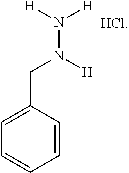

54. The method of any one of claims 29-53, wherein said compound of Formula (II), or salt thereof, is contacted with said ink solution comprising said composition of Formula (I) in a molar percent of about 0.01 to about 5 relative to said composition of Formula (I).

55. The method of claim 54, wherein said compound of Formula (II), or salt thereof, is contacted with said ink solution comprising said composition of Formula (I) in a molar percent of about 0.01 to about 1.5 relative to said composition of Formula (I).

56. The method of claim 55, wherein said compound of Formula (II), or salt thereof, is contacted with said ink solution comprising said composition of Formula (I) in a molar percent of about 0.15 to about 0.75 relative to said composition of Formula (I).

57. The method of claim 56, wherein said compound of Formula (II), or salt thereof, is contacted with said ink solution comprising said composition of Formula (I) in a molar percent of about 0.26 relative to said composition of Formula (I).

58. The oxidative-resistant ink solution of claim 1, having a vapor pressure of about 5 to about 100 kPa, for use in a fast-coating process, wherein said fast coating process is selected from the group consisting of blade-coating, slot die coating, shear coating, gravure coating, brush coating, syringe coating, and screen printing.

59. A method for producing a polycrystalline perovskite film using the oxidative-resistant ink solution of claim 1, said method comprising:
contacting said ink solution using a fast coating process onto a substrate to form a film, wherein said fast coating process is selected from the group consisting of blade coating, slot die coating, shear coating, gravure coating, brush coating, syringe coating, and screen printing.

60. The method of claim 59, wherein said fast-coating process is blade coating.

61. The method of claim 59, wherein said method produces a polycrystalline perovskite film having an area of at least 0.01 cm².

62. A polycrystalline film comprising:
a) a composition of Formula (I):
ABI_{3-y}X_{y} (I)
wherein,
A is a cation selected from the group consisting of methylammonium (MA), tetramethylammonium, formamidinium (FA), cesium (Cs), rubidium (Rb), potassium (K), sodium (Na), butylammonium (BA), phenethylammonium (PEA), phenylammonium (PA), guanidinium (GA), and a combination thereof;
B is a metal cation selected from the group consisting of lead, tin, calcium, cadmium, germanium, zinc, nickel, platinum, palladium, mercury, titanium, silicon, and a combination thereof;
X is selected from the group consisting of Cl⁻, Br⁻, F⁻, SCN⁻, and a combination thereof;
and
y is between 0 and 3;
and
b) a compound of Formula (II): 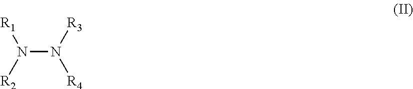
wherein,
R₁, R₂, R₃, and R₄ are each independently selected from the group consisting of hydrogen, C₁-C₄₀ alkyl, C₂-C₄₀ alkenyl, C₂-C₄₀ alkynyl, aminoalkyl, C₆-C₁₂ aryl, C₃-C₇ cycloalkyl, 4- to 7-membered heterocyclyl, 5- to 10-membered heteroaryl, C₆-C₁₂ aryl-C₁-C₁₀ alkyl, C₃-C₇ cycloalkyl-C₁-C₁₀ alkyl, 4- to 7-membered heterocyclyl-C₁-C₁₀ alkyl, 5- to 10-membered heteroaryl-C₁-C₁₀ alkyl, and C₁-C₂₀ alkyl-thio-C₁-C₂₀ alkyl, each of which is optionally substituted one or more times with a substituent, each independently selected from the group consisting of halogen, cyano, hydrazino, C₁-C₂₀ alkyl, amino, C₁-C₂₀ alkoxy, C₂-C₂₀ alkenyl, C₂-C₂₀ alkynyl, C₆-C₁₂ aryl, C₃-C₇ cycloalkyl, 4- to 7-membered heterocyclyl, and 5- to 10-membered heteroaryl;
wherein one or more carbon atoms in said “alkyl” of C₁-C₄₀ alkyl, aminoalkyl, C₆-C₁₂ aryl-C₁-C₁₀ alkyl, C₃-C₇ cycloalkyl-C₁-C₁₀ alkyl, 4- to 7-membered heterocyclyl-C₁-C₁₀ alkyl, 5- to 10-membered heteroaryl-C₁-C₁₀ alkyl, or C₁-C₂₀ alkyl-thio-C₁-C₂₀ alkyl are optionally:
i. replaced with O or S; and/or
ii. substituted with (═O);
or, a salt thereof;
provided that when B is tin, said compound of Formula (II), or salt thereof, is other than hydrazinium chloride or 4-fluorobenzohydrazide.

63. The polycrystalline film of claim 62, wherein y in said composition of Formula (I) is 0.

64. The polycrystalline film of claim 62, wherein A in said composition of Formula (I) is selected from the group consisting of Cs, MA, FA, and a combination thereof.

65. The polycrystalline film of claim 62, wherein B is lead.

66. The polycrystalline film of claim 62, wherein said composition of Formula (I) is Cs_{z}MA_{1-x-z}FAₓPbI₃, wherein x and z are between 0 and 1.

67. The polycrystalline film of claim 66, wherein z is selected from the group consisting of 0, 0.05, 0.08, 0.09, 0.10, 0.12, and 0.15; and x is selected from the group consisting of 0, 0.2, 0.3, 0.4, and 0.5.

68. The polycrystalline film of claim 67, wherein x is 0.3 and z is 0.

69. The polycrystalline film of claim 62, wherein in said compound or salt of Formula (II), R₃ and R₄ are each hydrogen, R₁ is hydrogen, and R₂ is selected from the group consisting of C₁-C₄₀ alkyl, C₂-C₄₀ alkenyl, C₂-C₄₀ alkynyl, aminoalkyl, C₆-C₁₂ aryl, C₃-C₇ cycloalkyl, 4- to 7-membered heterocyclyl, 5- to 7-membered heteroaryl, C₆-C₁₂ aryl-C₁-C₁₀ alkyl, C₃-C₇ cycloalkyl-C₁-C₁₀ alkyl, 4- to 7-membered heterocyclyl-C₁-C₁₀ alkyl, 5- to 10-membered heteroaryl-C₁-C₁₀ alkyl, and C₁-C₂₀ alkyl-thio-C₁-C₂₀ alkyl, each of which is optionally substituted one or more times with a substituent, each independently selected from the group consisting of halogen, cyano, hydrazino, C₁-C₂₀ alkyl, amino, C₁-C₂₀ alkoxy, C₂-C₂₀ alkenyl, C₂-C₂₀ alkynyl, C₆-C₁₂ aryl, C₃-C₇ cycloalkyl, 4- to 7-membered heterocyclyl, and 5- to 10-membered heteroaryl;
wherein one or more carbon atoms in said “alkyl” of C₁-C₄₀ alkyl, aminoalkyl, C₆-C₁₂ aryl-C₁-C₁₀ alkyl, C₃-C₇ cycloalkyl-C₁-C₁₀ alkyl, 4- to 7-membered heterocyclyl-C₁-C₁₀ alkyl, 5- to 10-membered heteroaryl-C₁-C₁₀ alkyl, C₁-C₂₀ alkyl-thio-C₁-C₂₀ alkyl are optionally:
i. replaced with O or S; and/or
ii. substituted with (═O).

70. The polycrystalline film of claim 69, wherein R₂ is C₁-C₁₀ alkyl, optionally substituted with hydrazino, and wherein one or more atoms in said alkyl are substituted with (═O).

71. The polycrystalline film of claim 70, wherein R₂ is

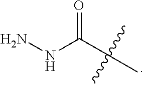 [SMILES: *C(=O)NN]

72. The polycrystalline film of claim 69, wherein R₂ is selected from the group consisting of C₁-C₁₀ alkyl, C₆-C₁₂ aryl-C₁-C₆ alkyl, and 5- to 10-membered heteroaryl-C₁-C₆ alkyl.

73. The polycrystalline film of claim 72, wherein R₂ is C₆-C₁₂ aryl-C₁-C₆ alkyl.

74. The polycrystalline film of claim 73, wherein R₂ is benzyl.

75. The polycrystalline film of claim 72, wherein R₂ is C₁-C₁₀ alkyl.

76. The polycrystalline film of claim 75, wherein R₂ is selected from the group consisting of methyl, ethyl, propyl, and butyl.

77. The polycrystalline film of claim 76, wherein R₂ is propyl.

78. The polycrystalline film of claim 72, wherein R₂ is 5- to 10-membered heteroaryl-C₁-C₆ alkyl.

79. The polycrystalline film of claim 78, wherein R₂ is thiophene-methyl.

80. The polycrystalline film of claim 62, wherein said compound of Formula (II) is a salt.

81. The polycrystalline film of claim 80, wherein said salt is

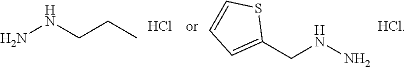

82. The polycrystalline film of claim 80, wherein said salt is

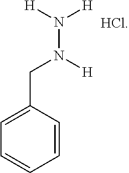

83. The polycrystalline film of claim 62, wherein said composition of Formula (I) is MA_{0.7}FA_{0.3}PbI₃ and said compound of Formula (II) or salt thereof is

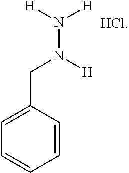

84. The polycrystalline film of claim 62, wherein said compound of Formula (II), or salt thereof, is present in a molar percent of about 0.01 to about 5 relative to said composition of Formula (I).

85. The polycrystalline film of claim 84, wherein said compound of Formula (II), or salt thereof, is present in a molar percent of about 0.01 to about 1.5 relative to said composition of Formula (I).

86. The polycrystalline film of claim 85, wherein said compound of Formula (II), or salt thereof, is present in a molar percent of about 0.15 to about 0.75 relative to said composition of Formula (I).

87. The polycrystalline film of claim 86, wherein said compound of Formula (II), or salt thereof, is present in a molar percent of about 0.26 relative to said composition of Formula (I).

88. A semiconductor device comprising:
one or more anode layers;
one or more cathode layers; and
one or more active layers, wherein at least one of said one or more active layers comprises the polycrystalline film of claim 62.

89. The semiconductor device of claim 88, wherein said device is selected from the group consisting of solar cell, light emitting diode, photodiode, photoelectrochemical cell, photoresistor, phototransistor, photomultiplier, photoelectric cell, electrochromic cell, and radiation detector.

90. The semiconductor device of claim 89, wherein said solar cell is a single junction solar cell.

91. The semiconductor device of claim 89, wherein said solar cell is a tandem solar cell.

92. A solar cell, comprising:
one or more transparent conductive oxide layers;
one or more conductive electrode layers; and
one or more active layers, wherein at least one of said one or more active layers comprises the polycrystalline film of claim 62.

93. The solar cell of claim 92 further comprising:
one or more hole transport layers; and
one or more electron transport layers.

94. The solar cell of claim 93, wherein said solar cell comprises:
one transparent conductive oxide layer;
one conductive electrode layer;
one hole transport layer;
one electron transport layer; and
one active layer, wherein said active layer comprises the polycrystalline film.

95. The solar cell of claim 94, wherein:
said hole transport layer is disposed on said transparent conductive oxide layer;
said active layer comprising the polycrystalline film is disposed on said hole transport layer;
said electron transport layer is disposed on said active layer; and
said conductive electrode layer is disposed on said electron transport layer.

96. The solar cell of claim 94, wherein:
said electron transport layer is disposed on said transparent conductive oxide layer;
said active layer comprising the polycrystalline film is disposed on said electron transport layer;
said hole transport layer is disposed on said active layer; and
said conductive electrode layer is disposed on said hole transport layer.

97. The solar cell of claim 93, wherein said one or more hole transport layers are selected from the group consisting of PTAA, Spiro-OMeTAD, PEDOT:PSS, NiO, MoO₃, V₂O₅, Poly-TPD, EH44, P3HT, and a combination thereof.

98. The solar cell of claim 93, wherein said one or more electron transport layers are selected from the group consisting of C₆₀, BCP, TiO₂, SnO₂, PCBM, ICBA, ZnO, ZrAcac, LiF, TPBI, PFN, Nb₂O₅, and a combination thereof.

99. The solar cell of claim 92 or 93, wherein said one or more transparent conductive oxide layers are selected from the group consisting of ITO, FTO, ZITO, and AZO.

100. The solar cell of claim 92 or 93, wherein said one or more conductive electrode layers are selected from the group consisting of Al, Au, Cu, Cr, Ni, Zn, Ca, Mg, Ag, Ti, and carbon.

101. The solar cell of claim 95, wherein:
said transparent conductive oxide layer is indium tin oxide;
said hole transport layer is PTAA;
said electron transport layer is C₆₀; and
said conductive electrode layer is Cu.

102. The solar cell of claim 101, further comprising a buffer layer of BCP disposed between said electron transport layer and said conductive electrode layer.

103. The solar cell of claim 93, wherein said solar cell exhibits a Power Conversion Efficiency of at least 20%.

104. The solar cell of claim 93, wherein said solar cell exhibits a Power Conversion Efficiency of at least 23%.

105. A solar module, comprising a plurality of the solar cell of claim 93 or 101.

106. The solar module of claim 105, having an aperture area of at least 37 cm².

107. The solar module of claim 105, having an aperture area of at least 39 cm².

108. The solar module of claim 105, wherein said module exhibits a Power Conversion Efficiency of at least 17%.

109. A kit, comprising
i) a vial containing a perovskite precursor solution comprising a solvent and a composition of Formula (I)
ABI_{3-y}X_{y} (I)
wherein,
A is a cation selected from the group consisting of methylammonium (MA), tetramethylammonium, formamidinium (FA), cesium (Cs), rubidium (Rb), potassium (K), sodium (Na), butylammonium (BA), phenethylammonium (PEA), phenylammonium (PA), guanidinium (GA), and a combination thereof;
B is a metal cation selected from the group consisting of lead, tin, calcium, cadmium, germanium, zinc, nickel, platinum, palladium, mercury, titanium, silicon, and a combination thereof;
X is selected from the group consisting of Cl⁻, Br⁻, F⁻, SCN⁻, and a combination thereof;
and
y is between 0 and 3; and
ii) a vial containing a compound of Formula (II): 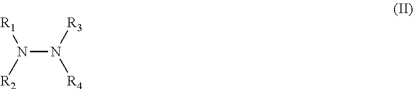
wherein,
R₁, R₂, R₃, and R₄ are each independently selected from the group consisting of hydrogen, C₁-C₄₀ alkyl, C₂-C₄₀ alkenyl, C₂-C₄₀ alkynyl, aminoalkyl, C₆-C₁₂ aryl, C₃-C₇ cycloalkyl, 4- to 7-membered heterocyclyl, 5- to 10-membered heteroaryl, C₆-C₁₂ aryl-C₁-C₁₀ alkyl, C₃-C₇ cycloalkyl-C₁-C₁₀ alkyl, 4- to 7-membered heterocyclyl-C₁-C₁₀ alkyl, 5- to 10-membered heteroaryl-C₁-C₁₀ alkyl, and C₁-C₂₀ alkyl-thio-C₁-C₂₀ alkyl, each of which is optionally substituted one or more times with a substituent, each independently selected from the group consisting of halogen, cyano, hydrazino, C₁-C₂₀ alkyl, amino, C₁-C₂₀ alkoxy, C₂-C₂₀ alkenyl, C₂-C₂₀ alkynyl, C₆-C₁₂ aryl, C₃-C₇ cycloalkyl, 4- to 7-membered heterocyclyl, and 5- to 10-membered heteroaryl;
wherein one or more carbon atoms in said “alkyl” of C₁-C₄₀ alkyl, aminoalkyl, C₆-C₁₂ aryl-C₁-C₁₀ alkyl, C₃-C₇ cycloalkyl-C₁-C₁₀ alkyl, 4- to 7-membered heterocyclyl-C₁-C₁₀ alkyl, 5- to 10-membered heteroaryl-C₁-C₁₀ alkyl, or C₁-C₂₀ alkyl-thio-C₁-C₂₀ alkyl are optionally:
i. replaced with O or S; and/or
ii. substituted with (═O);
or, a salt thereof.

110. The oxidative-resistant ink solution of claim 1, wherein said ink solution further comprises a second compound of Formula (II), or salt thereof.

111. The method of claim 29, further comprising contacting said oxidative-resistant ink solution with a second compound of Formula (II), or salt thereof.

112. The polycrystalline film of claim 62, further comprising a second compound of Formula (II), or salt thereof.

113. A method of preparing a perovskite film having reduced interfacial voids, comprising contacting a precursor solution comprising one or more non-coordinating solvents and a composition of Formula (I)
ABI_{3-y}X_{y} (I)
wherein,
A is a cation selected from the group consisting of methylammonium (MA), tetramethylammonium, formamidinium (FA), cesium (Cs), rubidium (Rb), potassium (K), sodium (Na), butylammonium (BA), phenethylammonium (PEA), phenylammonium (PA), guanidinium (GA), and a combination thereof;
B is a metal cation selected from the group consisting of lead, tin, calcium, cadmium, germanium, zinc, nickel, platinum, palladium, mercury, titanium, silicon, and a combination thereof;
X is selected from the group consisting of Cl⁻, Br⁻, F⁻, SCN⁻, and a combination thereof, and
y is between 0 and 3;
with:
(i) a compound of Formula (II), or a salt thereof, 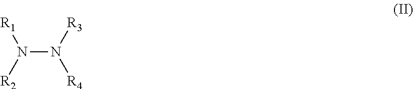
wherein,
R₁, R₂, R₃, and R₄ are each independently selected from the group consisting of hydrogen, C₁-C₄₀ alkyl, C₂-C₄₀ alkenyl, C₂-C₄₀ alkynyl, aminoalkyl, C₆-C₁₂ aryl, C₃-C₇ cycloalkyl, 4- to 7-membered heterocyclyl, 5- to 10-membered heteroaryl, C₆-C₁₂ aryl-C₁-C₁₀ alkyl, C₃-C₇ cycloalkyl-C₁-C₁₀ alkyl, 4- to 7-membered heterocyclyl-C₁-C₁₀ alkyl, 5- to 10-membered heteroaryl-C₁-C₁₀ alkyl, and C₁-C₂₀ alkyl-thio-C₁-C₂₀ alkyl, each of which is optionally substituted one or more times with a substituent, each independently selected from the group consisting of halogen, cyano, hydrazino, C₁-C₂₀ alkyl, amino, C₁-C₂₀ alkoxy, C₂-C₂₀ alkenyl, C₂-C₂₀ alkynyl, C₆-C₁₂ aryl, C₃-C₇ cycloalkyl, 4- to 7-membered heterocyclyl, and 5- to 10-membered heteroaryl;
wherein one or more carbon atoms in said “alkyl” of C₁-C₄₀ alkyl, aminoalkyl, C₆-C₁₂ aryl-C₁-C₁₀ alkyl, C₃-C₇ cycloalkyl-C₁-C₁₀ alkyl, 4- to 7-membered heterocyclyl-C₁-C₁₀ alkyl, 5- to 10-membered heteroaryl-C₁-C₁₀ alkyl, or C₁-C₂₀ alkyl-thio-C₁-C₂₀ alkyl are optionally:
i. replaced with O or S; and/or
ii. substituted with (═O);
and
(ii) a coordinating solvent, to prepare a modified precursor solution; and
contacting said modified precursor solution onto a substrate to prepare a perovskite film, wherein said perovskite film prepared has reduced interfacial voids.

114. The method of claim 113, wherein said coordinating solvent is dimethyl sulfoxide.

115. The method of claim 113, wherein in said compound or salt of Formula (II), R₃ and R₄ are each hydrogen, R₁ is hydrogen, and R₂ is selected from the group consisting of C₁-C₄₀ alkyl, C₂-C₄₀ alkenyl, C₂-C₄₀ alkynyl, aminoalkyl, C₆-C₁₂ aryl, C₃-C₇ cycloalkyl, 4- to 7-membered heterocyclyl, 5- to 7-membered heteroaryl, C₆-C₁₂ aryl-C₁-C₁₀ alkyl, C₃-C₇ cycloalkyl-C₁-C₁₀ alkyl, 4- to 7-membered heterocyclyl-C₁-C₁₀ alkyl, 5- to 10-membered heteroaryl-C₁-C₁₀ alkyl, and C₁-C₂₀ alkyl-thio-C₁-C₂₀ alkyl, each of which is optionally substituted one or more times with a substituent, each independently selected from the group consisting of halogen, cyano, hydrazino, C₁-C₂₀ alkyl, amino, C₁-C₂₀ alkoxy, C₂-C₂₀ alkenyl, C₂-C₂₀ alkynyl, C₆-C₁₂ aryl, C₃-C₇ cycloalkyl, 4- to 7-membered heterocyclyl, and 5- to 10-membered heteroaryl;
wherein one or more carbon atoms in said “alkyl” of C₁-C₄₀ alkyl, aminoalkyl, C₆-C₁₂ aryl-C₁-C₁₀ alkyl, C₃-C₇ cycloalkyl-C₁-C₁₀ alkyl, 4- to 7-membered heterocyclyl-C₁-C₁₀ alkyl, 5- to 10-membered heteroaryl-C₁-C₁₀ alkyl, C₁-C₂₀ alkyl-thio-C₁-C₂₀ alkyl are optionally:
i. replaced with O or S; and/or
ii. substituted with (═O).

116. The method of claim 115, wherein R₂ is C₁-C₁₀ alkyl, optionally substituted with hydrazino, and wherein one or more atoms in said alkyl are substituted with (═O).

117. The method of claim 115, wherein R₂ is

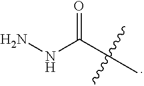 [SMILES: *C(=O)NN]

118. The method of claim 113, wherein said compound of Formula II is

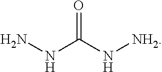

119. The method of claim 113, wherein said composition of Formula (I) is APbI₃, wherein A is a cation selected from the group consisting of methylammonium (MA), formamidinium (FA), cesium (Cs), and a combination thereof.

120. The method of claim 119, wherein said composition of Formula (I) is MA₁₋ₓFA_{X}PbI₃, wherein x is between 0 and 0.6.

121. The method of claim 120, wherein said composition of Formula (I) is MA_{0.6}FA_{0.4}PbI₃.

122. The method of claim 113, further comprising annealing said perovskite film, wherein the presence of said compound of Formula (II), or salt thereof, reduces time required for annealing.

123. The method of claim 113, wherein said compound or salt of Formula II is present in said modified precursor solution at about 0.25 to 5 mol % relative to said composition of Formula I; and wherein said coordinating solvent is present in said modified precursor solution at about 5 to 40 mol % relative to said composition of Formula I.

124. The method of claim 123, wherein said compound or salt of Formula II is present in said modified precursor solution at about 1.5 mol % relative to said composition of Formula I; and wherein said coordinating solvent is present in said modified precursor solution at about 25 mol % relative to said composition of Formula I.

125. The method of claim 113, wherein said one or more non-coordinating solvents are 2-methoxyethanol.

126. The method of claim 113, wherein:
said composition of Formula (I) is APbI₃, wherein A is a cation selected from the group consisting of methylammonium (MA), formamidinium (FA), cesium (Cs), and a combination thereof;
said compound of Formula II, or salt thereof, is 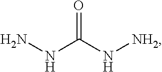
wherein said compound of Formula II is present in said modified precursor solution at about 1.5 mol % relative to said composition of Formula I; and
said coordinating solvent is dimethyl sulfoxide, wherein said coordinating solvent is present in said modified precursor solution at about 25 mol % relative to said composition of Formula I.

127. The method of claim 113, wherein said contacting said modified precursor solution onto a substrate to prepare a perovskite film comprises blade-coating said modified precursor solution onto said substrate.
